(19) United States
(12) Patent Application Publication
(10) Pub. No.: US 2024/0139686 A1
(43) Pub. Date: May 2, 2024

(54) RESIN MEMBRANE FILTER AND MANUFACTURING METHOD OF RESIN MEMBRANE FILTER

(71) Applicant: FUJIFILM Corporation, Tokyo (JP)

(72) Inventor: Hiroyuki YONEZAWA, Shizuoka (JP)

(73) Assignee: FUJIFILM Corporation, Tokyo (JP)

(21) Appl. No.: 18/395,615

(22) Filed: Dec. 24, 2023

Related U.S. Application Data
(63) Continuation of application No. PCT/JP2022/026551, filed on Jul. 4, 2022.

(30) Foreign Application Priority Data
Jul. 20, 2021 (JP) 2021-119362

(51) Int. Cl. B01D 67/00; B01D 69/02; B01L 3/00; G03F 7/00; G03F 7/038; G03F 7/039; G03F 7/40

(52) U.S. Cl. CPC B01D 67/0034; B01D 69/02; B01L 3/502753; G03F 7/0382; G03F 7/0385; G03F 7/0392; G03F 7/0397; G03F 7/40; G03F 7/70008; B01D 2325/0283; B01D 2325/04; B01L 2300/0681

(57) ABSTRACT

An object of the present invention is to provide a resin membrane filter having excellent separation accuracy and excellent toughness, and a manufacturing method of the resin membrane filter.

The resin membrane filter of the present invention includes a first main surface, a second main surface, and a plurality of through-holes, in which, in the through-hole, in a case where an average area of an opening portion at a position A which is located at a distance of 10% of a thickness of the resin membrane filter from the first main surface is denoted as Sva and an average area of an opening portion at a position B which is located at a distance of 90% of the thickness of the resin membrane filter from the first main surface is denoted as Svb, 0.8≤Sva/Svb≤1.25, a number ratio Ra of through-holes in which an area of the opening portion at the position A is more than 1.25 times Sva is 3.0% or less, and a number ratio Rb of through-holes in which an area of the opening portion at the position B is more than 1.25 times Svb is 3.0% or less.

### CROSS-REFERENCE TO RELATED APPLICATIONS

This application is a Continuation of PCT International Application No. PCT/JP2022/026551 filed on Jul. 4, 2022, which claims priority under 35 U.S.C. § 119(a) to Japanese Patent Application No. 2021-119362 filed on July 20, 2021. The above applications are hereby expressly incorporated by reference, in their entirety, into the present application.

### BACKGROUND OF THE INVENTION

### 1. Field of the Invention

The present invention relates to a resin membrane filter and a manufacturing method of a resin membrane filter.

### 2. Description of the Related Art

In the field of bioscience, porous membrane members used in applications such as blood filtration, cell separation, and culture base material have been known. In recent years, as a member that facilitates selective permeation or capture of an object compared to a porous membrane member made of nonwoven fabric in the related art, a porous membrane member made of a resin has been studied.

For example, JP2019-166509A discloses a waterproof ventilation filter including a resin film which has a bottomed recess portion with an opening on one main surface and first through-holes communicating between a surface of the recess portion and the other main surface, in which two or more of the first through-holes communicate with one recess portion.

### SUMMARY OF THE INVENTION

In JP2019-166509A, as a method for forming the recess portion and the through-holes in the resin film included in the filter, a method of using ion beam irradiation on an original film and a method of using laser irradiation on the original film are disclosed.

As a result of studying a resin membrane filter having a plurality of through-holes penetrating in a thickness direction with reference to the disclosure in JP2019-166509A, the present inventor has found that, in a resin membrane filter in which the through-holes are formed by the ion beam irradiation or the laser irradiation described above, a desired effect may not be obtained because through-holes with a large area of an opening portion exist at a certain amount or more.

In view of the above-described points, an object of the present invention is to provide a resin membrane filter having excellent separation accuracy and excellent toughness.

Another object of the present invention is to provide a manufacturing method of the resin membrane filter.

The inventors of the present invention have conducted intensive studies to solve the above-described problems, and as a result, have found that the above-described problems can be solved by the following configurations.
[1] A resin membrane filter comprising:
a first main surface;
a second main surface; and
a plurality of through-holes penetrating from the first main surface to the second main surface,
in which, in the through-hole, in a case where an average area of an opening portion at a position A which is located at a distance of 10% of a thickness of the resin membrane filter from the first main surface is denoted as Sva and an average area of an opening portion at a position B which is located at a distance of 90% of the thickness of the resin membrane filter from the first main surface is denoted as Svb, a relationship of an expression (1) described later is satisfied,
in the plurality of through-holes, a number ratio Ra of through-holes in which an area of the opening portion at the position A is more than 1.25 times Sva is 3.0% or less, and
in the plurality of through-holes, a number ratio Rb of through-holes in which an area of the opening portion at the position B is more than 1.25 times Svb is 3.0% or less.
[2] The resin membrane filter according to [1],
in which, in the plurality of through-holes, a number ratio Rt of through-holes in which an angle between an extending direction of the through-holes and a thickness direction of the resin membrane filter is within 5° is 99.0% or more.
[3] The resin membrane filter according to [1] or [2],
in which, in the plurality of through-holes, a number ratio Rr of through-holes in which a hole diameter is 0.9 to 1.1 times an average hole diameter of the through-holes is 99% or more.
[4] The resin membrane filter according to any one of [1] to [3],
in which a ratio of a standard deviation of hole diameters of the through-holes to an average hole diameter of the through-holes is 3.0% or less.
[5] The resin membrane filter according to any one of [1] to [4],
in which a curved portion in which a hole diameter of the through-hole increases as the curved portion approaches an opening end of the through-hole is formed in at least one end part of the through-hole, and
a curvature radius of the curved portion in a cut plane including an extending direction of the through-hole and a thickness direction of the resin membrane filter is 1 μm or more.
[6] The resin membrane filter according to any one of [1] to [5],
in which an average hole diameter of the through-holes is 10 μm or less.
[7] The resin membrane filter according to any one of [1] to [6],
in which an average hole diameter of the through-holes is 5 μm or less.
[8] The resin membrane filter according to [1] to [7],
in which a shape of the opening portion of the through-hole observed from a normal direction of the resin membrane filter is circular.
[9] The resin membrane filter according to any one of [1] to [8],
in which the thickness of the resin membrane filter is 10 μm or more.
[10] The resin membrane filter according to any one of [1] to [9],
in which a contact angle of at least one of the first main surface or the second main surface with water is 10° to 70°.
[11] The resin membrane filter according to any one of [1] to [10],
in which the resin membrane filter consists of a resin membrane formed of a photosensitive composition layer.
[12] The resin membrane filter according to any one of [1] to [11],
in which the resin membrane filter is a cured membrane of a negative tone photosensitive composition layer.
[13] The resin membrane filter according to any one of [1] to [11],
in which the resin membrane filter is formed from a positive tone photosensitive composition layer.
[14] The resin membrane filter according to any one of [1] to [13],
in which the resin membrane filter is used for cell separation.
[15] A manufacturing method of the resin membrane filter according to any one of [1] to and [14], comprising, in the following order:
a step P1 of preparing a photosensitive composition layer;
a step P2 of exposing the photosensitive composition layer in a patterned manner; and
a step P3 of developing the pattern-exposed photosensitive composition layer with a developer to form through-holes in the pattern-exposed photosensitive composition layer.
[16] The manufacturing method of the resin membrane filter according to [15],
in which the photosensitive composition layer is a layer formed of a negative tone photosensitive resin composition.
[17] The manufacturing method of the resin membrane filter according to or [16],
in which an exposure light of the step P2 includes i-rays.
[18] The manufacturing method of the resin membrane filter according to any one of to [17],
in which the step P2 is a step of performing the exposure through a photo mask.
[19] The manufacturing method of the resin membrane filter according to any one of to [18],
in which the manufacturing method includes, in the following order,
   a step P1-a of preparing a laminate including a temporary support and a photosensitive composition layer, and
   the step P2 of exposing the photosensitive composition layer in a patterned manner, and
after the step P2, the step P3 of developing the pattern-exposed photosensitive composition layer with a developer to form through-holes in the pattern-exposed photosensitive composition layer and a step P4-a of physically peeling off the temporary support and the pattern-exposed photosensitive composition layer are performed.
[20] The manufacturing method of the resin membrane filter according to [19],
in which the step P4-a is performed after performing the step P3.
[21] The manufacturing method of the resin membrane filter according to [19],
in which the step P3 is performed after performing the step P4-a.
[22] The manufacturing method of the resin membrane filter according to any one of to [18],
in which the manufacturing method includes, in the following order,
   a step P1-b of preparing a laminate including a temporary support, a water-soluble resin layer, and a photosensitive composition layer in this order, and
   the step P2 of exposing the photosensitive composition layer in a patterned manner, and
after the step P2, a step P3-a of developing the pattern-exposed photosensitive composition layer with a developer to form through-holes in the pattern-exposed photosensitive composition layer and a step P4-b of peeling off the pattern-exposed photosensitive composition layer from the temporary support by dissolving the water-soluble resin layer are performed.
[23] The manufacturing method of the resin membrane filter according to any one of to [18],
in which the manufacturing method includes, in the following order,
   a step P1-c of preparing a laminate including a water-soluble temporary support and a photosensitive composition layer in this order, and
   the step P2 of exposing the photosensitive composition layer in a patterned manner, and
after the step P2, a step P3-a of developing the pattern-exposed photosensitive composition layer with a developer to form through-holes in the pattern-exposed photosensitive composition layer and a step P4-c of obtaining the pattern-exposed photosensitive composition layer by dissolving the water-soluble temporary support are performed.

According to the present invention, it is possible to provide a resin membrane filter having excellent separation accuracy and excellent toughness.

In addition, according to the present invention, it is possible to provide a manufacturing method of the resin membrane filter.

### BRIEF DESCRIPTION OF THE DRAWINGS

FIG. 1 is a schematic view showing an example of a structure of a resin membrane filter according to the embodiment of the present invention.

FIG. 2 is a schematic view showing an example of a structure of a through-hole included in the resin membrane filter according to the embodiment of the present invention.

FIG. 3 is a schematic view showing another example of the structure of the through-hole included in the resin membrane filter according to the embodiment of the present invention.

### DESCRIPTION OF THE PREFERRED EMBODIMENTS

Hereinafter, the present invention will be described in detail.

In the present specification, the numerical ranges shown using “to” indicate ranges including the numerical values described before and after “to” as the lower limit value and the upper limit value.

In the numerical range described stepwise in the present specification, the upper limit value or the lower limit value described in a certain numerical range may be replaced with the upper limit value or the lower limit value of another numerical range described stepwise. In addition, in the numerical range described in the present specification, an upper limit value and a lower limit value described in a certain numerical range may be replaced with values shown in Examples.

In the present specification, the term “step” includes not only an independent step but also a step that cannot be clearly distinguished from other steps, as long as the intended purpose of the step is achieved.

In the present specification, a term “transparent” means that an average transmittance of visible light at a wavelength of 400 to 700 nm is 80% or more, and preferably 90% or more.

In the present specification, a transmittance is a value measured by using a spectrophotometer, and for example, can be measured by using a spectrophotometer U-3310 manufactured by Hitachi, Ltd.

In the present specification, unless otherwise specified, a weight-average molecular weight (Mw) and a number-average molecular weight (Mn) are values obtained by a gel permeation chromatography (GPC) analysis apparatus and converted using polystyrene as a standard substance, with TSKgel GMHxL, TSKgel G4000HxL, or TSKgel G2000HxL (all product names manufactured by Tosoh Corporation) as a column, tetrahydrofuran (THF) as an eluent, and a differential refractometer as a detector.

In the present specification, unless otherwise specified, a ratio of constitutional units of a polymer is a mass ratio.

In the present specification, unless otherwise specified, a molecular weight of a compound having a molecular weight distribution is the weight-average molecular weight (Mw).

In the present specification, unless otherwise specified, a content of metal elements is a value measured by using an inductively coupled plasma (ICP) spectroscopic analysis apparatus.

In the present specification, “(meth)acrylic” is a concept including both acrylic and methacrylic, and “(meth)acryloxy group” is a concept including both an acryloxy group and a methacryloxy group.

In the present specification, “alkali-soluble” means that the solubility in 100 g of aqueous solution of 1% by mass sodium carbonate at 22° C. is 0.1 g or more.

In the present specification, “water-soluble” means that the solubility in 100 g of water with a pH of 7.0 at a liquid temperature of 22° C. is 0.1 g or more. Therefore, for example, a water-soluble resin is intended to be a resin which satisfies the above-described solubility conditions.

In the present specification, a “solid content” of a composition refers to components which form a composition layer formed of the composition, and in a case where the composition contains a solvent (an organic solvent, water, and the like), the solid content means all components except the solvent. In addition, in a case where the components are components which form a composition layer, the components are considered to be solid contents even in a case where the components are liquid components.

### [Resin Membrane Filter]

The resin membrane filter according to the embodiment of the present invention includes a first main surface, a second main surface, and a plurality of through-holes penetrating from the first main surface to the second main surface. In this case, in the through-hole, in a case where an average area of an opening portion at a position A which is located at a distance of 10% of a thickness of the resin membrane filter from the first main surface is denoted as Sva and an average area of an opening portion of the through-hole at a position B which is located at a distance of 90% of the thickness of the resin membrane filter from the first main surface is denoted as Svb, a relationship of the following expression (1) is satisfied.

0.8≤Sva/Svb≤1.25 Expression (1)

In addition, in the plurality of through-holes of the resin membrane filter according to the embodiment of the present invention, a number ratio Ra of through-holes in which an area of the opening portion at the position A is more than 1.25 times Sva is 3.0% or less, and a number ratio Rb of through-holes in which an area of the opening portion at the position B is more than 1.25 times Svb is 3.0% or less.

In the present specification, the case where the resin membrane filter satisfies the relationship of the expression (1) described above and the above-described number ratio Ra and the above-described number ratio Rb are 3.0% or less also referred to as “satisfying specific requirements”.

The mechanism for solving the problems of the present invention by satisfying the specific requirements with the resin membrane filter is not entirely clear, but the present inventors presume as follows.

In the resin membrane filter in the related art, which is obtained by forming through-holes by ion beam irradiation or laser irradiation, a required separation accuracy may not be obtained. The present inventor has found that the reason why the separation accuracy required in the above-described resin membrane filter is that more than a certain number of through-holes having a large area of an opening portion are present. More specifically, in a case where the through-holes are formed by the ion beam irradiation, variation in hole diameter of the through-holes is suppressed, but through-holes having a large hole diameter are formed with a certain probability due to overlapping ion beams because of variations in irradiation direction and/or irradiation position of ion beam. Therefore, it is predicted that this would cause a decrease in separation accuracy. In addition, in a case where the through-holes are formed by the laser irradiation, a temperature in a vicinity of a region irradiated with laser increases, the resin is melted, and as a result, it is predicted that the separation accuracy would be reduced.

In addition, the present inventor has found that the expansion of the opening area of these through-holes may cause a problem that toughness of the resin membrane filter is reduced. It is considered that, in a case where the toughness of the resin membrane filter is degraded, it affects, for example, separation accuracy after a long-term use.

On the other hand, as a result of intensive studies, the present inventor has found that, in a case where through-holes are formed in a resin membrane filter, by forming through-holes satisfying the above-described specific requirements, a resin membrane filter having excellent separation accuracy and excellent toughness is obtained.

Hereinafter, in the present specification, the fact that the separation accuracy and/or the toughness of the resin membrane filter is more excellent is also referred to as that “the effects of the present invention are more excellent”.

The resin membrane filter according to the embodiment of the present invention will be described in detail with reference to the drawings.

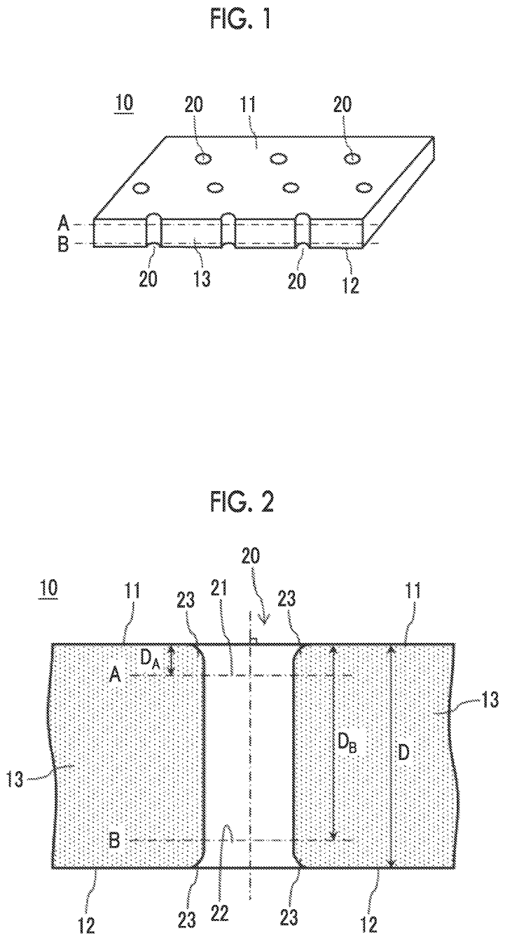

FIG. 1 is a schematic view (perspective view) showing an example of a structure of the resin membrane filter according to the embodiment of the present invention.

A plurality of through-holes 20 penetrating from a first main surface 11 to a second main surface 12 are formed in a resin membrane filter 10. In addition, FIG. 1 shows a cut plane 13 obtained by cutting the resin membrane filter 10 in a plane including an in-plane direction in which the plurality of through-holes 20 are arranged and a thickness direction of the resin membrane filter 10.

FIG. 2 is a schematic view showing an example of a structure of the through-hole 20 included in the resin membrane filter 10 shown in FIG. 1, and is a cross-sectional view of the resin membrane filter 10 in a plane including an extending direction of the through-hole 20 and the thickness direction of the resin membrane filter 10. As shown in FIG. 2, the through-hole 20 extends along the thickness direction of the resin membrane filter 10, in other words, a normal direction to the first main surface 11 and the second main surface 12.

In addition, at both end parts of the through-hole 20 on the first main surface 11 side and the second main surface 12 side, a curved portion 23 in which the hole diameter of the through-hole 20 increases as the curved portion approaches the opening end of the through-hole 20 is formed.

As shown in FIG. 2, a position of the through-hole 20, which is located at a distance D_{A} of 10% of a thickness D of the resin membrane filter 10 from the first main surface 11, is denoted as a position A, and a position of the through-hole 20, which is located at a distance D_{B} of 90% of the thickness D of the resin membrane filter 10 from the first main surface 11, is denoted as a position B. In the resin membrane filter 10 according to the embodiment of the present invention, in a case where an average area of an opening portion 21 of the through-hole 20 at the position A is denoted as Sva and an average area of an opening portion 22 of the through-hole 20 at the position B is denoted as Svb, the relationship of the expression (1) described above is satisfied.

In the resin membrane filter in which the Sva and Svb satisfy the expression (1), it is considered that the separation accuracy is further improved because the variation in opening area of the through-hole in the extending direction of the through-hole is suppressed. From the above viewpoint, it is preferable that the Sva and Svb satisfies the following expression (1a), and it is more preferable that the Sva and Svb satisfies the following expression (1b).

0.85≤Sva/Svb≤1.20 Expression (1a)

0.90≤Sva/Svb≤1.10 Expression (1b)

In addition, in the plurality of through-holes 20 of the resin membrane filter 10 according to the embodiment of the present invention, a number ratio Ra of through-holes in which an area of the opening portion 21 at the position A is more than 1.25 times Sva is 3.0% or less, and a number ratio Rb of through-holes in which an area of the opening portion 22 at the position B is more than 1.25 times Svb is 3.0% or less.

In the resin membrane filter in which the above-described number ratio Ra is 3.0% or less and the above-described number ratio Rb is 3.0% or less, variation in opening area of each through-hole is suppressed, and the number of through-holes having a clearly large opening area with respect to a desired opening area is small. As a result, it is considered that the separation accuracy and the toughness of the resin membrane filter are improved.

From the above-described viewpoint, both the above-described number ratio Ra and number ratio Rb are preferably 2.0% or less and more preferably 1.0% or less. The lower limit thereof is not particularly limited, but may be, for example, 0%.

As shown in FIG. 2, the area of the opening portion of the through-hole 20 at the position A is a cross-sectional area of a cut plane (opening portion 21) of the through-hole 20, which passes through the position A at the distance D_{A} of 10% of the thickness D from the first main surface 11 and is cut by a plane parallel to the first main surface 11. Similarly, the area of the opening portion of the through-hole 20 at the position B is a cross-sectional area of a cut plane (opening portion 22) of the through-hole 20, which passes through the position B at the distance D_{B} of 90% of the thickness D from the first main surface 11 and is cut by a plane parallel to the first main surface 11.

Each of Sva and Svb is an arithmetic mean value obtained by randomly selecting 100 through-holes from the through-holes included in the resin membrane filter, measuring the area of the opening portion at the position A and the area of the opening portion at the position B in the selected through-holes, and averaging the measured areas.

A detailed measuring method of the area of the opening portion at the position A and the area of the opening portion at the position B in the through-hole included in the resin membrane filter will be described in Examples later.

Returning to FIG. 1, a plurality of through-holes 20 are periodically arranged in the resin membrane filter 10. Specifically, the plurality of through-holes 20 are arranged at equal intervals in the in-plane direction of the resin membrane filter 10, and are arranged in a staggered pattern with an angle of 60°. That is, on the first main surface 11 (and the second main surface 12) of the resin membrane filter 10, three adjacent through-holes 20 form a lattice unit consisting of an equilateral triangle with an angle of 60°, and the formed lattice units constitute a staggered pattern. By arranging the plurality of through-holes at equal intervals in this manner, a resistance of liquid to pass through the resin membrane filter 10 can be reduced, and a formation of through-hole with an increased opening area due to overlapping of a plurality of through-holes can be suppressed.

The plurality of through-holes formed in the resin membrane filter are not limited to those arranged in the staggered pattern with an angle of 60° as long as the above-described specific requirements are satisfied, and the plurality of through-holes may be periodically arranged in other arrangements such as another staggered arrangement, a square grid arrangement, and a rectangular grid arrangement. In addition, the plurality of through-holes are not limited to those that are periodically arranged as long as the above-described specific requirements are satisfied, and the plurality of through-holes may not be periodically arranged.

It is preferable that the plurality of through-holes are arranged in a staggered pattern or in a square grid pattern in the in-plane direction of the resin membrane filter, and it is more preferable to be arranged in a staggered pattern with 60° in the in-plane direction of the resin membrane filter.

The arrangement of the plurality of through-holes in the resin membrane filter is appropriately designed according a shape of the through-hole and properties (size, form, property, elasticity, and the like) of an object of the resin membrane filter.

For example, in a case where the plurality of through-holes are periodically arranged at equal intervals in the in-plane direction as shown in FIG. 1, a pitch of the periodic arrangement of the through-holes is preferably 1 to 30 μm and more preferably 3 to 15 μm.

The “pitch” in the present specification means a period of a periodic structure included in the periodic pattern. In a case where the plurality of through-holes are periodically arranged in the in-plane direction of the resin membrane filter, the pitch means the sum of the hole diameter of the through-hole and the distance between the through-holes on a straight line along a direction in which the through-holes are periodically arranged (hereinafter, also referred to as “arrangement direction”).

The number of through-holes formed in the resin membrane filter is appropriately designed according to the shape and arrangement of the through-holes, and the properties of the object of the resin membrane filter.

The number of through-holes per area of the resin membrane filter is often 1×10⁴ holes/cm² or more, preferably 1×10⁵ holes/cm² or more and more preferably 1×10⁶ holes/cm² or more. The upper limit thereof not particularly limited but is often 1×10¹⁰ holes/cm² or less, preferably 1×10⁹ holes/cm² or less and more preferably 1×10⁸ holes/cm² or less.

### [Shape of Through-Hole]

Next, the shape of the through-hole included in the resin membrane filter will be described in detail.

The shape of the opening portion of the through-hole 20 shown in FIG. 1 is circular, but the shape of the opening portion of the through-hole is not limited to the circular shape, and may be an elliptical shape or a polygonal shape such as a square shape and a hexagonal shape. From the viewpoint that the mechanical strength is more excellent, the shape of the opening portion of the through-hole included in the resin membrane filter is preferably circular or elliptical, and from the viewpoint of improving the separation accuracy, it is more preferably circular.

In the present specification, the “shape of the opening portion” with regard to the through-hole formed in the resin membrane filter refers to an observed shape of a cut plane obtained by cutting the through-hole on the main surface of the resin membrane filter or on a plane parallel to the main surface, in a case of being observed from the normal direction to the main surface.

In addition, the through-hole 20 shown in FIGS. 1 and 2 extends along the normal direction to the first main surface 11 and the second main surface 12 of the resin membrane filter 10, but the extending direction of the through-hole is not limited to this direction.

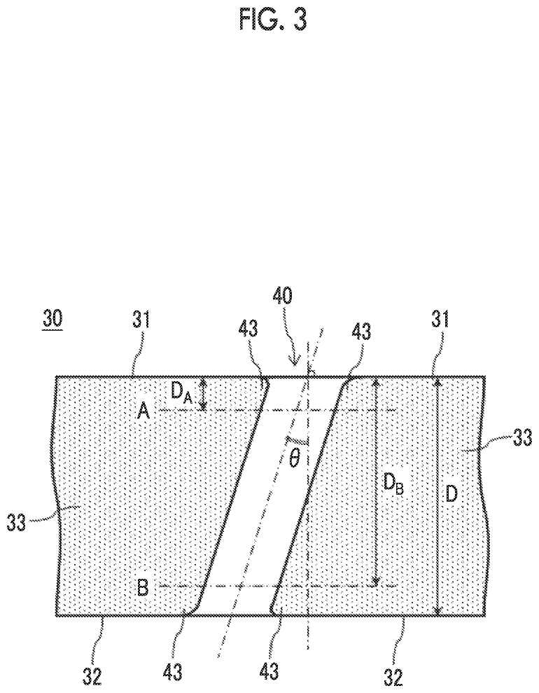

FIG. 3 shows another example of the structure of the through-hole which may be included in the resin membrane filter.

FIG. 3 is a cross-sectional view showing a structure of a through-hole 40 of a resin membrane filter 30 according to the embodiment of the present invention, and shows a shape of the through-hole 40 in a cross section 33 cut along a plane including an extending direction of the through-hole 40 and a thickness direction of the resin membrane filter 30.

The through-hole 40 shown in FIG. 3 extends along a direction forming an angle θ with respect to a normal direction to a first main surface 31 and a second main surface 32 of the resin membrane filter 30. In addition, at both end parts of the through-hole 40 on the first main surface 31 side and the second main surface 32 side, a curved portion 43 in which the hole diameter of the through-hole 40 increases as the curved portion approaches the opening end of the through-hole 40 is formed.

As described above, the resin membrane filter may include through-holes obliquely inclined with respect to the normal direction to the first main surface and the second main surface of the resin membrane filter.

In the plurality of through-holes included in the resin membrane filter, from the viewpoint that the toughness of the resin membrane is more excellent, a number ratio Rt of through-holes in which an angle (tilt angle of the through-holes) between the extending direction of the through-holes and the thickness direction of the resin membrane filter is within 5° is preferably 90% or more, more preferably 95% or more, and still more preferably 99.0% or more. The upper limit thereof is not particularly limited, and may be 100%.

A measuring method of the angle (tilt angle of the through-holes) between the extending direction of the through-holes included in the resin membrane filter and the thickness direction of the resin membrane filter will be described in Examples later.

An average hole diameter of the through-holes is not particularly limited, and is appropriately selected according the shape of the through-hole and properties (size, form, property, elasticity, and the like) of the object of the resin membrane filter. The average hole diameter of the through-holes is, for example, 20 μm or less, and from the viewpoint that the effects of the present invention are more excellent, it is preferably 10 μm or less and more preferably 5 μm or less. The lower limit thereof is not particularly limited, but from the viewpoint that the effects of the present invention are more excellent, it is preferably 0.05 μm or more and more preferably 1 μm or more.

In addition, in the plurality of through-holes included in the resin membrane filter, from the viewpoint that the effects of the present invention are more excellent, a number ratio Rr of through-holes in which a hole diameter is 0.9 to 1.1 times an average hole diameter of the through-holes is preferably 90% or more, more preferably 95% or more, and still more preferably 99% or more. The upper limit thereof is not particularly limited, and may be 100%.

Furthermore, in the resin membrane filter, from the viewpoint that the effects of the present invention are more excellent, a ratio of a standard deviation of hole diameters of the through-holes to the average hole diameter of the through-holes is preferably 5.0% or less, more preferably 3.0% or less, and still more preferably 1.0% or less. The lower limit value is not particularly limited, and may be 0%.

The “hole diameter” of the through-hole in the present specification means a hole diameter of an opening cross section, which is obtained by cutting the through-hole with a plane which is parallel to the main surface of the resin membrane filter and passes through the above-described position A. In a case where the shape of the opening cross section is circular, the hole diameter of the through-hole is a diameter of the circular opening cross section, and in a case where the shape of the opening cross section is other than circular, the hole diameter of the through-hole is an equivalent circle diameter of the opening cross section.

A method of deriving the average hole diameter of the through-holes and the standard deviation of the hole diameter of the through-holes will be described in Examples later.

In the through-hole included in the resin membrane filter, it is preferable that a curved portion in which the hole diameter of the through-hole increases as the curved portion approaches the opening end is formed in at least one end part of the first main surface side or the second main surface side.

In the curved portion, a curvature radius in a cut plane including the extending direction of the through-hole and the thickness direction of the resin membrane filter is preferably 0.1 μm or more and more preferably 1 μm or more. The upper limit thereof is not particularly limited, and is preferably 3 μm or less and more preferably 2 or μm or less.

A method of confirming the curved portion formed in the through-hole will be described in Examples later.

### [Physical Properties of Resin Membrane Filter]

A thickness of the resin membrane filter is not particularly limited, but from the viewpoint that the toughness is more excellent, it is preferably 5 μm or more, more preferably 8 μm or more, and still more preferably 10 μm or more. The upper limit thereof is not particularly limited, but from the viewpoint that the separation accuracy is more excellent, it is preferably 100 μm or less, more preferably 50 μm or less, and still more preferably 30 μm or less.

The thickness of the resin membrane filter is calculated as an average value of any five points measured by a cross-sectional observation with a scanning electron microscope (SEM).

In the resin membrane filter, a contact angle of at least one of the first main surface or the second main surface with water is often 10° to 90°, and from the viewpoint that the separation accuracy and the filtration speed are more excellent, it is preferably 10° to 70° and more preferably 10° to 50°.

The contact angle of the first main surface and the second main surface in the resin membrane filter with water is obtained by measuring a static contact angle (°) with water by a liquid droplet method using a contact angle meter (automatic contact angle meter “DMo-602”, manufactured by Kyowa Interface Science Co., Ltd.).

### [Composition of Resin Membrane Filter]

The resin membrane filter is, for example, a resin membrane formed of a photosensitive composition. Among these, a resin membrane manufactured by forming a photosensitive composition layer containing a photosensitive composition on a temporary support and then performing pattern exposure and development is preferable.

The resin membrane filter may include a layer other than the resin membrane formed of the photosensitive composition layer, but a filter consisting of the resin membrane formed of the photosensitive composition layer is preferable. That is, the resin membrane filter may be a composite membrane including the film formed from the photosensitive composition layer, but is preferably a single membrane formed from the photosensitive composition layer.

The resin membrane filter may be a cured membrane of a negative tone photosensitive composition layer or may be a resin membrane formed from a positive tone photosensitive composition layer. Among these, from the viewpoint that the toughness of the resin membrane filter is more excellent, a cured membrane of a negative tone photosensitive composition layer is preferable.

The negative tone photosensitive composition layer is a photosensitive composition layer having a solubility in a developer, which is decreased in an exposed region (exposed portion).

The positive tone photosensitive composition layer is a photosensitive composition layer in which, in a case where a photoacid generator is decomposed in an exposed region (exposed portion) to generate acid, a solubility of the exposed portion in an alkali aqueous solution is increased due to action of the generated acid.

It is preferable that the resin membrane filter contains at least one selected from the group consisting of a (meth)acrylic resin and an alkali-soluble resin as a binder polymer described later, and a polymerizable compound described later.

In addition, it is also preferable that the resin membrane filter contains a resin which has a constitutional unit having an acid group protected by an acid-decomposable group, which will be described later, and a photoacid generator described later.

Hereinafter, each component contained in the photosensitive composition used for manufacturing the resin membrane filter will be described in detail.

### <Binder Polymer>

The photosensitive composition may contain a binder polymer.

Examples of the binder polymer include a (meth)acrylic resin, a styrene resin, an epoxy resin, an amide resin, an amido epoxy resin, an alkyd resin, a phenol resin, an ester resin, a urethane resin, an epoxy acrylate resin obtained by a reaction of an epoxy resin and a (meth)acrylic acid, and acid-modified epoxy acrylate resin obtained by a reaction of an epoxy acrylate resin and acid anhydride.

From the viewpoint of excellent alkali developability and film formability, examples of one suitable aspect of the binder polymer include a (meth)acrylic resin.

In the present specification, the (meth)acrylic resin means a resin having a constitutional unit derived from a (meth)acrylic compound. A content of the constitutional unit derived from a (meth)acrylic compound may be 30% by mass or more with respect to all constitutional units of the (meth)acrylic resin, preferably 50% by mass or more, more preferably 70% by mass or more, and still more preferably 90% by mass or more.

The (meth)acrylic resin may be composed of only the constitutional unit derived from a (meth)acrylic compound, or may have a constitutional unit derived from a polymerizable monomer other than the (meth)acrylic compound. That is, the upper limit of the content of the constitutional unit derived from a (meth)acrylic compound is 100% by mass or less with respect to all constitutional units of the (meth)acrylic resin.

Examples of the (meth)acrylic compound include (meth)acrylic acid, (meth)acrylic acid ester, (meth)acrylamide, and (meth)acrylonitrile.

Examples of the (meth)acrylic acid ester include (meth)acrylic acid alkyl ester, (meth)acrylic acid tetrahydrofurfuryl ester, (meth)acrylic acid dimethylaminoethyl ester, (meth)acrylic acid diethylaminoethyl ester, (meth)acrylic acid glycidyl ester, (meth)acrylic acid benzyl ester, 2,2,2-trifluoroethyl (meth)acrylate, and 2,2,3,3-tetrafluoropropyl (meth)acrylate, and (meth)acrylic acid alkyl ester is preferable.

Examples of the (meth)acrylamide include acrylamides such as diacetone acrylamide.

An alkyl group of the (meth)acrylic acid alkyl ester may be linear or branched. Specific examples thereof include (meth)acrylic acid alkyl esters having an alkyl group having 1 to 12 carbon atoms, such as methyl (meth)acrylate, ethyl (meth)acrylate, propyl (meth)acrylate, butyl (meth)acrylate, pentyl (meth)acrylate, hexyl (meth)acrylate, heptyl (meth)acrylate, octyl (meth)acrylate, 2-ethylhexyl (meth)acrylate, nonyl (meth)acrylate, decyl (meth)acrylate, undecyl (meth)acrylate, and dodecyl (meth)acrylate.

As the (meth)acrylic acid ester, (meth)acrylic acid alkyl ester having an alkyl group having 1 to 4 carbon atoms is preferable, and methyl (meth)acrylate or ethyl (meth)acrylate is more preferable.

The (meth)acrylic resin may have a constitutional unit other than the constitutional unit derived from a (meth)acrylic compound.

The polymerizable monomer forming the above-described constitutional unit is not particularly limited as long as it is a compound other than the (meth)acrylic compound, which can be copolymerized with the (meth)acrylic compound, and examples thereof include styrene compounds which may have a substituent at an a-position or an aromatic ring, such as styrene, vinyltoluene, and α-methylstyrene, vinyl alcohol esters such as acrylonitrile and vinyl-n-butyl ether, maleic acid monoesters such as maleic acid, maleic acid anhydride, monomethyl maleate, monoethyl maleate, and monoisopropyl maleate, fumaric acid, cinnamic acid, α-cyanocinnamic acid, itaconic acid, and crotonic acid.

These polymerizable monomers may be used alone or in combination of two or more kinds thereof.

In addition, from the viewpoint of improving alkali developability, the (meth)acrylic resin preferably has a constitutional unit having an acid group. Examples of the acid group include a carboxy group, a sulfo group, a phosphoric acid group, and a phosphonic acid group.

Among these, the (meth)acrylic resin more preferably has a constitutional unit having a carboxy group, and still more preferably has a constitutional unit derived from the above-described (meth)acrylic acid.

From the viewpoint of excellent developability, the content of the constitutional unit having an acid group (preferably, the constitutional unit derived from (meth)acrylic acid) in the (meth)acrylic resin is preferably 10% by mass or more with respect to the total mass of the (meth)acrylic resin. In addition, the upper limit value thereof is not particularly limited, but from the viewpoint of excellent alkali resistance, is preferably 50% by mass or less and more preferably 40% by mass or less.

In addition, it is more preferable that the (meth)acrylic resin has a constitutional unit derived from the above-described (meth)acrylic acid alkyl ester.

In a case of having a constitutional unit derived from the (meth)acrylic acid alkyl ester, a content of the constitutional unit derived from (meth)acrylic acid alkyl ester in the (meth)acrylic resin is preferably 1% to 90% by mass, more preferably 1% to 50% by mass, and still more preferably 1% to 30% by mass with respect to all constitutional units of the (meth)acrylic resin.

As the (meth)acrylic resin, a resin having both the constitutional unit derived from (meth)acrylic acid and the constitutional unit derived from (meth)acrylic acid alkyl ester is preferable, and a resin composed only of the constitutional unit derived from (meth)acrylic acid and the constitutional unit derived from (meth)acrylic acid alkyl ester is more preferable.

In addition, as the (meth)acrylic resin, an acrylic resin which has a constitutional unit derived from methacrylic acid, a constitutional unit derived from methyl methacrylate, and a constitutional unit derived from ethyl acrylate is also preferable.

In addition, the (meth)acrylic resin preferably has at least one selected from the group consisting of a constitutional unit derived from methacrylic acid and a constitutional unit derived from methacrylic acid alkyl ester, and more preferably has both the constitutional unit derived from methacrylic acid and the constitutional unit derived from methacrylic acid alkyl ester.

The total content of the constitutional unit derived from methacrylic acid and the constitutional unit derived from methacrylic acid alkyl ester in the (meth)acrylic resin is preferably 40% by mass or more and more preferably 60% by mass or more with respect to all constitutional units of the (meth)acrylic resin. The upper limit is not particularly limited, and may be 100% by mass or less, preferably 80% by mass or less.

In addition, it is also preferable that the (meth)acrylic resin has at least one selected from the group consisting of a constitutional unit derived from methacrylic acid and a constitutional unit derived from methacrylic acid alkyl ester, and has at least one selected from the group consisting of a constitutional unit derived from acrylic acid and a constitutional unit derived from acrylic acid alkyl ester.

From the viewpoint that developability of the photosensitive composition layer is excellent in a case of manufacturing the resin membrane filter, the (meth)acrylic resin preferably has an ester group at a terminal.

The terminal portion of the (meth)acrylic resin is composed of a site derived from a polymerization initiator used in the synthesis. The (meth)acrylic resin having an ester group at the terminal can be synthesized by using a polymerization initiator which generates a radical having an ester group.

Examples of other suitable aspects of the binder polymer include an alkali-soluble resin.

From the viewpoint of developability, the binder polymer is preferably an alkali-soluble resin having an acid value of 60 mgKOH/g or more.

From the viewpoint that it is easy to form a strong membrane by thermally crosslinking with a crosslinking component by heating, the alkali-soluble resin is more preferably a resin (so-called a carboxy group-containing resin) having an acid value of 60 mgKOH/g or more and having a carboxy group, and still more preferably a (meth)acrylic resin (so-called a carboxy group-containing (meth)acrylic resin) having an acid value of 60 mgKOH/g or more and having a carboxy group.

In a case where the binder polymer is a (meth)acrylic resin having a carboxy group, for example, the three-dimensional crosslinking density can be increased by adding a thermal crosslinking compound such as a blocked isocyanate compound and thermally crosslinking In addition, in a case where the carboxy group of the resin having a carboxy group is anhydrous and hydrophobized, wet heat resistance can be improved.

The carboxy group-containing (meth)acrylic resin having an acid value of 60 mgKOH/g or more is not particularly limited as long as the above-described conditions of acid value are satisfied, and a known (meth)acrylic resin can be appropriately selected.

For example, a carboxy group-containing acrylic resin having an acid value of 60 mgKOH/g or more among polymers described in paragraph of JP2011-095716A, a carboxy group-containing acrylic resin having an acid value of 60 mgKOH/g or more among polymers described in paragraphs to of JP2010-237589A, and the like can be preferably used.

Examples of other suitable aspects of the alkali-soluble resin include a styrene-acrylic copolymer.

In the present specification, the styrene-acrylic copolymer refers to a resin having a constitutional unit derived from a styrene compound and a constitutional unit derived from a (meth)acrylic compound. The total content of the above-described constitutional unit derived from a styrene compound and the above-described constitutional unit derived from a (meth)acrylic compound is preferably 30% by mass or more and more preferably 50% by mass or more with respect to all constitutional units of the above-described copolymer.

In addition, the content of the constitutional unit derived from a styrene compound is preferably 1% by mass or more, more preferably 5% by mass or more, and still more preferably 5% to 80% by mass with respect to the all constitutional units of the above-described copolymer.

In addition, the content of the constitutional unit derived from the above-described (meth)acrylic compound is preferably 5% by mass or more, more preferably 10% by mass or more, and still more preferably 20% by mass to 95% by mass with respect to the all constitutional units of the above-described copolymer.

The alkali-soluble resin is not limited to the above-described aspects as long as it is a resin having alkali solubility. Examples of other suitable aspects of the alkali-soluble resin include an alkali-soluble urethane resin (for example, “PH-9001” manufactured by Taisei Fine Chemical Co., Ltd., and the like), a polyester urethane resin (for example, “VYLON UR-3500” manufactured by TOYOBO CO., LTD., and the like), and an organic-inorganic hybrid resin (“CO1VIPOCERAN SQ109” manufactured by Arakawa Chemical Industries, Ltd., and the like).

Examples of other suitable aspects of the binder polymer include a polymer having an aromatic ring structure, and a polymer having a constitutional unit having an aromatic ring structure is more preferable.

Examples of a monomer forming the constitutional unit having an aromatic ring structure include a monomer having an aralkyl group, styrene, and a polymerizable styrene derivative (for example, methylstyrene, vinyltoluene, tert-butoxystyrene, acetoxystyrene, 4-vinylbenzoic acid, styrene dimer, and styrene trimer). Among these, a monomer having an aralkyl group or styrene is preferable. Examples of the aralkyl group include a substituted or unsubstituted phenylalkyl group (excluding a benzyl group), and a substituted or unsubstituted benzyl group, and a substituted or unsubstituted benzyl group is preferable.

Examples of a monomer having the phenylalkyl group include phenylethyl (meth)acrylate.

Examples of a monomer having the benzyl group include (meth)acrylates having a benzyl group, such as benzyl (meth)acrylate and chlorobenzyl (meth)acrylate; and vinyl monomers having a benzyl group, such as vinylbenzyl chloride and vinylbenzyl alcohol. Among these, benzyl (meth)acrylate is preferable.

In a case where the binder polymer has the constitutional unit having an aromatic ring structure, a content of the constitutional unit having an aromatic ring structure is preferably 5% to 90% by mass, more preferably 10% to 70% by mass, and still more preferably 20% to 60% by mass with respect to the all constitutional units of the binder polymer.

In addition, the content of the constitutional unit having an aromatic ring structure in the binder polymer is preferably 5 to 70 mol %, more preferably 10 to 60 mol %, and still more preferably 20 to 60 mol % with respect to all constitutional units of the binder polymer.

In the present specification, in a case where the content of a “constitutional unit” is defined by a molar ratio, the “constitutional unit” is synonymous with the “monomer unit”. In addition, in the present specification, the “monomer unit” may be modified after polymerization by a polymer reaction or the like. The same applies to the following.

Examples of other suitable aspects of the binder polymer include a polymer having an aliphatic hydrocarbon ring structure. That is, the binder polymer preferably has a constitutional unit having an aliphatic hydrocarbon ring structure. The aliphatic hydrocarbon ring structure may be monocyclic or polycyclic. Among these, the binder polymer more preferably has a ring structure in which two or more aliphatic hydrocarbon rings are fused.

Examples of a ring constituting the aliphatic hydrocarbon ring structure in the constitutional unit having an aliphatic hydrocarbon ring structure include a tricyclodecane ring, a cyclohexane ring, a cyclopentane ring, a norbornane ring, and an isophorone ring.

Among these, a ring in which two or more aliphatic hydrocarbon rings are fused is preferable, and a tetrahydrodicyclopentadiene ring (tricyclo[5.2.1.0^{2,6}] decane ring) is more preferable.

Examples of a monomer forming the constitutional unit having an aliphatic hydrocarbon ring structure include dicyclopentanyl (meth)acrylate, cyclohexyl (meth)acrylate, and isobornyl (meth)acrylate.

The binder polymer may have one constitutional unit having an aliphatic hydrocarbon ring structure alone, or two or more kinds thereof.

In a case where the binder polymer has the constitutional unit having an aliphatic hydrocarbon ring structure, a content of the constitutional unit having an aliphatic hydrocarbon ring structure is preferably 5% to 90% by mass, more preferably 10% to 80% by mass, and still more preferably 20% to 70% by mass with respect to the all constitutional units of the binder polymer.

In addition, the content of the constitutional unit having an aliphatic hydrocarbon ring structure in the binder polymer is preferably 5 to 70 mol %, more preferably 10 to 60 mol %, and still more preferably 20 to 50 mol % with respect to all constitutional units of the binder polymer.

In a case where the binder polymer has the constitutional unit having an aromatic ring structure and the constitutional unit having an aliphatic hydrocarbon ring structure, the total content of the constitutional unit having an aromatic ring structure and the constitutional unit having an aliphatic hydrocarbon ring structure is preferably 10% to 90% by mass, more preferably 20% to 80% by mass, and still more preferably 40% to 75% by mass with respect to all constitutional units of the binder polymer.

In addition, the total content of the constitutional unit having an aromatic ring structure and the constitutional unit having an aliphatic hydrocarbon ring structure in the binder polymer is preferably 10 to 80 mol %, more preferably 20 to 70 mol %, and still more preferably 40 to 60 mol % with respect to all constitutional units of the binder polymer.

The binder polymer preferably has a constitutional unit having an acid group.

Examples of the above-described acid group include a carboxy group, a sulfo group, a phosphonic acid group, and a phosphoric acid group, and a carboxy group is preferable.

As the above-described constitutional unit having an acid group, constitutional units derived from (meth)acrylic acid is preferable, and a constitutional unit derived from methacrylic acid is more preferable.

The binder polymer may have one constitutional unit having an acid group alone, or two or more kinds thereof.

In a case where the binder polymer has the constitutional unit having an acid group, a content of the constitutional unit having an acid group is preferably 5% to 50% by mass, more preferably 5% to 40% by mass, and still more preferably 10% to 30% by mass with respect to the all constitutional units of the binder polymer.

In addition, the content of the constitutional unit having an acid group in the binder polymer is preferably 5 to 70 mol %, more preferably 10 to 50 mol %, and still more preferably 20 to 40 mol % with respect to all constitutional units of the binder polymer.

Furthermore, a content of the constitutional unit derived from (meth)acrylic acid in the binder polymer is preferably 5 to 70 mol %, more preferably 10 to 50 mol %, and still more preferably 20 to 40 mol % with respect to all constitutional units of the binder polymer.

The binder polymer preferably has a reactive group, and more preferably has a constitutional unit having a reactive group.

As the reactive group, a radically polymerizable group is preferable, and an ethylenically unsaturated group is more preferable. In addition, in a case where the binder polymer has an ethylenically unsaturated group, the binder polymer preferably has a constitutional unit having an ethylenically unsaturated group in the side chain.

In the present specification, the “main chain” represents a relatively longest binding chain in a molecule of a polymer compound constituting a resin, and the “side chain” represents an atomic group branched from the main chain.

As the ethylenically unsaturated group, an allyl group or a (meth)acryloxy group is more preferable.

Examples of the constitutional unit having a reactive group include those shown below, but the constitutional unit having a reactive group is not limited thereto.

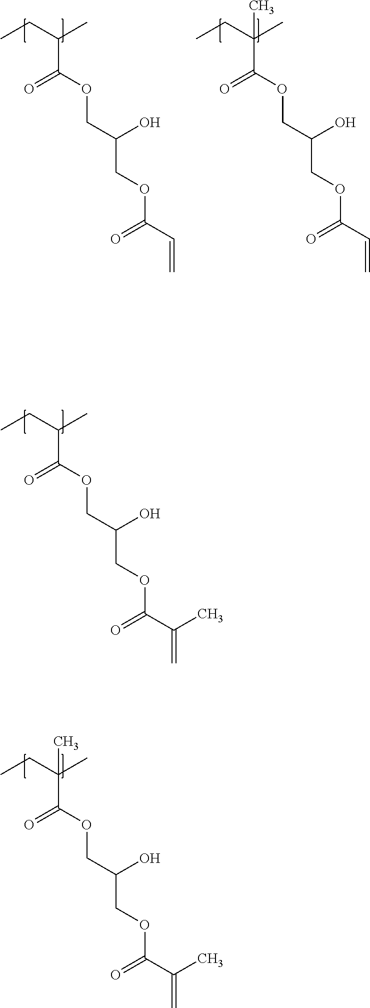

The binder polymer may have one constitutional unit having a reactive group alone, or two or more kinds thereof.

In a case where the binder polymer has the constitutional unit having a reactive group, a content of the constitutional unit having a reactive group is preferably 5% to 70% by mass, more preferably 10% to 50% by mass, and still more preferably 20% to 40% by mass with respect to the all constitutional units of the binder polymer.

In addition, the content of the constitutional unit having a reactive group in the binder polymer is preferably 5 to 70 mol %, more preferably 10 to 60 mol %, and still more preferably 20 to 50 mol % with respect to all constitutional units of the binder polymer.

Examples of a method for introducing the reactive group into the binder polymer include a method of reacting a compound such as an epoxy compound, a blocked isocyanate compound, an isocyanate compound, a vinyl sulfone compound, an aldehyde compound, a methylol compound, and a carboxylic acid anhydride with a functional group such as a hydroxy group, a carboxy group, a primary amino group, a secondary amino group, an acetoacetyl group, and a sulfo group.

Preferred examples of the method for introducing the reactive group into the binder polymer include a method in which a polymer having a carboxy group is synthesized by a polymerization reaction, and then a glycidyl (meth)acrylate is reacted with a part of the carboxy group of the obtained polymer by a polymer reaction, thereby introducing a (meth)acryloxy group into the polymer. By this method, a binder polymer having a (meth)acryloxy group in the side chain can be obtained.

The above-described polymerization reaction is preferably carried out under a temperature condition of 70° C. to 100° C., and more preferably carried out under a temperature condition of 80° C. to 90° C. As a polymerization initiator used in the above-described polymerization reaction, an azo-based initiator is preferable, and for example, V-601 (product name) or V-65 (product name) manufactured by FUJIFILM Wako Pure Chemical Corporation is more preferable. The above-described polymer reaction is preferably carried out under a temperature condition of 80° C. to 110° C. In the above-described polymer reaction, it is preferable to use a catalyst such as an ammonium salt.

Examples of other suitable aspects of the binder polymer include an epoxy resin having two or more thermally crosslinking groups. Examples of such an epoxy resin include an epoxy resin having two or more epoxy groups or oxetanyl groups in the molecule. More specific examples thereof include a bisphenol A-type epoxy resin, a bisphenol F-type epoxy resin, a phenol novolac-type epoxy resin, a cresol novolac-type epoxy resin, and an aliphatic epoxy resin.

### (Resin Which has Constitutional Unit Having Acid Group Protected by Acid-Decomposable Group)

In a case where the resin membrane filter is formed form the positive tone photosensitive composition, the positive tone photosensitive composition preferably contains a resin having an acid group protected by an acid-decomposable group.

The above-described resin having an acid group protected by an acid-decomposable group is preferably a polymer (hereinafter, also referred to as “polymer A”) which has a constitutional unit (hereinafter, also referred to as “constitutional unit A”) having an acid group protected by an acid-decomposable group.

In addition, the photosensitive composition may contain other polymers in addition to the polymer A having the constitutional unit A. In the present specification, the polymer A having the constitutional unit A and other polymers are also collectively referred to as “polymer component”.

In the above-described polymer A, due to action of a catalytic amount of an acidic substance generated upon exposure to light, the constitutional unit A having an acid group protected by an acid-decomposable group in the polymer A undergoes a deprotection reaction to be an acid group, and development with a developer can be performed.

It is preferable that all the polymers included in the above-described polymer component are polymers having at least a constitutional unit having an acid group, which will be described later. In addition, the above-described photosensitive resin composition layer may further contain a polymer other than these polymers. The above-described polymer component in the present specification is not particularly limited, and it is intended to include another polymer which is added as necessary.

The polymer A is preferably an addition polymerization type resin and more preferably a polymer having a constitutional unit derived from (meth)acrylic acid or an ester thereof. A constitutional unit other than the constitutional unit derived from (meth)acrylic acid or an ester thereof may include, for example, a constitutional unit derived from styrene and a constitutional unit derived from a vinyl compound.

### —Constitutional Unit A—

The constitutional unit A is a constitutional unit having an acid group protected by an acid-decomposable group.

Examples of the acid group protected by an acid-decomposable group include known acid groups and acid-decomposable groups.

Examples of the acid group include a carboxy group and a phenolic hydroxyl group. In addition, examples of the acid group protected by an acid-decomposable group include a group which is relatively easily decomposed by acid (for example, an acetal-based functional group such as a tetrahydropyranyl ester group and a tetrahydrofuranyl ester group), and a group which is relatively difficult to be decomposed by acid (for example, a tertiary alkyl group such as a tert-butyl ester group, and a tertiary alkyl carbonate group such as a tert-butyl carbonate group).

Among these, the above-described acid-decomposable group is preferably a group having a structure protected by an acetal-based functional group.

The constitutional unit A may be used alone, or in combination of two or more kinds thereof.

A content of the constitutional unit A is preferably 20.0% by mass or more, more preferably 20.0% to 90.0% by mass, and still more preferably 30.0% to 70.0% by mass with respect to the total mass of the polymer A.

In addition, a content of the monomer derived from the constitutional unit A is preferably 5.0% to 80.0% by mass, more preferably 10% to 80% by mass, and still more preferably 30% to 70% by mass with respect to the total mass of the polymer A.

### —Constitutional Unit B—

The polymer A may have a constitutional unit B having an acid group.

The constitutional unit B is an acid group which is not protected by a protective group, for example, an acid-decomposable group, that is, a constitutional unit having an acid group having no protective group. In a case where the polymer A includes the constitutional unit B, the polymer A is easily dissolved in an alkali developer in the developing step after the pattern exposure, whereby the development time can be shortened.

Examples of the constitutional unit B include the constitutional unit included in the alkali-soluble resin described above.

The constitutional unit B may be used alone, or in combination of two or more kinds thereof.

A content of the constitutional unit B is preferably 0.1% to 20.0%, more preferably 0.5% to 15.0% by mass, and still more preferably 1% to 10.0% by mass with respect to the total mass of the polymer A.

### —Other Constitutional Units—

The polymer A may include other constitutional units (hereinafter, also referred to as “constitutional unit C”) in addition to the constitutional units A and B described above.

Examples of a monomer forming the constitutional unit C include styrenes, a (meth)acrylic acid alkyl ester, a (meth)acrylic acid cyclic alkyl ester, a (meth)acrylic acid aryl ester, an unsaturated dicarboxylic acid diester, a bicyclic unsaturated compound, a maleimide compound, an unsaturated aromatic compound, a conjugated diene compound, an unsaturated monocarboxylic acid, an unsaturated dicarboxylic acid, an unsaturated dicarboxylic acid anhydride, a group having an aliphatic cyclic skeleton, and other unsaturated compounds.

The constitutional unit C is preferably a constitutional unit having an aromatic ring or a constitutional unit having an aliphatic cyclic skeleton.

In addition, the monomer forming the constitutional unit C is also preferably a (meth)acrylic acid alkyl ester, and more preferably a (meth)acrylic acid alkyl ester having an alkyl group having 4 to 12 carbon atoms.

The constitutional unit C may be used alone, or in combination of two or more kinds thereof.

A content of the constitutional unit C is preferably 70.0% by mass or less, more preferably 60.0% by mass or less, and still more preferably 50.0% by mass or less with respect to the total mass of the polymer A. The lower limit value thereof is preferably 0% by mass, more preferably 1.0% by mass or more, and still more preferably 5.0% by mass or more.

From the viewpoint of optimizing the solubility in a developer and the physical properties of the above-described photosensitive resin composition layer, it is also preferable that the polymer A includes, as the constitutional unit C, a constitutional unit having an ester of the acid group in the constitutional unit B described above.

A molecular weight of the polymer A is preferably 60,000 or less, more preferably 2,000 to 60,000, and still more preferably 3,000 to 50,000.

A dispersity (Mw/Mn) of the polymer A is preferably 1.0 to 5.0 and more preferably 1.05 to 3.5.

A production method of the polymer A is not particularly limited, and a known method may be used.

For example, the polymer A can be synthesized by polymerizing a monomer for forming the constitutional unit A, a monomer for forming the constitutional unit B having an acid group, and a monomer for forming the constitutional unit C in an organic solvent containing these monomers using a polymerization initiator.

The polymer A may be used alone, or in combination of two or more kinds thereof.

A content of the polymer A is preferably 50% to 99% by mass and more preferably 70% to 98% by mass with respect to the total mass of the photosensitive resin composition layer.

From the viewpoint that the toughness of the resin membrane filter is more excellent, a weight-average molecular weight (Mw) of the binder polymer is preferably 10,000 or more, more preferably 30,000 or more, still more preferably 50,000 to 200,000, and particularly preferably 50,000 to 120,000.

An acid value of the binder polymer is preferably 10 to 200 mgKOH/g, more preferably 60 to 200 mgKOH/g, still more preferably 60 to 150 mgKOH/g, and particularly preferably 70 to 130 mgKOH/g.

The acid value of the binder polymer is a value measured according to the method described in JIS K0070: 1992.

In addition, from the viewpoint of developability, a dispersity of the binder polymer is preferably 1.0 to 6.0, more preferably 1.0 to 5.0, still more preferably 1.0 to 4.0, and particularly preferably 1.0 to 3.0.

The photosensitive composition may contain only one kind of the binder polymer, or may include two or more kinds thereof.

From the viewpoint that the effects of the present invention are more excellent, a content of the binder polymer is preferably 10% to 90% by mass, more preferably 20% to 80% by mass, and still more preferably 30% to 80% by mass with respect to the total mass of the solid content of the photosensitive composition.

### <Polymerizable Compound>

The photosensitive composition may contain a polymerizable compound.

The polymerizable compound is a compound having a polymerizable group. Examples of the polymerizable group include a radically polymerizable group and a cationically polymerizable group, and a radically polymerizable group is preferable.

The polymerizable compound preferably includes a radically polymerizable compound having an ethylenically unsaturated group (hereinafter, also simply referred to as an “ethylenically unsaturated compound”).

As the ethylenically unsaturated group, a (meth)acryloxy group is preferable.

The ethylenically unsaturated compound in the present specification is a compound other than the above-described binder polymer, and preferably has a molecular weight of less than 5,000.

Examples of one suitable aspect of the polymerizable compound include a compound represented by Formula (M) (simply referred to as “compound M”).

Q²-R¹-Q¹ Formula (M)

In Formula (M), Q¹ and Q² each independently represent a (meth)acryloyloxy group, and R¹ represents a divalent linking group having a chain structure.

Q¹ and Q² in Formula (M) may be the same or different from each other, but from the viewpoint of easiness of synthesis, Q¹ and Q² preferably have the same group.

Examples of R¹ in Formula (M) include a hydrocarbon group, and an alkylene oxide (-L¹-O-) adduct of a hydrocarbon group, and from the viewpoint that the effects of the present invention are more excellent, a hydrocarbon group having 6 to 20 carbon atoms or an alkylene oxide (-L¹-O-) adduct of a hydrocarbon group is preferable.

It is sufficient that the above-described hydrocarbon group has a chain structure at least in part, and a portion other than the chain structure is not particularly limited. For example, the portion may be a branched chain, a cyclic or a linear alkylene group having 1 to 20 carbon atoms, an arylene group, an ether bond, or a combination thereof; and an alkylene group or a group in which two or more alkylene groups and one or more arylene groups are combined is preferable.

Examples of the alkylene oxide adduct of a hydrocarbon group include an alkyleneoxyalkylene group (-L¹-O-L¹-), a polyalkyleneoxyalkylene group (-(L¹-O)ₚ-L¹-), and alkylene oxide adducts of a hydrocarbon group, other than the polyalkyleneoxyalkylene group.

The L¹'s each independently represent an alkylene group, and an ethylene group, a propylene group, or a butylene group is preferable and an ethylene group or a 1,2-propylene group is more preferable. p represents an integer of 2 or more. p preferably represents an integer of 10 to 30.

In addition, from the viewpoint that the effects of the present invention are more excellent, the number of atoms in the shortest linking chain which links Q¹ and Q² in the compound M is preferably 20 to 150, more preferably 30 to 120, and still more preferably 40 to 90.

In the present specification, the “number of atoms in the shortest linking chain which links Q¹ and Q²” is the shortest number of atoms linking from an atom in R¹ linked to Q¹ to an atom in R¹ linked to Q².

Specific examples of the compound M include 1,6-hexanediol di(meth)acrylate, 1,7-heptanediol di(meth)acrylate, 1,8-octanediol di(meth)acrylate, 1,9-nonanediol di(meth)acrylate, 1,10-decanediol di(meth)acrylate, 1,4-cyclohexanediol di(meth)acrylate; bisphenol A di(meth)acrylate, hydrogenated bisphenol A di(meth)acrylate, or an ethylene oxide/propylene oxide adduct thereof; bisphenol F di(meth)acrylate, hydrogenated bisphenol F di(meth)acrylate, or an ethylene oxide/propylene oxide adduct thereof; polyethylene glycol di(meth)acrylate, polypropylene glycol di(meth)acrylate, poly(ethylene glycol/propylene glycol) di(meth)acrylate, and polybutylene glycol di(meth)acrylate. The above-described ester monomers can also be used as a mixture.

In addition, examples of one suitable aspect of the polymerizable compound include a bi- or higher functional ethylenically unsaturated compound.

In the present specification, the “bi- or higher functional ethylenically unsaturated compound” means a compound having two or more ethylenically unsaturated groups in one molecule.

As the ethylenically unsaturated group in the ethylenically unsaturated compound, a (meth)acryloyl group is preferable. That is, as the ethylenically unsaturated compound, a (meth)acrylate compound is preferable.

The bifunctional ethylenically unsaturated compound is not particularly limited and can be appropriately selected from a known compound.

Examples of the bifunctional ethylenically unsaturated compound other than the above-described compound M include tricyclodecane dimethanol di(meth)acrylate, dioxane glycol di(meth)acrylate, and 1,4-cyclohexanediol di(meth)acrylate.

Examples of a commercially available product of the bifunctional ethylenically unsaturated compound include tricyclodecane dimethanol diacrylate (product name NK ESTER A-DCP, manufactured by Shin-Nakamura Chemical Co., Ltd.), tricyclodecane dimethanol dimethacrylate (product name: NK ESTER DCP, manufactured by Shin-Nakamura Chemical Co., Ltd.), 1,9-nonanediol diacrylate (product name: NK ESTER A-NOD-N, manufactured by Shin-Nakamura Chemical Co., Ltd.), 1,6-hexanediol diacrylate (product name: NK ESTER A-HD-N, manufactured by Shin-Nakamura Chemical Co., Ltd.), ethoxylated bisphenol A dimethacrylate (product name: NK ESTER BPE-500 and 900, manufactured by Shin-Nakamura Chemical Co., Ltd.), polyethylene glycol dimethacrylate (product name: NK ESTER 23G, manufactured by Shin-Nakamura Chemical Co., Ltd.), and dioxane glycol diacrylate (KAYARAD R-604 manufactured by Nippon Kayaku Co., Ltd.).

The tri- or higher functional ethylenically unsaturated compound is not particularly limited and can be appropriately selected from a known compound.

Examples of the tri- or higher functional ethylenically unsaturated compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

Here, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the polymerizable compound also include a urethane (meth)acrylate compound.

Examples of the urethane (meth)acrylate include urethane di(meth)acrylate, and examples thereof include propylene oxide-modified urethane di(meth)acrylate and ethylene oxide and propylene oxide-modified urethane di(meth)acrylate.

In addition, examples of the urethane (meth)acrylate also include tri- or higher functional urethane (meth)acrylate. The lower limit of the number of functional groups is more preferably 6 or more and still more preferably 8 or more. The upper limit of the number of functional groups is preferably 20 or less. Examples of the tri- or higher functional urethane (meth)acrylate include 8UX-015A (manufactured by Taisei Fine Chemical Co., Ltd.); NK OLIGO UA-32P, U-15HA, UA-122P, UA-160TM, and UA-1100H (all manufactured by Shin-Nakamura Chemical Co., Ltd.); AH-600 (manufactured by KYOEISHA CHEMICAL Co., LTD.); and UA-306H, UA-306T, UA-306I, UA-510H, and UX-5000 (all manufactured by Nippon Kayaku Co., Ltd.).

Examples of one suitable aspect of the polymerizable compound include an ethylenically unsaturated compound having an acid group.

Examples of the acid group include a phosphoric acid group, a sulfo group, and a carboxy group.

Among these, as the acid group, a carboxy group is preferable.

Examples of the ethylenically unsaturated compound having an acid group include a tri- or tetra-functional ethylenically unsaturated compound having an acid group [component obtained by introducing a carboxy group to pentaerythritol tri- and tetra-acrylate (PETA) skeleton (acid value: 80 to 120 mgKOH/g)), and a penta- or hexa-functional ethylenically unsaturated compound having an acid group [component obtained by introducing a carboxy group to dipentaerythritol penta- and hexa-acrylate (DPHA) skeleton (acid value: 25 to 70 mgKOH/g)].

The tri- or higher functional ethylenically unsaturated compound having an acid group may be used in combination with the bifunctional ethylenically unsaturated compound having an acid group, as necessary.

As the ethylenically unsaturated compound having an acid group, polymerizable compounds having an acid group, which are described in paragraphs [0025] to [0030] of JP2004-239942A, are preferable, and the contents described in this publication are incorporated in the present specification.

Examples of the polymerizable compound also include a compound obtained by reacting a polyhydric alcohol with an α,β-unsaturated carboxylic acid, a compound obtained by reacting a glycidyl group-containing compound with an α,β-unsaturated carboxylic acid, urethane monomer such as a (meth)acrylate compound having a urethane bond, phthalate compounds such as γ-chloro-β-hydroxypropyl-β′-(meth)acryloyloxyethyl-o-phthalate, β-hydroxyethyl-β′-(meth)acryloyloxyethyl-o-phthalate, and β-hydroxypropyl-β′-(meth)acryloyloxyethyl-o-phthalate, and (meth)acrylic acid alkyl esters.

These compounds may be used alone or in combination of two or more kinds thereof.

Examples of the polymerizable compound also include a caprolactone-modified compound of ethylenically unsaturated compound (for example, KAYARAD (registered trademark) DPCA-20 manufactured by Nippon Kayaku Co., Ltd., A-9300-1CL manufactured by Shin-Nakamura Chemical Co., Ltd., and the like), an alkylene oxide-modified compound of ethylenically unsaturated compound (for example, KAYARAD RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., and the like), and ethoxylated glycerin triacrylate (A-GLY-9E manufactured by Shin-Nakamura Chemical Co., Ltd., and the like).

As the polymerizable compound (particularly, the ethylenically unsaturated compound), from the viewpoint that the developability of the photosensitive composition layer is excellent in a case of manufacturing the resin membrane filter, an ethylenically unsaturated compound including an ester bond is also preferable.

The ethylenically unsaturated compound including an ester bond is not particularly limited as long as it includes an ester bond in the molecule, but from the viewpoint that the effect of the present invention is excellent, an ethylenically unsaturated compound having a tetramethylolmethane structure or a trimethylolpropane structure is preferable, and tetramethylolmethane tri(meth)acrylate, tetramethylolmethane tetra(meth)acrylate, trimethylolpropane tri(meth)acrylate, or di(trimethylolpropane) tetraacrylate is more preferable.

As the ethylenically unsaturated compound, from the viewpoint of imparting reliability, it is preferable to include an ethylenically unsaturated compound having an aliphatic group having 6 to 20 carbon atoms and the above-described ethylenically unsaturated compound having a tetramethylolmethane structure or a trimethylolpropane structure.

Examples of the ethylenically unsaturated compound having an aliphatic structure having 6 or more carbon atoms include 1,9-nonanediol di(meth)acrylate, 1,10-decanediol di(meth)acrylate, and tricyclodecane dimethanol di(meth)acrylate.

A molecular weight of the polymerizable compound is preferably 200 to 3,000, more preferably 250 to 2,600, still more preferably 280 to 2,200, and particularly preferably 300 to 2,200.

A proportion of a content of a polymerizable compound having a molecular weight of 300 or less in the polymerizable compounds contained in the photosensitive composition is preferably 30% by mass or less, more preferably 25% by mass or less, and still more preferably 20% by mass or less with respect to the content of all the polymerizable compounds contained in the photosensitive composition.

As one suitable aspect of the photosensitive composition, the photosensitive composition preferably contains the bi- or higher functional ethylenically unsaturated compound, more preferably contains the bifunctional ethylenically unsaturated compound.

In addition, as one suitable aspect of the photosensitive composition, it is more preferable that the photosensitive composition contains the compound represented by Formula (M) and a blocked isocyanate compound described later.

The photosensitive composition may contain a monofunctional ethylenically unsaturated compound as the ethylenically unsaturated compound.

A content of the bi- or higher functional ethylenically unsaturated compound in the above-described ethylenically unsaturated compound is preferably 60% to 100% by mass, more preferably 80% to 100% by mass, and still more preferably 90% to 100% by mass with respect to the total content of all ethylenically unsaturated compounds contained in the photosensitive composition.

The polymerizable compound (particularly, the ethylenically unsaturated compound) may be used alone, or in combination of two or more kinds thereof.

A content of the polymerizable compound (particularly, the ethylenically unsaturated compound) in the photosensitive composition is preferably 1% by mass to 70% by mass, more preferably 5% by mass to 70% by mass, still more preferably 5% by mass to 60% by mass, and particularly preferably 5% by mass to 50% by mass with respect to the total mass of the solid content of the photosensitive composition.

In order to make the size of the through-hole more uniform and to further improve the separation accuracy, a ratio of the content of the polymerizable compound to the content of the binder polymer in the photosensitive composition is, in terms of mass ratio, preferably 40% or more, more preferably 50% or more, and still more preferably 60% or more. The upper limit thereof is not particularly limited, from the viewpoint that flexibility of the resin membrane filter is further improved and the toughness is more excellent, it is, in terms of mass ratio, preferably 150% or less, more preferably 120% or less, and still more preferably 100% or less.

### <Polymerization Initiator>

The photosensitive composition may contain a polymerization initiator.

As the polymerization initiator, a photopolymerization initiator is preferable.

The photopolymerization initiator is not particularly limited and a known photopolymerization initiator can be used.

Examples of the photopolymerization initiator include a photopolymerization initiator having an oxime ester structure (hereinafter, also referred to as an “oxime-based photopolymerization initiator”), a photopolymerization initiator having an α-aminoalkylphenone structure (hereinafter, also referred to as an “α-aminoalkylphenone-based photopolymerization initiator”), a photopolymerization initiator having an α-hydroxyalkylphenone structure (hereinafter also referred to as an “α-hydroxyalkylphenone-based polymerization initiator”), a photopolymerization initiator having an acylphosphine oxide structure, (hereinafter, also referred to as an “acylphosphine oxide-based photopolymerization initiator”), and a photopolymerization initiator having an N-phenylglycine structure (hereinafter, also referred to as an “N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based polymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators disclosed in paragraphs [0031] to [0042] of JP2011-095716A and paragraphs [0064] to [0081] of JP2015-014783A may be used.

Examples of a commercially available product of the photopolymerization initiator include 1-[4-(phenylthio)phenyl]-1,2-octanedione-2-(O-benzoyloxime) [product name: IRGACURE (registered trademark) OXE-01, manufactured by BASF SE], 1-[9-ethyl-6-(2-methylbenzoyl)-9H-carbazol-3-yl]ethanone-1-(O-acetyloxime) [product name: IRGACURE (registered trademark) OXE-02, manufactured by BASF SE], IRGACURE (registered trademark) OXE03 (manufactured by BASF SE), IRGACURE (registered trademark) OXE04 (manufactured by BASF SE), IRGACURE (registered trademark) 307 (manufactured by BASF SE), IRGACURE (registered trademark) 379 (manufactured by BASF SE), 2-(dimethylamino)-2-[(4-methylphenyl)methyl]-1-[4-(4-morpholinyl)phenyl]-1-butanone [product name: Omnirad (registered trademark) 379EG, manufactured by IGM Resins B.V.], 2-methyl-1-(4-methylthiophenyl)-2-morpholinopropan-1-one [product name: Omnirad (registered trademark) 907, manufactured by IGM Resins B.V.], 2-hydroxy-1-{4-[4-(2-hydroxy-2-methylpropionyl)benzyl]phenyl}-2-methylpropan-1-one [product name: Omnirad (registered trademark) 127, manufactured by IGM Resins B.V.], 2-benzyl-2-dimethylamino-1-(4-morpholinophenyl)butanone-1 [product name: Omnirad (registered trademark) 369, manufactured by IGM Resins B.V.], 2-hydroxy-2-methyl-1-phenylpropan-1-one [product name: Omnirad (registered trademark) 1173, manufactured by IGM Resins B.V.], 1-hydroxy cyclohexyl phenyl ketone [product name: Omnirad (registered trademark) 184, manufactured by IGM Resins B.V.], 2,2-dimethoxy-1,2-diphenylethan-1-one (product name: Omnirad (registered trademark) 651, manufactured by IGM Resins B.V.], an oxime ester-based photopolymerization initiator [product name: Lunar (registered trademark) 6, manufactured by DKSH Management Ltd.], 1-[4-(phenylthio)phenyl]-3-cyclopentylpropan-1,2-dione-2-(O-benzoyloxime) (product name: TR-PB G-305, manufactured by TRONLY), 1,2-propanedione, 3-cyclohexyl-1-[9-ethyl-6-(2-furanylcarbonyl)-9H-carbazole-3-yl]2-(O-acetyloxime) (product name: TR-PBG-326, manufactured by TRONLY), 3-cyclohexyl-1-(6-(2-(benzoyloxyimino)hexanoyl)-9-ethyl-9H-carbazole-3-yl)-propan-1,2-dio ne-2-(O-benzoyloxime) (product name: TR-PBG-391, manufactured by TRONLY), APi-307 (1-(biphenyl-4-yl)-2-methyl-2-morpholinopropan-1-one, manufactured by Shenzhen UV-ChemTech Co., Ltd.), and 2,2′-bis(2-chlorophenyl)-4,4′,5,5′-tetraphenyl-1,2′-biimidazole (HABI).

The photopolymerization initiator may be used alone or in combination of two or more kinds thereof. In a case of using two or more kinds thereof, it is preferable to use at least one selected from the oxime-based photopolymerization initiator, the α-aminoalkylphenone-based polymerization initiator, or the α-hydroxyalkylphenone-based photopolymerization initiator.

In a case where the photosensitive composition contains the photopolymerization initiator, a content of the photopolymerization initiator is preferably 0.1% by mass or more, more preferably 0.5% by mass or more, and still more preferably 1.0% by mass or more with respect to the total mass of the solid content of the photosensitive composition. In addition, the upper limit value thereof is preferably 10% by mass or less and more preferably 5% by mass or less with respect to the total mass of the solid content of the photosensitive composition.

### <Photoacid Generator>

The photosensitive composition may contain a photoacid generator.

In a case where the photosensitive composition contains the above-described resin which has a constitutional unit having an acid group protected by an acid-decomposable group, the photosensitive composition preferably contains a photoacid generator.

The photoacid generator (photocationic polymerization initiator) is a compound which receives actinic rays to generate an acid. The photoacid generator is preferably a compound which is sensitive to actinic rays having a wavelength of 300 nm or more (more preferably, a wavelength of 300 to 450 nm), and generates an acid, and a chemical structure thereof is not limited. A photo-acid generator which is not directly sensitive to actinic rays having a wavelength of 300 nm or more can also be used in combination with a sensitizer as long as it is a compound which is sensitive to actinic rays having a wavelength of 300 nm or more and generates an acid by being used in combination with the sensitizer.

The photo-acid generator is preferably a photo-acid generator which generates an acid with a pKa of 4 or less, more preferably a photo-acid generator which generates an acid with a pKa of 3 or less, and even more preferably a photo-acid generator which generates an acid with a pKa of 2 or less. The lower limit value of the pKa is not particularly limited, but is preferably −10.0 or more.

Examples of the photoacid generator include an ionic photoacid generator and a nonionic photoacid generator.

Examples of the ionic photoacid generator include onium salt compounds such as diaryliodonium salts and triarylsulfonium salts, and quaternary ammonium salts. In addition, as the ionic photoacid generator, ionic photoacid generators described in paragraphs [0114] to [0133] of JP2014-085643A may be used.

Examples of the nonionic photoacid generator include trichloromethyl-s-triazines, a diazomethane compound, an imide sulfonate compound, and an oxime sulfonate compound. As the trichloromethyl-s-triazines, the diazomethane compound, and the imide sulfonate compound, compounds described in paragraphs [0083] to [0088] of JP2011-221494A may be used. In addition, as the oxime sulfonate compound, compounds described in paragraphs [0084] to [0088] of WO2018/179640A may be used.

From the viewpoint of sensitivity and resolution, the photoacid generator also preferably includes at least one compound selected from the group consisting of an onium salt compound and an oxime sulfonate compound, and from the viewpoint of sensitivity, resolution, and adhesiveness, more preferably include an oxime sulfonate compound.

The photoacid generator may be used alone, or in combination of two or more kinds thereof.

In a case where the photosensitive composition contains the photoacid generator, a content of the photoacid generator is preferably 0.1% to 30.0% by mass, more preferably 0.1% to 20.0% by mass, and still more preferably 0.5% to 15.0% by mass with respect to the total mass of the solid content of the photosensitive composition.

### <Thermal Crosslinking Compound>

From the viewpoint of hardness of a cured membrane to be obtained and pressure-sensitive adhesiveness of an uncured membrane to be obtained, the photosensitive composition preferably contains a thermal crosslinking compound. In the present specification, a thermal crosslinking compound having an ethylenically unsaturated group, which will be described later, is not treated as the ethylenically unsaturated compound, but is treated as the thermal crosslinking compound.

Examples of the thermal crosslinking compound include an epoxy compound, an oxetane compound, a methylol compound, and a blocked isocyanate compound. Among these, from the viewpoint of hardness of a cured membrane to be obtained and pressure-sensitive adhesiveness of an uncured membrane to be obtained, a blocked isocyanate compound is preferable.

Since the blocked isocyanate compound reacts with a hydroxy group and a carboxy group, for example, in a case where at least one of the binder polymer or the radically polymerizable compound having an ethylenically unsaturated group has at least one of a hydroxy group or a carboxy group, hydrophilicity of the formed membrane tends to decrease, and the function as a protective membrane tends to be strengthened.

The blocked isocyanate compound refers to a “compound having a structure in which the isocyanate group of isocyanate is protected (so-called masked) with a blocking agent”.

A dissociation temperature of the blocked isocyanate compound is not particularly limited, but is preferably 90° C. to 160° C. and more preferably 100° C. to 150° C.

The dissociation temperature of blocked isocyanate means “temperature at an endothermic peak accompanied with a deprotection reaction of blocked isocyanate, in a case where the measurement is performed by differential scanning calorimetry (DSC) analysis using a differential scanning calorimeter”.

As the differential scanning calorimeter, for example, a differential scanning calorimeter (model: DSC6200) manufactured by Seiko Instruments Inc. can be suitably used. However, the differential scanning calorimeter is not limited thereto.

Examples of the blocking agent having a dissociation temperature of 100° C. to 160° C. include an active methylene compound [diester malonates (dimethyl malonate, diethyl malonate, di-n-butyl malonate, di-2-ethylhexyl malonate, and the like)], and an oxime compound (compound having a structure represented by —C(═N—OH)— in a molecule, such as formaldoxime, acetoaldoxime, acetoxime, methyl ethyl ketoxime, and cyclohexanoneoxime).

Among these, from the viewpoint of storage stability, the blocking agent having a dissociation temperature of 90° C. to 160° C. is preferably, for example, at least one selected from an oxime compound and a pyrazole compound.

From the viewpoint of improving brittleness of the membrane and improving the adhesion to the object to be transferred, for example, the blocked isocyanate compound preferably has an isocyanurate structure.

The blocked isocyanate compound having an isocyanurate structure can be obtained, for example, by isocyanurate-forming and protecting hexamethylene diisocyanate.

Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

The blocked isocyanate compound may have a polymerizable group.

The polymerizable group is not particularly limited, and a known polymerizable group can be used, and a radically polymerizable group is preferable.

Examples of the polymerizable group include a (meth)acryloxy group, a (meth)acrylamide group, an ethylenically unsaturated group such as styryl group, and an epoxy group such as a glycidyl group.

Among these, as the polymerizable group, an ethylenically unsaturated group is preferable, a (meth)acryloxy group is more preferable, and an acryloxy group is still more preferable.

As the blocked isocyanate compound, a commercially available product can be used.

Examples of the commercially available product of the blocked isocyanate compound include Karenz (registered trademark) AOI-BM, Karenz (registered trademark) MOI-BM, Karenz (registered trademark) MOI-BP, and the like (all of which are manufactured by SHOWA DENKO K.K.), and block-type DURANATE series (for example, DURANATE (registered trademark) TPA-B80E, DURANATE (registered trademark) SBN-70D, DURANATE (registered trademark) WT32-B75P, and the like manufactured by Asahi Kasei Corporation).

An NCO value of the blocked isocyanate compound is preferably 4.5 mmol/g or more, more preferably 5.0 mmol/g or more, and still more preferably 5.3 mmol/g or more. The upper limit value of the NCO value of the blocked isocyanate compound is preferably 8 0 mmol/g or less, more preferably 6.0 mmol/g or less, still more preferably less than 5.8 mmol/g, and particularly preferably 5.7 mmol/g or less.

The NCO value of the blocked isocyanate compound means the number of moles of isocyanate groups included in 1 g of the blocked isocyanate compound, and is a value calculated from the structural formula of the blocked isocyanate compound.

As the thermal crosslinking compound, from the viewpoint that the hydrophilicity and flexibility of the resin membrane filter are more excellent, it is also preferable to use an epoxy-based thermal crosslinking compound. Examples of the epoxy-based thermal crosslinking compound include a compound having two or more epoxy groups or oxetanyl groups in the molecule.

As the epoxy-based thermal crosslinking compound, a commercially available product can be used. Examples of a commercially available product of the epoxy-based thermal crosslinking compound include JER152, JER157S70, JER157S65, JER806, JER828, and JER1007 (manufactured by Mitsubishi Chemical Holdings Corporation); commercially available products described in paragraph 0189 of JP2011-221494A; DENACOL (registered trademark) EX series and DENACOL (registered trademark) DLC series (all manufactured by Nagase ChemteX Corporation); and YH-300, YH-301, YH-302, YH-315, YH-324, and YH-325 (all manufactured by Nippon Steel Chemical Co., Ltd.).

One thermal crosslinking compound may be used alone, or two or more kinds of thermal crosslinking compounds may be used in combination.

In a case where the photosensitive composition contains the thermal crosslinking compound, a content of the thermal crosslinking compound is preferably 1% to 50% by mass and more preferably 5% to 30% by mass with respect to the total mass of the solid content of the photosensitive composition.

### <Surfactant>

The photosensitive composition may contain a surfactant.

Examples of the surfactant include surfactants described in paragraph of [0017] of JP4502784B and paragraphs [0060] to [0071] of JP2009-237362A.

As the surfactant, a nonionic surfactant, a fluorine-based surfactant, or a silicone-based surfactant is preferable.

Examples of a commercially available product of the fluorine-based surfactant include: MEGAFACE F-171, F-172, F-173, F-176, F-177, F-141, F-142, F-143, F-144, F-437, F-475, F-477, F-479, F-482, F-551A, F-552, F-554, F-555-A, F-556, F-557, F-558, F-559, F-560, F-561, F-565, F-563, F-568, F-575, F-780, EXP, MFS-330, EXP.MFS-578, EXP.MFS-579, EXP.MFS-586, EXP.MFS-587, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (all of which are manufactured by NEOS COMPANY LIMITED).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily (Feb. 22, 2016) and Nikkei Business Daily (Feb. 23, 2016)), for example, MEGAFACE DS-21.

In addition, as the fluorine-based surfactant, a polymer of a fluorine atom-containing vinyl ether compound having a fluorinated alkyl group or a fluorinated alkylene ether group, and a hydrophilic vinyl ether compound can also be preferably used.

In addition, as the fluorine-based surfactant, a block polymer can also be used.

In addition, as the fluorine-based surfactant, a fluorine-containing polymer compound including a constitutional unit derived from a (meth)acrylate compound having a fluorine atom and a constitutional unit derived from a (meth)acrylate compound having 2 or more (preferably 5 or more) alkyleneoxy groups (preferably ethyleneoxy groups or propyleneoxy groups) can also be preferably used.

In addition, as the fluorine-based surfactant, a fluorine-containing polymer having an ethylenically unsaturated bond-containing group in the side chain can also be used. Examples thereof include MEGAFACE RS-101, RS-102, RS-718K, and RS-72-K (all manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC (registered trademark) L10, L31, L61, L62, 10R5, 17R2, and 25R2 (all manufactured by BASF SE), TETRONIC 304, 701, 704, 901, 904, and 150R1 (all manufactured by BASF SE), SOLSPERSE 20000 (manufactured by Lubrizol Corporation), NCW-101, NCW-1001, and NCW-1002 (all manufactured by FUJIFILM Wako Pure Chemical Corporation), PIONIN D-6112, D-6112-W, and D-6315 (all manufactured by Takemoto Oil&Fat Co., Ltd.), and OLFINE E1010 and SURFYNOL 104, 400, and 440 (all manufactured by Nissin Chemical Co., Ltd.).

Examples of the silicone-based surfactant include a linear polymer consisting of a siloxane bond and a modified siloxane polymer with an organic group introduced in the side chain or the terminal.

Specific examples of the silicone-based surfactant include DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH3OPA, and TORAY SILICONE SH8400 (all of which are manufactured by Dow Corning Toray Co., Ltd.), X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all of which are manufactured by Shin-Etsu Chemical Co., Ltd.), F-4440, TSF-4300, TSF-4445, TSF-4460, and TSF-4452 (all of which are manufactured by Momentive Performance Materials Co., Ltd.), and BYK307, BYK323, and BYK330 (all of which are manufactured by BYK Chemie).

One surfactant may be used alone, or two or more kinds of surfactants may be used in combination.

In a case where the photosensitive composition contains the surfactant, a content of the surfactant is preferably 0.01% to 3.0% by mass, more preferably 0.01% to 1.0% by mass, and still more preferably 0.05% to 0.80% by mass with respect to the total mass of the solid content of the photosensitive composition.

### <Polymerization Inhibitor>

The photosensitive composition may contain a polymerization inhibitor.

The polymerization inhibitor means a compound having a function of delaying or prohibiting a polymerization reaction. As the polymerization inhibitor, for example, a known compound used as a polymerization inhibitor can be used.

From the viewpoint that the opening area of the through-hole formed in the resin membrane filter is more uniform, further improving the separation accuracy of the resin membrane filter, the photosensitive composition preferably contains the polymerization inhibitor.

Examples of the polymerization inhibitor include phenothiazine compounds such as phenothiazine, bis-(1-dimethylbenzyl)phenothiazine, and 3,7-dioctylphenothiazine; hindered phenolic compounds such as bis [3-(3-tert-butyl-4-hydroxy-5-methylphenyl)propionic acid][ethylene bis(oxyethylene)], 2,4-bis[(laurylthio)methyl]-o-cresol, 1,3,5-tris(3,5-di-t-butyl-4-hydroxybenzyl), 1,3,5-tris(4-t-butyl-3-hydroxy-2,6-dimethylbenzyl), 2,4-bis-(n-octylthio)-6-(4-hydroxy-3,5-di-t-butylanilino)-1,3,5-triazine, and pentaerythritol tetrakis[3-(3,5-di-tert-butyl-4-hydroxyphenyl)propionate]; nitroso compounds or a salt thereof, such as 4-nitrosophenol, N-nitrosodiphenylamine, N-nitrosocyclohexylhydroxylamine, and N-nitrosophenylhydroxylamine; quinone compounds such as methylhydroquinone, t-butylhydroquinone, 2,5-di-t-butylhydroquinone, and 4-benzoquinone; phenolic compounds such as 4-methoxyphenol, 4-methoxy-1-naphthol, and t-butylcatechol; and metal salt compounds such as copper dibutyldithiocarbamate, copper diethyldithiocarbamate, manganese diethyldithiocarbamate, and manganese diphenyldithiocarbamate.

One polymerization inhibitor may be used alone, or two or more kinds of polymerization inhibitors may be used in combination.

In a case where the photosensitive composition contains the polymerization inhibitor, a content of the polymerization inhibitor is preferably 0.001% to 5.0% by mass, more preferably 0.01% to 3.0% by mass, and still more preferably 0.02% to 2.0% by mass with respect to the total mass of the solid content of the photosensitive composition. The content of the polymerization inhibitor is preferably 0.005% by mass to 5.0% by mass, more preferably 0.01% by mass to 3.0% by mass, and still more preferably 0.01% by mass to 1.0% by mass with respect to the total mass of the polymerizable compound.

### <Hydrogen Donating Compound>

The photosensitive composition may contain a hydrogen donating compound.

The hydrogen donating compound has a function of further improving sensitivity of the photopolymerization initiator to actinic rays, suppressing inhibition of polymerization of the polymerizable compound by oxygen, or the like.

Examples of the hydrogen donating compound include amines and an amino acid compound.

Examples of the amines include compounds described in M. R. Sander et al., “Journal of Polymer Society” Vol. 10, page 3173 (1972), JP1969-020189B (JP-S44-020189B), JP1976-082102A (JP-S51-082102A), JP1977-134692A (JP-S52-134692A), JP1984-138205A (JP-S59-138205A), JP1985-084305A (JP-S60-084305A), JP1987-018537A (JP-S62-018537A), JP1989-033104A (JP-S64-033104A), and Research Disclosure 33825. More specific examples thereof include 4,4′-bis(diethylamino)benzophenone (EAB-F), tris(4-dimethylaminophenyl)methane (another name: Leucocrystal Violet), triethanolamine, p-dimethylaminobenzoic acid ethyl ester, p-formyldimethylaniline, and p-methylthiodimethylaniline

Among these, as the amines, at least one selected from the group consisting of 4,4′-bis(diethylamino)benzophenone and tris(4-dimethylaminophenyl)methane is preferable.

Examples of the amino acid compound include N-phenylglycine, N-methyl-N-phenylglycine, and N-ethyl-N-phenylglycine.

In addition, examples of the hydrogen donating compound also include an organic metal compound described in JP1973-042965B (JP-S48-042965B) (tributyl tin acetate and the like), a hydrogen donor described in JP1980-034414B (JP-S55-034414B), and a sulfur compound described in JP1994-308727A (JP-H6-308727A) (trithiane and the like).

One hydrogen donating compound may be used alone, or two or more kinds of hydrogen donating compounds may be used in combination.

In a case where the photosensitive composition contains the hydrogen donating compound, from the viewpoint of improving a curing rate by balancing the polymerization growth rate and chain transfer, a content of the hydrogen donating compound is preferably 0.01% to 10.0% by mass, more preferably 0.01% to 8.0% by mass, and still more preferably 0.03% to 5.0% by mass with respect to the total mass of the solid content of the photosensitive composition.

### <Solvent>

The photosensitive composition preferably contains a solvent.

As the solvent contained in the photosensitive composition, an organic solvent is preferable. Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol.

In addition, as the solvent, an organic solvent (high-boiling-point solvent) having a boiling point of 180° C. to 250° C. can also be used, as necessary.

One kind of solvent may be used alone, or two or more kinds of solvents may be used in combination.

The total solid content of the photosensitive composition is preferably 5% to 80% by mass, more preferably 5% to 40% by mass, and still more preferably 5% to 30% by mass with respect to the total mass of the photosensitive composition.

That is, a content of the solvent in the photosensitive composition is preferably 20% to 95% by mass, more preferably 60% to 95% by mass, and still more preferably 70% to 95% by mass with respect to the total mass of the photosensitive composition.

### <Impurities and the Like>

The photosensitive composition may contain a predetermined amount of impurities. Examples of the impurities include sodium, potassium, magnesium, calcium, iron, manganese, copper, aluminum, titanium, chromium, cobalt, nickel, zinc, tin, halogen, and ions of these. Among these, halide ion (chloride ion, bromide ion, and iodide ion), sodium ion, and potassium ion are easily mixed as impurities, so that the following content is preferable.

A content of the impurities in the photosensitive composition is preferably 80 ppm or less, more preferably 10 ppm or less, and still more preferably 2 ppm or less on a mass basis. The content of impurities in the photosensitive composition may be 1 ppb or more or 0.1 ppm or more on a mass basis. Specific examples of the content of the impurities in the photosensitive composition include an aspect in which all the above-described impurities are 0.6 ppm on a mass basis.

Examples of a method for keeping the impurities in the range include selecting a raw material having a low content of impurities as a raw material for the photosensitive composition, preventing the impurities from being mixed in a case of forming the photosensitive composition, and washing and removing the impurities. By such a method, the amount of impurities can be kept within the above-described range.

The impurities can be quantified by a known method such as inductively coupled plasma (ICP) emission spectroscopy, atomic absorption spectroscopy, and ion chromatography.

In addition, it is preferable that the content of compounds such as benzene, formaldehyde, trichloroethylene, 1,3-butadiene, carbon tetrachloride, chloroform, N,N-dimethylformamide, N,N-dimethylacetamide, and hexane is low in the photosensitive composition. A content of these compounds in the photosensitive composition is preferably 100 ppm or less, more preferably 20 ppm or less, and still more preferably 4 ppm or less on a mass basis. The lower limit thereof may be 10 ppb or more or 100 ppb or more on a mass basis. The content of these compounds can be suppressed in the same manner as in the above-described metal as impurities. In addition, the compounds can be quantified by a known measurement method.

A content of water in the photosensitive composition is preferably 0.01% to 1.0% by mass and more preferably 0.05% to 0.5% by mass.

### <Other Components>

The photosensitive composition may contain a component other than the above-described components (hereinafter also referred to as “other components”). Examples of the other components include a colorant, an antioxidant, and particles (for example, metal oxide particles). In addition, examples of the other components also include other additives described in paragraphs to of JP2000-310706A.

### —Particles—

Examples of the particles include metal oxide particles.

The metal of the metal oxide particles also includes semimetal such as B, Si, Ge, As, Sb, or Te.

An average primary particle diameter of the particles is, for example, 1 to 200 nm.

The average primary particle diameter of the particles is calculated by measuring particle diameters of 200 random particles using an electron microscope and arithmetically averaging the measurement results. In a case where the shape of the particle is not a spherical shape, the longest side is set as the particle diameter.

In a case where the photosensitive composition contains the particles, the photosensitive composition may contain only one kind of particles having different metal types, sizes, and the like, or may contain two or more kinds thereof.

It is preferable that the photosensitive composition does not contain the particles, or in a case where the photosensitive composition contains the particles, a content of the particles is more than 0% by mass and 35% by mass or less with respect to the total mass of the solid content of the photosensitive composition; it is more preferable that the photosensitive composition does not contain the particles, or in a case where the photosensitive composition contains the particles, a content of the particles is more than 0% by mass and 10% by mass or less with respect to the total mass of the solid content of the photosensitive composition; it is still more preferable that the photosensitive composition does not contain the particles, or in a case where the photosensitive composition contains the particles, a content of the particles is more than 0% by mass and 5% by mass or less with respect to the total mass of the solid content of the photosensitive composition; it is even more preferable that the photosensitive composition does not contain the particles, or in a case where the photosensitive composition contains the particles, a content of the particles is more than 0% by mass and 1% by mass or less with respect to the total mass of the solid content of the photosensitive composition; and it is particularly preferable that the photosensitive composition does not contain the particles.

### —Colorant—

The photosensitive composition layer may contain a trace amount of a colorant (pigment, dye, and the like), or may not substantially contain a colorant.

In a case where the photosensitive composition contains the colorant, a content of the colorant is preferably less than 1% by mass and more preferably less than 0.1% by mass with respect to the total mass of the solid content of the photosensitive composition.

### —Antioxidant—

Examples of the antioxidant include 3-pyrazolidones such as 1-phenyl-3-pyrazolidone (another name; phenidone), 1-phenyl-4,4-dimethyl-3-pyrazolidone, and 1-phenyl-4-methyl-4-hydroxymethyl-3-pyrazolidone; polyhydroxybenzenes such as hydroquinone, catechol, pyrogallol, methylhydroquinone, and chlorohydroquinone; paramethylaminophenol, paraaminophenol, parahydroxyphenylglycine, and paraphenylenediamine.

In a case where the photosensitive composition contains the antioxidant, a content of the antioxidant is preferably 0.001% by mass or more, more preferably 0.005% by mass or more, and still more preferably 0.01% by mass or more with respect to the total mass of the solid content of the photosensitive composition. The upper limit thereof is not particularly limited, and is preferably 1% by mass or less.

### [Manufacturing Method of Resin Membrane Filter]

Examples of a manufacturing method of the resin membrane filter according to the embodiment of the present invention include a manufacturing method including, in the following order:
a step P1 of preparing a photosensitive composition layer;
a step P2 of exposing the photosensitive composition layer in a patterned manner; and
a step P3 of developing the pattern-exposed photosensitive composition layer with a developer to form through-holes in the pattern-exposed photosensitive composition layer.

Hereinafter, the procedure of each step in the manufacturing method of the resin membrane filter will be described in detail.

[Step P1 (step of Preparing Photosensitive Composition Layer)]

The step P1 is a step of preparing a photosensitive composition layer.

The “preparation” of the photosensitive composition layer includes an act of forming the photosensitive composition layer, and also includes an act of procuring the photosensitive composition layer by purchase or the like.

The photosensitive composition layer prepared by the step P1 may be a single layer or a laminate with other layers.

### <Step P1-a>

As the step P1, among these, a step P1 -a of preparing a laminate including a temporary support and a photosensitive composition layer is preferable.

Examples of the step P1-a include a method of producing the above-described laminate by forming a photosensitive composition layer on a temporary support and a method of producing the above-described laminate by bonding a temporary support and a photosensitive composition layer.

The laminate prepared by the step P1-a may be a laminate consisting of a temporary support and a photosensitive composition layer, or may have other layers in addition to the temporary support and the photosensitive composition layer.

### <Forming Method of Photosensitive Composition Layer>

A method of forming the photosensitive composition layer on the temporary support (hereinafter, also simply referred to as “forming method of the photosensitive composition layer”) will be described.

The forming method of the photosensitive composition layer is not particularly limited, but a method in which the photosensitive composition layer is formed by a coating method using a photosensitive composition containing the above-described components (for example, the binder polymer, the polymerizable compound, the polymerization initiator, and the like) constituting the resin membrane filter and a solvent is desirable. More specific examples thereof include a method in which the photosensitive composition is applied onto the temporary support to form a coating film, and the coating film is dried at a predetermined temperature to form the photosensitive composition layer.

### (Temporary Support)

The temporary support used in the forming method of the photosensitive composition layer is not particularly limited, and a member having a function of supporting the formed photosensitive composition layer is used.

The temporary support may be a monolayer structure or a multilayer structure.

The temporary support is preferably a film and more preferably a resin film. As the temporary support, a film which has flexibility and does not generate significant deformation, contraction, or stretching under pressure or under pressure and heating is preferable.

Examples of the above-described film include a polyethylene terephthalate film (for example, a biaxial stretching polyethylene terephthalate film), a polymethylmethacrylate film, a cellulose triacetate film, a polystyrene film, a polyimide film, and a polycarbonate film.

Among these, as the temporary support, a polyethylene terephthalate film is preferable.

In addition, it is preferable that the film used as the temporary support does not have deformation such as wrinkles or scratches.

In a case where the pattern exposure is performed through the temporary support, a temporary support having high transparency may be used. In this case, the transmittance of the temporary support at 365 nm is preferably 60% or more and more preferably 70% or more.

From the viewpoint of pattern formability during pattern exposure through the temporary support and transparency of the temporary support, it is preferable that a haze of the temporary support is small. Specifically, a haze value of the temporary support is preferably 2% or less, more preferably 0.5% or less, and still more preferably 0.1% or less.

From the viewpoint of pattern formability during pattern exposure through the temporary support and transparency of the temporary support, it is preferable that the number of fine particles, foreign substances, and defects included in the temporary support is small. The number of fine particles having a diameter of 1 μm or more, foreign substances, and defects in the temporary support is preferably 50 pieces/10 mm² or less, more preferably 10 pieces/10 mm² or less, still more preferably 3 pieces/10 mm² or less, and particularly preferably 0 piece/10 mm².

A thickness of the temporary support is not particularly limited, but from the viewpoint of easiness of handling and general-purpose properties, is preferably 5 to 200 μm, more preferably 5 to 150 μm, and still more preferably 5 to 100 μm.

The thickness of the temporary support is obtained as an average value of 5 random points measured by cross-sectional observation with SEM.

In order to improve adhesiveness between the temporary support and the composition layer, a side of the temporary support in contact with the composition layer may be surface-modified by UV irradiation, corona discharge, plasma, and/or the like.

In a case where the surface is modified by UV irradiation, the exposure amount is preferably 10 to 2,000 mJ/cm² and more preferably 50 to 1,000 mJ/cm².

Examples of a light source for the UV irradiation include a low pressure mercury lamp, a high pressure mercury lamp, an ultra-high pressure mercury lamp, a carbon arc lamp, a metal halide lamp, a xenon lamp, a chemical lamp, an electrodeless discharge lamp, and a light emitting diode (LED), all of which emit a light in a wavelength range of 150 to 450 nm. As long as the amount of light irradiated is within the range, the lamp output or the illuminance is not particularly limited.

Examples of the temporary support include a biaxial stretching polyethylene terephthalate membrane having a membrane thickness of 50 μm, a biaxial stretching polyethylene terephthalate membrane having a membrane thickness of 75 μm, and a biaxial stretching polyethylene terephthalate membrane having a membrane thickness of 100 μm.

Examples of a preferred aspect of the temporary support include aspects described in, for example, paragraphs [0017] and [0018] of JP2014-085643A, paragraphs [0019] to [0026] of JP2016-027363A, paragraphs [0041] to [0057] of WO2012/081680A, and paragraphs [0029] to [0040] of WO2018/179370A, the contents of which are incorporated herein by reference.

From the viewpoint of imparting handleability, a layer (lubricant layer) containing fine particles may be provided on the surface of the temporary support. The lubricant layer may be provided on one surface of the temporary support, or on both surfaces thereof. A diameter of the particles contained in the lubricant layer is preferably 0.05 to 0.8 μm. In addition, a membrane thickness of the lubricant layer is preferably 0.05 to 1.0 μm.

Examples of a commercially available product of the temporary support include LUMIRROR #50-T60, LUMIRROR 16KS40, and LUMIRROR 16FB40 (all manufactured by Toray Industries, Inc.), and COSMOSHINE A4100, COSMOSHINE A4300, and COSMOSHINE A8300 (all manufactured by TOYOBO Co., Ltd.).

### (Photosensitive Composition)

Components contained in the photosensitive composition used for forming the photosensitive composition layer are as described above.

The photosensitive composition layer may be a layer formed of a negative tone photosensitive resin composition, or may be a layer formed of a positive tone photosensitive resin composition.

For example, from the viewpoint of coating properties, a viscosity of the photosensitive composition at 25° C. is preferably 1 to 50 mPa·s, more preferably 2 to 40 mPa·s, and still more preferably 3 to 30 mPa·s. The viscosity is measured using a viscometer. As the viscometer, for example, a viscometer (product name: VISCOMETER TV-22) manufactured by Toki Sangyo Co., Ltd. can be suitably used. However, the viscometer is not limited to the above-described viscometer.

For example, from the viewpoint of coating properties, a surface tension of the photosensitive composition at 25° C. is preferably 5 to 100 mN/m, more preferably 10 to 80 mN/m, and still more preferably 15 to 40 mN/m. The surface tension is measured using a tensiometer. As the tensiometer, for example, a tensiometer (product name: Automatic Surface Tensiometer CBVP-Z) manufactured by Kyowa Interface Science Co., Ltd. can be suitably used. However, the tensiometer is not limited to the above-described tensiometer.

Examples of a method for applying the photosensitive composition include a printing method, a spray coating method, a roll coating method, a bar coating method, a curtain coating method, a spin coating method, and a die coating method (that is, a slit coating method).

As a method for drying the coating film of the photosensitive composition, heat drying or vacuum drying is preferable. In the present specification, the “drying” means removing at least a part of the solvent contained in the composition. Examples of the drying method include natural drying, heat drying, and vacuum drying. The above-described methods can be adopted alone or in combination of two or more thereof.

The drying temperature is preferably 80° C. or higher and more preferably 90° C. or higher. In addition, the upper limit value thereof is preferably 130° C. or lower and more preferably 120° C. or lower. The drying can be performed by continuously changing the temperature.

In addition, the drying time is preferably 20 seconds or more, more preferably 40 seconds or more, and still more preferably 60 seconds or more. In addition, the upper limit value thereof is not particularly limited, but is preferably 600 seconds or less, and more preferably 300 seconds or less.

### <Characteristics of Photosensitive Composition Layer>

### (Dissolution Rate)

From the viewpoint of suppressing residue during development, a dissolution rate of the photosensitive composition layer in a 1.0% by mass sodium carbonate aqueous solution is preferably 0.01 μm/sec or more, more preferably 0.10 μm/sec or more, and still more preferably 0.20 μm/sec or more. The upper limit thereof is not particularly limited, but is preferably 5.0 μm/sec or less, more preferably 4.0 μm/sec or less, and still more preferably 3.0 μm/sec or less. Examples of a specific preferred numerical value include 1.8 μm/sec, 1.0 μm/sec, and 0.7 μm/sec. The dissolution rate of the photosensitive composition layer in a 1.0% by mass sodium carbonate aqueous solution per unit time is measured as follows.

A photosensitive composition layer (within a film thickness of 1.0 to 10 μm) formed on a glass substrate, from which the solvent has been sufficiently removed, is subjected to a shower development with a 1.0% by mass sodium carbonate aqueous solution at 25° C. until the photosensitive composition layer is dissolved completely (however, the maximum time is 2 minutes).

The dissolution rate of the photosensitive composition layer is obtained by dividing the film thickness of the photosensitive composition layer by the time required for the photosensitive composition layer to dissolve completely. In a case where the photosensitive layer is not dissolved completely in 2 minutes, the dissolution rate of the photosensitive layer is calculated in the same manner as above, from the amount of change in film thickness up to 2 minutes.

A dissolution rate of the cured membrane (within a membrane thickness of 1.0 to 10 μm) of the photosensitive composition layer in a 1.0% sodium carbonate aqueous solution is preferably 3.0 μm/sec or less, more preferably 2.0 μm/sec or less, still more preferably 1.0 μm/sec or less, and most preferably 0.2 μm/sec or less. The cured membrane of the photosensitive composition layer is a membrane obtained by exposing the photosensitive composition layer with i-rays at an exposure amount of 300 mJ/cm². Examples of a specific preferred numerical value include 0.8 μm/sec, 0.2 μm/sec, and 0.001 μm/sec. For development, a shower nozzle of 1/4 MINJJX030PP manufactured by H.IKEUCHI Co., Ltd. is used, and a spraying pressure of the shower is set to 0.08 MPa. Under the above-described conditions, a shower flow rate per unit time is set to 1,800 mL/min.

### (Swelling Ratio)

From the viewpoint of improving forming properties of the through-hole, a swelling ratio of the cured membrane of the photosensitive composition layer with respect to a 1.0% by mass sodium carbonate aqueous solution is preferably 100% or less, more preferably 50% or less, and still more preferably 30% or less. The swelling ratio of the photosensitive resin layer after exposure with respect to a 1.0% by mass sodium carbonate aqueous solution is measured as follows.

A photosensitive resin layer (within a membrane thickness of 1.0 to 10 μm) formed on a glass substrate, from which the solvent has been sufficiently removed, is exposed at an exposure amount of 500 mJ/cm² (i-ray measurement) with an ultra-high pressure mercury lamp. The glass substrate is immersed in a 1.0% by mass sodium carbonate aqueous solution at 25° C., and the membrane thickness is measured after 30 seconds. Then, an increased proportion of the membrane thickness after immersion to the membrane thickness before immersion is calculated. Examples of a specific preferred numerical value include 4%, 13%, and 25%.

### (Content of Foreign Substances)

From the viewpoint of forming the through-hole, the number of foreign substances having a diameter of 1.0 μm or more in the photosensitive composition layer is preferably 10 pieces/mm² or less, and more preferably 5 pieces/mm² or less.

The number of foreign substances is measured as follows. Any 5 regions (1 mm×1 mm) on a surface of the photosensitive composition layer are visually observed from a normal direction to the surface of the photosensitive composition layer with an optical microscope, the number of foreign substances having a diameter of 1.0 μm or more in each region is measured, and the values are arithmetically averaged to calculate the number of foreign substances. Examples of a specific preferred numerical value include 0 pieces/mm², 1 pieces/mm², 4 pieces/mm², and 8 pieces/mm².

### <Step P1-b>

The step P1-a of preparing the laminate including a photosensitive composition layer may be a step P1-b of preparing a laminate including a temporary support, a water-soluble resin layer, and a photosensitive composition layer in this order.

Examples of the step P1-b include a method in which the above-described photosensitive composition is applied onto a surface of a temporary support having a water-soluble resin layer on the water-soluble resin layer side to form a coating film, and then the coating film is dried to the photosensitive composition layer, thereby producing the laminate including the temporary support, the water-soluble resin layer, and the photosensitive composition layer in this order.

In the present specification, the “water-soluble resin layer” means a layer containing a water-soluble resin. That is, a part or the whole of the resin constituting the water-soluble resin layer is a water-soluble resin.

Examples of the resin which can be used as the water-soluble resin include resins such as a polyvinyl alcohol-based resin, a polyvinylpyrrolidone-based resin, a cellulose-based resin, an acrylamide-based resin, a polyethylene oxide-based resin, gelatin, a vinyl ether-based resin, a polyamide-based resin, and a copolymer thereof.

In addition, as the water-soluble resin, a copolymer of (meth)acrylic acid/vinyl compound, or the like can also be used. As the copolymer of (meth)acrylic acid/vinyl compound, a copolymer of (meth)acrylic acid/allyl (meth)acrylic acid is preferable, and a copolymer of methacrylic acid/allyl methacrylate is more preferable.

In a case where the water-soluble resin is a copolymer of (meth)acrylic acid/vinyl compound, for example, a compositional ratio (mol %) of each component is preferably 90/10 to 20/80 and more preferably 80/20 to 30/70.

The lower limit value of the weight-average molecular weight of the water-soluble resin is preferably 5,000 or more, more preferably 7,000 or more, and still more preferably 10,000 or more. In addition, the upper limit value thereof is preferably 200,000 or less, more preferably 100,000 or less, and still more preferably 50,000 or less.

A dispersity (Mw/Mn) of the water-soluble resin is preferably 1 to 10 and more preferably 1 to 5.

The water-soluble resin layer preferably contains polyvinyl alcohol as the water-soluble resin, and more preferably contains both polyvinyl alcohol and polyvinylpyrrolidone as the water-soluble resin.

The water-soluble resin may be used alone, or in combination of two or more kinds thereof.

A content of the water-soluble resin is not particularly limited, and is preferably 50% by mass or more, more preferably 70% by mass or more, still more preferably 80% by mass or more, and particularly preferably 90% by mass or more with respect to the total mass of the water-soluble resin layer. The upper limit value thereof is not particularly limited, and for example, 99.9% by mass or less is preferable and 99.8% by mass or less is more preferable.

The water-soluble resin layer may contain a known additive such as a surfactant as necessary.

A thickness of the water-soluble resin layer is not particularly limited, but from the viewpoint of removal time of the water-soluble resin layer (interlayer) and filter smoothness, it is preferably 0.1 to 5 μm and more preferably 0.5 to 3 μm.

From the viewpoint that it is easy to dissolve and remove the water-soluble resin layer, which will be described later, a dissolution rate of the water-soluble resin layer in water (hot water) at a liquid temperature of 80° C. is preferably 0.5 μm/sec or more, more preferably 1 μm/sec or more, and still more preferably 2 μm/sec or more. The upper limit thereof is not particularly limited, but is preferably 10 μm/sec or less, more preferably 8 μm/sec or less, and still more preferably 5 μm/sec or less.

The dissolution rate of the water-soluble resin layer in the hot water per unit time is measured according to the above-described measuring method of the dissolution rate of the photosensitive composition layer.

A method of preparing the temporary support having a water-soluble resin layer (laminate including the temporary support and the water-soluble resin layer), which is used in the step P1-b, is not particularly limited, and a method of forming a coating film by a coating method using a composition containing components constituting the water-soluble resin layer, such as the water-soluble resin, and a solvent is preferable. More specific examples thereof include a method in which the above-described composition is applied onto the temporary support to form a coating film, and the coating film is dried at a predetermined temperature to form the water-soluble resin layer, thereby producing the temporary support having a water-soluble resin layer.

Examples of the solvent contained in the above-described composition include the solvent contained in the above-described photosensitive composition. In addition, the method of applying the above-described composition and the method of drying the coating film can be performed according to the above-described forming method of the photosensitive composition layer.

### <Step P1-c>

The step P1-a of preparing the laminate including a photosensitive composition layer may be a step P1-c of preparing a laminate including a water-soluble temporary support and a photosensitive composition layer in this order. That is, the temporary support used in the forming method of the photosensitive composition layer may be a water-soluble temporary support.

In the present specification, the “water-soluble temporary support” means a temporary support containing a water-soluble resin. That is, a part or the whole of the resin constituting the water-soluble temporary support is a water-soluble resin.

In the step P1-c, it is preferable that the laminate including the water-soluble temporary support and the photosensitive resin layer in this order is produced according to the above-described forming method of the photosensitive composition layer, except that the water-soluble temporary support is used as the temporary support. That is, a step of producing the above-described laminate, in which the above-described photosensitive composition is applied onto the water-soluble temporary support to form a coating film, and the coating film is dried at a predetermined temperature to form the photosensitive composition layer, is preferable.

Examples of the water-soluble resin contained in the water-soluble temporary support include the resin described as the water-soluble resin contained in the above-described water-soluble resin layer, including the preferred aspect thereof.

The water-soluble temporary support preferably contains polyvinyl alcohol as the water-soluble resin.

The water-soluble resin may be used alone, or in combination of two or more kinds thereof.

A content of the water-soluble resin is not particularly limited, and is preferably 50% by mass or more, more preferably 70% by mass or more, still more preferably 80% by mass or more, and particularly preferably 90% by mass or more with respect to the total mass of the water-soluble temporary support. The upper limit value thereof is not particularly limited, and for example, 99.9% by mass or less is preferable and 99.8% by mass or less is more preferable.

The water-soluble temporary support may contain a known additive such as a surfactant as necessary.

From the viewpoint that it is easy to dissolve and remove the water-soluble temporary support, which will be described later, a dissolution rate of the water-soluble temporary support in water (hot water) at a liquid temperature of 80° C. is preferably 0.5 μm/sec or more, more preferably 1 μm/sec or more, and still more preferably 2 μm/sec or more. The upper limit thereof is not particularly limited, but is preferably 10 μm/sec or less, more preferably 8 μm/sec or less, and still more preferably 5 μm/sec or less.

The dissolution rate of the water-soluble temporary support in the hot water per unit time is measured according to the above-described measuring method of the dissolution rate of the photosensitive composition layer.

The water-soluble temporary support may be produced by a known method, or may be obtained as a commercially available product. Examples of the commercially available product of the water-soluble temporary support include Solublon (registered trademark) EF (manufactured by Aicello Chemical Co., Ltd., PVA film), Hi-Selon (registered trademark) (manufactured by Mitsubishi Chemical Corporation, PVA film), and CLARIA (registered trademark) (manufactured by KURARAY CO., LTD., PVA film).

In addition, the step P1-a is not limited to the above-described forming method of the photosensitive composition layer, and may be a bonding step of bonding the temporary support and the photosensitive composition layer to produce a laminate including the temporary support and the photosensitive composition layer.

The above-described bonding step is performed, for example, by pressure-bonding the temporary support and the surface of the photosensitive composition layer so that the temporary support and the photosensitive composition layer are in contact with each other. The pressure-bonding method in this case is not particularly limited, and examples thereof include a known transfer method and laminating method. Among these, it is preferable to superimpose the surface of the photosensitive composition layer on the temporary support, followed by pressurizing and heating the laminate with a roll or the like.

A known laminator such as a vacuum laminator and an auto-cut laminator can be used for the bonding. A laminating temperature is not particularly limited, but is, for example, 70° C. to 130° C.

### <Cover Film>

The laminate including the temporary support and the photosensitive composition layer, which is prepared by the step P1-a, may further include a cover film. In a case where the above-described laminate further includes a cover film, a laminate including the temporary support, the photosensitive composition layer, and the cover film in this order is preferable. By disposing the photosensitive resin layer between the temporary support and the cover film, the photosensitive resin layer before exposure can be protected from both surface sides.

Examples of the cover film include polyolefin films such as a polypropylene film and a polyethylene film, polyester films such as a polyethylene terephthalate film, polycarbonate films, and polystyrene films.

In addition, a resin film composed of the same material as the above-described temporary support may be used as the cover film.

Among these, as the cover film, a polyolefin film is preferable, a polypropylene film or a polyethylene film is more preferable, and a polypropylene film is still more preferable.

From the viewpoint of excellent mechanical strength and relatively low cost, a thickness of the cover film is preferably 1 to 100 μm, more preferably 5 to 50 μm, still more preferably 5 to 40 μm, and particularly preferably 15 to 30 μm.

A method of further laminating the cover film on the laminate including the temporary support and the photosensitive composition layer is not particularly limited, and examples thereof include a method of bonding the cover film to a surface of the above-described laminate on the photosensitive composition layer side.

The above-described bonding method is not particularly limited, and examples thereof include a method of bonding the cover film and the above-described laminate using a known laminator such as a vacuum laminator and an auto-cut laminator.

### [Step P2 (Exposing Step)]

The step P2 is a step of exposing the photosensitive composition layer prepared by the step P1 in a patterned manner.

In the present specification, the “exposure in a patterned manner” means an exposure in a form of performing the exposure in a patterned manner, that is, a form in which an exposed portion and a non-exposed portion are present.

The position, shape, and area of the exposed region and the unexposed region in the pattern exposure are appropriately adjusted according to the position, shape, and area, of the through-hole to be formed in the target resin membrane filter.

In a case where the photosensitive composition layer is a negative tone photosensitive composition layer, by exposing the photosensitive composition layer in a patterned manner, a solubility in a developer in the exposed portion is decreased. As a result, a non-exposed portion is removed (dissolved) in the subsequent developing step, and the through-hole is formed at a position corresponding to the non-exposed portion after the developing step.

On the other hand, in a case where the photosensitive composition layer is a positive tone photosensitive composition layer, by exposing the photosensitive composition layer in a patterned manner, the photoacid generator is decomposed in an exposed portion to generate acid, and a solubility of the exposed portion in an alkali aqueous solution is increased due to action of the generated acid. As a result, the exposed portion is removed (dissolved) in the subsequent developing step, and the through-hole is formed at a position corresponding to the exposed portion after the developing step.

In a case where the pattern exposure is performed on the above-described laminate including the temporary support and the photosensitive composition layer, which is prepared in the step P1-a, the laminate may be irradiated with exposure light from a surface on the photosensitive composition layer side, or may be irradiated with exposure light from a surface on the temporary support side.

As a light source for the pattern exposure, a light source which can radiate light at a wavelength region (for example, a wavelength of 300 to 450 nm, such as 365 nm, 405 nm, and 436 nm) at which at least the photosensitive composition layer can be cured can be used as appropriate.

The exposure light for the pattern exposure preferably includes at least one selected from the group consisting of g-rays (436 nm), i-rays (365 nm), and h-rays (405 nm), and more preferably includes i-rays, and it is still more preferable that a main wavelength of the exposure light for the pattern exposure is 365 nm. The main wavelength is a wavelength having the highest intensity.

Examples of a light source used in the step P2 include various lasers, a light emitting diode (LED), an ultra-high pressure mercury lamp, a high pressure mercury lamp, and a metal halide lamp. In addition, the wavelength of irradiation light may be adjusted as necessary through a spectral filter such as a long wavelength cut filter, a short wavelength cut filter, and a bandpass filter.

Examples of the exposure method include a method of performing the exposure using a photo mask and a projection exposure method not using a photo mask.

Examples of the method of performing the pattern exposure using a photo mask include a contact exposure method in which the photosensitive composition layer is exposed in a state in which the photo mask and the photosensitive composition layer are in contact with each other, and a proximity exposure in which the photosensitive composition layer is exposed in a state in which the photo mask and the photosensitive composition layer are not in contact with each other. The above-described proximity exposure method is a non-contact exposure method in which a gap is provided between the photo mask and the photosensitive composition layer for the exposure.

In the step P2, it is preferable to perform the pattern exposure through a photo mask, and from the viewpoint that it is possible to form a through-hole in which the above-described value of Sva/Svb is closer to 1, it is more preferable to perform the pattern exposure by a contact exposure method.

The photo mask used in the pattern exposure has a pattern structure corresponding to the position, shape, and area, of the through-hole to be formed in the target resin membrane filter.

For example, in a case where the photosensitive composition layer is a negative tone photosensitive composition layer, the photo mask used in the pattern exposure has a light shielding unit corresponding to a region in which the through-hole is formed in the resin membrane filter and an opening unit corresponding to a region in which the through-hole is not formed. By irradiating the negative tone photosensitive composition layer with the exposure light through such a photo mask, a non-exposed portion is formed at a position corresponding to the light shielding unit of the photo mask, a certain non-exposed portion is removed in the subsequent developing step, and the through-hole is formed at a position corresponding to the non-exposed portion.

In a case where the photosensitive composition layer is a positive tone photosensitive composition layer, a photo mask having an opening unit corresponding to a region in which the through-hole is formed in the resin membrane filter and a light shielding unit corresponding to a region in which the through-hole is not formed is used.

An irradiation amount (exposure amount) of the exposure light in the step P2 is not particularly limited, and is appropriately selected depending on conditions such as the composition and thickness of the photosensitive composition layer, the periodic pattern of the photo mask, and the wavelength of the exposure light, so that a desired pattern structure is formed in the photosensitive composition layer in the step P3 described later.

The exposure amount is, for example, 5 to 200 mJ/cm², preferably 10 to 200 mJ/cm².

In addition, in the step P2, a direction in which the photosensitive composition layer is irradiated with the exposure light is not particularly limited, but from the viewpoint that it is possible to form the through-hole extending in a direction more perpendicular to the first main surface of the resin membrane filter, an angle between the irradiation direction of the exposure light to the photosensitive composition layer and the normal direction to the surface of the photosensitive composition layer is preferably within 10° and more preferably within 5°. The lower limit thereof is not particularly limited, and may be 0°.

In the step P2, in a case where the pattern exposure is performed on the above-described laminate including the temporary support, the photosensitive composition layer, and the cover film in this order, the photosensitive composition layer may be exposed in a patterned manner through the cover film, or after peeling off the cover film from the laminate, the photosensitive composition layer may be exposed in a patterned manner from a surface from which the cover film has been peeled off.

In addition, with regard to the laminate including the temporary support and the photosensitive composition layer, the photosensitive composition layer may be exposed in a patterned manner through the temporary support, or after performing the step P4 of peeling off the temporary support from the laminate, the photosensitive composition layer may be exposed in a patterned manner from a surface from which the temporary support has been peeled off.

Examples of preferred aspects of the light source, the exposure amount, and the exposing method used for the pattern exposure include aspects described in, for example, paragraphs and of WO2018/155193A, the contents of which are incorporated herein by reference.

### [Step P3 (Developing Step)]

The step P3 is a developing step of developing the photosensitive composition layer exposed in a patterned manner in the step P2 with a developer to form through-holes in the pattern-exposed photosensitive composition layer.

By performing the step P2 and the step P3, a resin membrane filter having a plurality of through-holes having a specific shape is formed.

Examples of the developer include an alkali aqueous solution and an organic solvent-based developer, and an alkali aqueous solution is preferable.

That is, examples of the step P3 include a step P3-a of developing the pattern-exposed photosensitive composition layer with an alkali aqueous solution to form through-holes in the pattern-exposed photosensitive composition layer and a step P3-b of developing the pattern-exposed photosensitive composition layer with an organic solvent-based developer to form through-holes in the pattern-exposed photosensitive composition layer, and the step P3-a is preferable.

Examples of an alkali compound included in the alkali aqueous solution include sodium hydroxide, potassium hydroxide, sodium carbonate, potassium carbonate, sodium hydrogen carbonate, potassium hydrogencarbonate, tetramethyl ammonium hydroxide, tetraethyl ammonium hydroxide, tetrapropyl ammonium hydroxide, tetrabutylammonium hydroxide, and choline (2-hydroxyethyltrimethylammonium hydroxide).

The pH of the alkali aqueous solution at 25° C. is preferably 8 to 13 and more preferably 9 to 12.

A content of the alkali compound in the alkali aqueous solution is not particularly limited, but is preferably 0.1% by mass to 5% by mass and more preferably 0.1% by mass to 3% by mass with respect to the total amount of the alkali aqueous solution.

The alkali aqueous solution contains water as a remainder other than the alkali compound. The alkali aqueous solution may contain an organic solvent and/or a known surfactant.

Examples of the development method include methods such as puddle development, shower development, spin development, and dip development.

Examples of the developer which is suitably used in the present specification include the developer described in paragraph of WO2015/093271A, and examples of the developing method which is suitably used include the developing method described in paragraph of WO2015/093271A. The contents thereof are incorporated in the present specification.

### [Step P4 (Peeling Step)]

In a case where the step P1 of preparing the photosensitive composition layer is the step P1-a of preparing the laminate including the temporary support and the photosensitive composition layer, it is preferable that the manufacturing method of the resin membrane filter further includes a step P4 of peeling off the pattern-exposed photosensitive composition layer from the temporary support.

Examples of the step P4 include a step P4-a of physically peeling off the temporary support and the pattern-exposed photosensitive composition layer in the laminate including the temporary support and the pattern-exposed photosensitive composition layer in this order.

The peeling method in the step P4-a is not particularly limited, and the same mechanism as the cover film peeling mechanism described in paragraphs and of JP2010-072589A can be used.

In addition, in a case where the step P1-a is the step P1-b of preparing the laminate including the temporary support, the water-soluble resin layer, and the pattern-exposed photosensitive composition layer in this order, the step P4 may be a step P4-b of peeling off the pattern-exposed photosensitive composition layer from the temporary support by dissolving the water-soluble resin layer to remove the water-soluble resin layer.

In addition, in a case where the step P1-a is the step P1-c of preparing the laminate including the water-soluble temporary support and the pattern-exposed photosensitive composition layer in this order, the step P4 may be a step P4-c of obtaining the pattern-exposed photosensitive composition layer by dissolving the water-soluble temporary support to remove the water-soluble temporary support.

Examples of the step P4-b and the step P4-c include a method of immersing each of the laminates in an aqueous solvent containing water. The aqueous solvent may contain a water-soluble organic solvent in addition to the water. In addition, the above-described alkali aqueous solution may be used as the aqueous solvent. A temperature of the aqueous solvent is not particularly limited, but from the viewpoint that the required time is shortened, it is preferably 30° C. or higher and more preferably 50° C. or higher. The upper limit is not particularly limited and may be 85° C. or lower.

A timing of performing the step P4 is not particularly limited, and examples thereof include a timing between the step P1-a and the step P2, a timing between the step P2 and the step P3, and a timing after the step P3. It is preferable to perform the step P4 between the step P2 and the step P3 or after the step P3, and more preferable to perform the step P4 after the step P3.

In addition, the step P4-b and step P4-c described above may be performed simultaneously with the step P3-a of forming through-holes in the pattern-exposed photosensitive composition layer by developing the pattern-exposed photosensitive composition layer with the alkali aqueous solution. In a case where the step P4-b or the step P4-c is performed at the same time as the step P3-a, the water-soluble resin layer or the water-soluble temporary support is dissolved and removed with the alkali aqueous solution which is used as the developer in the step P3-a.

Hereinafter, preferred embodiments of the manufacturing method of the resin membrane filter will be exemplified. The manufacturing method of the resin membrane filter is not limited to the following specific embodiments.

### First Embodiment

A manufacturing method of the resin membrane filter according to a first embodiment is a manufacturing method including, in the following order:
the step P1-a of preparing a laminate including a temporary support and a photosensitive composition layer; and
the step P2 of exposing the photosensitive composition layer in a patterned manner, and after the step P2, the step P3 of developing the pattern-exposed photosensitive composition layer with a developer to form through-holes in the pattern-exposed photosensitive composition layer and the step P4-a of physically peeling off the temporary support and the pattern-exposed photosensitive composition layer are performed.

In the manufacturing method according to the first embodiment, it is sufficient that both the step P3 and the step P4-a are performed after performing the step P2, and an order of the step P3 and the step P4-a is not particularly limited. That is, the step P4-a may be performed after the step P3 has been performed, or the step P3 may be performed after the step P4-a has been performed.

### Second Embodiment

A manufacturing method of the resin membrane filter according to a second embodiment is a manufacturing method including, in the following order:
the step P1-b of preparing a laminate including a temporary support, a water-soluble resin layer, and a photosensitive composition layer in this order; and
the step P2 of exposing the photosensitive composition layer in a patterned manner, and
after the step P2, the step P3-a of developing the pattern-exposed photosensitive composition layer with an alkali aqueous solution to form through-holes in the pattern-exposed photosensitive composition layer and the step P4-b of peeling off the pattern-exposed photosensitive composition layer from the temporary support by dissolving the water-soluble resin layer in water are performed.

In the manufacturing method according to the second embodiment, it is sufficient that both the step P3-a and the step P4-b are performed after performing the step P2, and an order of the step P3-a and the step P4-b is not particularly limited. That is, the step P4-b may be performed after the step P3-a has been performed, the step P3-a may be performed after the step P4-b has been performed, or the step P3-a and the step P4-b may be performed at the same time.

### Third Embodiment

A manufacturing method of the resin membrane filter according to a third embodiment is a manufacturing method including, in the following order:
the step P1-c of preparing a laminate including a water-soluble temporary support and a photosensitive composition layer in this order; and
the step P2 of exposing the photosensitive composition layer in a patterned manner, and after the step P2, the step P3-a of developing the pattern-exposed photosensitive composition layer with an alkali aqueous solution to form through-holes in the pattern-exposed photosensitive composition layer and the step P4-c of obtaining the pattern-exposed photosensitive composition layer by dissolving the water-soluble temporary support in water are performed.

In the manufacturing method according to the third embodiment, it is sufficient that both the step P3-a and the step P4-c are performed after performing the step P2, and an order of the step P3-a and the step P4-c is not particularly limited. That is, the step P4-c may be performed after the step P3-a has been performed, the step P3-a may be performed after the step P4-c has been performed, or the step P3-a and the step P4-c may be performed at the same time. Preferred aspects of each step in the manufacturing methods according to the first to third embodiments are as described above.

### [Post-Exposing Step and Post-Baking Step]

The manufacturing method of the resin membrane filter may include a step (post-exposing step) of further exposing the resin membrane filter manufactured by the method including at least the above-described steps P1 to P3 and/or a step (post-baking step) of heating the resin membrane filter.

In a case where both of the post-exposing step and the post-baking step are included, it is preferable that the post-baking is performed after the post-exposure. An exposure amount of the post-exposure is preferably 100 to 5000 mJ/cm² and more preferably 200 to 3000 mJ/cm². A temperature of the post-baking is preferably 80° C. to 250° C. and more preferably 90° C. to 160° C. A post-baking time is preferably 1 minute to 180 minutes and more preferably 10 minutes to 60 minutes.

The manufacturing method of the resin membrane filter may include a step other than the above-described steps. As other steps, a known step which can be performed in a photolithography process can be applied without particular limitation.

### [Applications of Resin Membrane Filter]

The resin membrane filter according to the embodiment of the present invention can be applied to various applications.

Examples of the applications of the resin membrane filter include cell separation, selective permeation membrane, microsensor, drug delivery film, and cell culture base material. Among these, the resin membrane filter according to the embodiment of the present invention is preferably used as a cell separation filter.

### EXAMPLES

Hereinafter, the present disclosure will be described in more detail with reference to examples. The material, the amount used, the ratio, the process contents, the process procedure, and the like shown in the following examples can be appropriately changed, within a range not departing from a gist of the present disclosure. Accordingly, the range of the disclosure is not limited to specific examples shown below.

### Raw Material

Raw materials used in manufacture of the resin membrane filter in Examples and Comparative Examples are shown below.

### <Binder Polymer>

“B1”: copolymer of styrene (St), methyl methacrylate (MMA), and methacrylic acid (MAA) (St:MMA:MAA=52:19:29 (mass ratio), acid value=189, Mw=70,000; diluted liquid with a concentration of solid contents of 30% by mass)
“B2”: copolymer of St, MMA, and MAA (St:MMA:MAA=52:19:29 (mass ratio), acid value=189, Mw=100,000; diluted liquid with a concentration of solid contents of 30% by mass)
“B3”: copolymer of St, MMA, and MAA (St:MMA:MAA=52:19:29 (mass ratio), acid value=189, Mw=30,000; diluted liquid with a concentration of solid contents of 30% by mass)
“B4”: copolymer of St, MMA, MAA, and glycidyl methacrylate adduct of methacrylic acid (MAA-GMA) (St:MMA:MAA:MAA-GMA=47:2:19:32 (mass ratio), acid value=124, Mw=42,000; diluted liquid with a concentration of solid contents of 30% by mass)
“B5”: copolymer of dicyclopentanyl methacrylate (DCPMA), MMA, MAA (DCPMA:MMA:MAA=52:19:29 (mass ratio), acid value=189, Mw=70,000; diluted liquid with a concentration of solid contents of 30% by mass)
“B6”: copolymer of benzyl methacrylate (BnMA), MMA, MAA (BnMA:MMA:MAA=52:19:29 (mass ratio), acid value=189, Mw=70,000; diluted liquid with a concentration of solid contents of 30% by mass)
“B7”: copolymer of St, MMA, MAA, and 2-hydroxyethyl methacrylate (HEMA) (St:MMA:MAA:HEMA=52:19:19:10 (mass ratio), acid value=124, Mw=70,000; diluted liquid with a concentration of solid contents of 30% by mass)
“B8”: copolymer of St, MMA, MAA, and 2-ethylhexyl methacrylate (2EMA) (St:MMA:MAA:2EMA=42:19:29:10 (mass ratio), acid value=189, Mw=70,000; diluted liquid with a concentration of solid contents of 30% by mass)
“B9”: copolymer of St, MMA, MAA, and AM-90G (methoxypolyethylene glycol acrylate, manufactured by Shin-Nakamura Chemical Co., Ltd.) (St:MMA:MAA:AM-90G=42:19:29:10 (mass ratio), acid value=189, Mw=70,000; diluted liquid with a concentration of solid contents of 30% by mass)
“B10”: EPICLON (registered trademark) N-690 (manufactured by DIC Corporation, cresol novolac-type epoxy resin; concentration of solid contents: 100% by mass)
“B11”: PH-9001 (manufactured by Taisei Fine Chemical Co., Ltd., alkali-soluble urethane polymer, acid value=41, Mw=20,000; diluted liquid with a concentration of solid contents of 40% by mass)
“B12”: VYLON (registered trademark) UR-3500 (manufactured by TOYOBO CO., LTD., urethane-modified polyester, acid value=35, Mw=13,000; diluted liquid with a concentration of solid contents of 40% by mass)
“B13”: COMPOCERAN (registered trademark) SQ109 (manufactured by Arakawa Chemical Industries, Ltd., organic-inorganic hybrid resin; diluted liquid with a concentration of solid contents of 25% by mass)
“B51”: copolymer of tetrahydrofura-2-yl methacrylate (MATHF), MAA, MMA (MATHF:MAA:MMA=40:7:53 (mass ratio), Mw=20,000; diluted liquid with a concentration of solid contents of 30% by mass)
“B52”: copolymer of MATHF, MAA, and 2EMA (MATHF:MAA:2EMA=40:7:53 (mass ratio), Mw=20,000; diluted liquid with a concentration of solid contents of 30% by mass)
“B53”: copolymer of MATHF, MAA, and cyclohexyl methacrylate (CyMA) (MATHF:MAA:CyMA=40:7:53 (mass ratio), Mw=20,000; diluted liquid with a concentration of solid contents of 30% by mass)

### <Polymerizable Compound>

“BPE-500”: ethoxylated bisphenol A dimethacrylate (NK ESTER BPE-500, manufactured by Shin-Nakamura Chemical Co., Ltd.)
“BPE-900”: ethoxylated bisphenol A dimethacrylate (NK ESTER BPE-900, manufactured by Shin-Nakamura Chemical Co., Ltd.)
“23G”: polyethylene glycol dimethacrylate (NK ESTER 23Q manufactured by Shin-Nakamura Chemical Co., Ltd.)
“UA-160TM”: urethane (meth)acrylate (NK OLIGO UA-160TM, manufactured by Shin-Nakamura Chemical Co., Ltd.)
“UA-122P”: urethane (meth)acrylate (NK OLIGO UA-122P, manufactured by Shin-Nakamura Chemical Co., Ltd.)
“A-NOD-N”: 1,9-nonanediol diacrylate (NK ESTER A-NOD-N, manufactured by Shin-Nakamura Chemical Co., Ltd.)
“A-DPH”: dipentaerythritol hexaacrylate (NK ESTER A-DPH, manufactured by Shin-Nakamura Chemical Co., Ltd.)
“AM-30G”: methoxypolyethylene glycol acrylate (NK ESTER AM-3065 manufactured by Shin-Nakamura Chemical Co., Ltd.)

### <Photopolymerization Initiator>

“HABI”: 2,2′-bis(2-chlorophenyl)-4,4′,5,5′-tetraphenyl-1,2′-biimidazole
“379”: Irgacure (registered trademark) 379, manufactured by BASF SE
“OXE-02”: Irgacure (registered trademark) OXE-02, manufactured by BASF SE

### <Photoacid Generator>

“PAG103” Irgacure PAG103, manufactured by BASF SE
“Compound A-1”: compound represented by the following structural formula

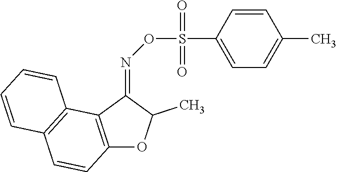 [SMILES: Cc1ccc(S(=O)(=O)O/N=C2/c3c(ccc4ccccc34)OC2C)cc1]

### <Polymerization Inhibitor>

### Phenothiazine

### <Additive>

“EAB-F”: 4,4′-bis(diethylamino)benzophenone (hydrogen donating compound)
“DURANATE (registered trademark) SBN-70D”: manufactured by Asahi Kasei Corporation (blocked isocyanate-based thermal crosslinking compound)
“JER828”: manufactured by Mitsubishi Chemical Holdings Corporation (epoxy-based thermal crosslinking compound)
“CMTU”: compound represented by the following structural formula

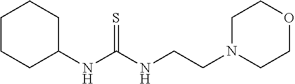 [SMILES: S=C(NCCN1CCOCC1)NC1CCCCC1]

### <Surfactant>

“F-551A”: MEGAFACE (registered trademark) F-551A, manufactured by DIC Corporation, fluorine-based surfactant

### <Solvent>

“PMA”: 1-methoxy-2-propylacetate
“MEK”: methyl ethyl ketone
“PGME”: Propylene glycol monomethyl ether

### [Preparation of Photosensitive Composition]

As a negative tone photosensitive composition, compositions N1 to N25 and N27 to N30, having formulations shown in Table 1, were prepared by mixing and stirring the respective raw materials shown in Table 1.

In addition, as a composition N26, a commercially available product of a negative tone photosensitive composition (TMMR (registered trademark) 52000, manufactured by TOKYO OHKA KOGYO CO., LTD.) was prepared.

In addition, as a positive tone photosensitive composition, compositions P1 to P4, having formulations shown in Table 2, were prepared by mixing and stirring the respective raw materials shown in Table 2.

Table 1 shows the formulations of the compositions N1 to N25 and N27 to N30, which were the negative tone photosensitive composition, and Table 2 shows the formulations of the compositions P1 to P4, which were the positive tone photosensitive composition.

TABLE 1
(1)

| | | Compo- | Compo- | Compo- | Compo- | Compo- | Compo- | Compo- | Compo- | Compo- | Compo- |
|---|---|---|---|---|---|---|---|---|---|---|---|
| | | sition | sition | sition | sition | sition | sition | sition | sition | sition | sition |
| | | N1 | N2 | N3 | N4 | N5 | N6 | N7 | N8 | N9 | N10 |
| Binder | B1 | 574 | | | | | | | | | 574 |
| polymer | B2 | | 574 | | | | | | | | |
| | B3 | | | 574 | | | | | | | |
| | B4 | | | | 574 | | | | | | |
| | B5 | | | | | 574 | | | | | |
| | B6 | | | | | | 574 | | | | |
| | B7 | | | | | | | 574 | | | |
| | B8 | | | | | | | | 574 | | |
| | B9 | | | | | | | | | 574 | |
| | B10 | | | | | | | | | | |
| | B11 | | | | | | | | | | |
| | B12 | | | | | | | | | | |
| | B13 | | | | | | | | | | |
| Polymerizable | BPE-500 | | | | | | | | | | 120 |
| compound | BPE-900 | 120 | 120 | 120 | 120 | 120 | 120 | 120 | 120 | 120 | |
| | 23G | | | | | | | | | | |
| | UA-160TM | | | | | | | | | | |
| | UA-122P | | | | | | | | | | |
| | A-NOD-N | | | | | | | | | | |
| | A-DPH | | | | | | | | | | |
| | AM-30G | | | | | | | | | | |
| Photopolymerization | HABI | 5 | 5 | 5 | 5 | 5 | 5 | 5 | 5 | 5 | 5 |
| initiator | 379 | | | | | | | | | | |
| | OXE-02 | | | | | | | | | | |
| Polymerization | Phenothiazine | 0.20 | 0.20 | 0.20 | 0.20 | 0.20 | 0.20 | 0.20 | 0.20 | 0.20 | 0.20 |
| inhibitor | | | | | | | | | | | |
| Additive | EAB-F | 0.3 | 0.3 | 0.3 | 0.3 | 0.3 | 0.3 | 0.3 | 0.3 | 0.3 | 0.3 |
| | DURANATE | | | | | | | | | | |
| | SBN-70D | | | | | | | | | | |
| | JER828 | | | | | | | | | | |
| Surfactant | F-551A | 0.1 | 0.1 | 0.1 | 0.1 | 0.1 | 0.1 | 0.1 | 0.1 | 0.1 | 0.1 |
| Solvent | PMA | 100 | 100 | 100 | 100 | 100 | 100 | 100 | 100 | 100 | 100 |
| | MEK | 100 | 100 | 100 | 100 | 100 | 100 | 100 | 100 | 100 | 100 |
| | PGME | 100 | 100 | 100 | 100 | 100 | 100 | 100 | 100 | 100 | 100 |

TABLE 1
(2)

| | | Compo- | Compo- | Compo- | Compo- | Compo- | Compo- | Compo- | Compo- | Compo- | Compo- |
|---|---|---|---|---|---|---|---|---|---|---|---|
| | | sition | sition | sition | sition | sition | sition | sition | sition | sition | sition |
| | | N11 | N12 | N13 | N14 | N15 | N16 | N17 | N18 | N19 | N20 |
| Binder | B1 | 574 | 574 | 574 | 574 | 574 | 574 | 574 | 574 | 534 | 604 |
| polymer | B2 | | | | | | | | | | |
| | B3 | | | | | | | | | | |
| | B4 | | | | | | | | | | |
| | B5 | | | | | | | | | | |
| | B6 | | | | | | | | | | |
| | B7 | | | | | | | | | | |
| | B8 | | | | | | | | | | |
| | B9 | | | | | | | | | | |
| | B10 | | | | | | | | | | |
| | B11 | | | | | | | | | | |
| | B12 | | | | | | | | | | |
| | B13 | | | | | | | | | | |
| Polymerizable | BPE-500 | | | | | | | | | | |
| compound | BPE-900 | | | | | 100 | 100 | 90 | 60 | 160 | 90 |
| | 23G | 120 | | | | | | | 60 | | |
| | UA-160TM | | 120 | | | | | | | | |
| | UA-122P | | | 120 | | | | | | | |
| | A-NOD-N | | | | 120 | | | 10 | | | |
| | A-DPH | | | | | 20 | | 10 | | | |
| | AM-30G | | | | | | 20 | 10 | | | |
| Photopolymerization | HABI | 5 | 5 | 5 | 5 | 5 | 5 | 5 | 5 | 5 | 5 |
| initiator | 379 | | | | | | | | | | |
| | OXE-02 | | | | | | | | | | |
| Polymerization | Phenothiazine | 0.20 | 0.20 | 0.20 | 0.20 | 0.20 | 0.20 | 0.20 | 0.20 | 0.20 | 0.20 |
| inhibitor | | | | | | | | | | | |
| Additive | EAB-F | 0.3 | 0.3 | 0.3 | 0.3 | 0.3 | 0.3 | 0.3 | 0.3 | 0.3 | 0.3 |
| | DURANATE | | | | | | | | | | |
| | SBN-70D | | | | | | | | | | |
| | JER828 | | | | | | | | | | |
| Surfactant | F-551A | 0.1 | 0.1 | 0.1 | 0.1 | 0.1 | 0.1 | 0.1 | 0.1 | 0.1 | 0.1 |
| Solvent | PMA | 100 | 100 | 100 | 100 | 100 | 100 | 100 | 100 | 100 | 100 |
| | MEK | 100 | 100 | 100 | 100 | 100 | 100 | 100 | 100 | 100 | 100 |
| | PGME | 100 | 100 | 100 | 100 | 100 | 100 | 100 | 100 | 100 | 100 |

TABLE 1
(3)

| | | Compo- | Compo- | Compo- | Compo- | Compo- | Compo- | Compo- | Compo- | Compo- |
|---|---|---|---|---|---|---|---|---|---|---|
| | | sition | sition | sition | sition | sition | sition | sition | sition | sition |
| | | N21 | N22 | N23 | N24 | N25 | N27 | N28 | N29 | N30 |
| Binder | B1 | 577 | 577 | 534 | 534 | 574 | 334 | 267 | 267 | 334 |
| polymer | B2 | | | | | | | | | |
| | B3 | | | | | | | | | |
| | B4 | | | | | | | | | |
| | B5 | | | | | | | | | |
| | B6 | | | | | | | | | |
| | B7 | | | | | | | | | |
| | B8 | | | | | | | | | |
| | B9 | | | | | | | | | |
| | B10 | | | | | | 60 | | | |
| | B11 | | | | | | | 200 | | |
| | B12 | | | | | | | | 200 | |
| | B13 | | | | | | | | | 240 |
| Polymerizable | BPE-500 | | | | | | | | | |
| compound | BPE-900 | 120 | 120 | 110 | 110 | 120 | 120 | | 120 | 120 |
| | 23G | | | | | | | | | |
| | UA-160TM | | | | | | | | | |
| | UA-122P | | | | | | | 120 | | |
| | A-NOD-N | | | | | | | | | |
| | A-DPH | | | | | | | | | |
| | AM-30G | | | | | | | | | |
| Photopolymerization initiator | HABI | | | 5 | 5 | 5 | 5 | 5 | 5 | 5 |
| | 379 | 3 | | | | | | | | |
| | OXE-02 | | 3 | | | | | | | |
| Polymerization | Phenothiazine | 0.20 | 0.20 | 0.20 | 0.20 | 0.20 | 0.20 | 0.20 | 0.20 | 0.20 |
| inhibitor | | | | | | | | | | |
| Additive | EAB-F | | | 0.3 | 0.3 | 0.3 | 0.3 | 0.3 | 0.3 | 0.3 |
| | DURANATE | | | 50 | | | | | | |
| | SBN-70D | | | | | | | | | |
| | JER828 | | | | 50 | | 50 | 50 | 50 | 50 |
| Surfactant | F-551A | 0.1 | 0.1 | 0.1 | 0.1 | 0.1 | 0.1 | 0.1 | 0.1 | 0.1 |
| Solvent | PMA | 100 | 100 | 100 | 100 | 100 | 100 | 100 | 100 | 50 |
| | MEK | 100 | 100 | 100 | 100 | 100 | 200 | 157 | 157 | 100 |
| | PGME | 100 | 100 | 100 | 100 | 100 | 130 | 100 | 100 | 100 |

TABLE 2

| | | Compo- | Compo- | Compo- | Compo- |
|---|---|---|---|---|---|
| | | sition | sition | sition | sition |
| | | P1 | P2 | P3 | P4 |
| Binder | B51 | 574 | 574 | | |
| polymer | B52 | | | 574 | |
| | B53 | | | | 574 |
| Photoacid | PAG 103 | 5 | | | |
| generator | Compound A-1 | | 5 | 5 | 5 |
| Additive | CMTU | 0.50 | 0.50 | 0.50 | 0.50 |
| Surfactant | F-551A | 0.1 | 0.1 | 0.1 | 0.1 |
| Solvent | MEK | 200 | 200 | 200 | 200 |
| | PGME | 220 | 220 | 220 | 220 |

### Example 1

### [Manufacturing of Resin Membrane Filter]

### <Formation of Photosensitive Composition Layer (Step P1-a)>

The composition N1 was applied onto a surface of a temporary support consisting of a polyethylene terephthalate (PET) film (LUMIRROR (registered trademark) #50-T60, manufactured by Toray Industries, Inc.) having a thickness of 50 μm, and the formed coating film was dried. As a result, a laminate including the temporary support and a photosensitive composition layer having a film thickness of 15 μm was produced.

Furthermore, a polypropylene (PP) film (TORAYFAN (registered trademark) #25A-KW37, manufactured by Toray Industries, Inc.) having a thickness of 25 μm was superimposed on the laminate as a cover film so as to be in contact with the photosensitive composition layer, thereby producing a dry film DF1 having a layer configuration consisting of temporary support/photosensitive composition layer/cover film.

### <Exposing Step (Step P2)>

As an exposure mask, a photo mask 1 in which circular light shielding units having a diameter of 3 μm were arranged in a staggered pattern with an angle of 60° was prepared. A pitch (distance between centers of two adjacent light shielding units) of the light shielding units in the photo mask 1 was 20 μm. That is, in the photo mask 1, a lattice unit consisting of an equilateral triangle with a side of 20 μm and an angle of 60° was formed by three adjacent light shielding units, and the formed lattice units constituted a staggered pattern.

The cover film was peeled off from the dry film DF1. Next, using an ultra-high pressure mercury lamp proximity exposure machine, pattern exposure was performed by irradiating the photosensitive composition layer with ultraviolet rays through the photo mask. At this time, contact exposure was performed with an exposure gap of 0 μm by bringing the photo mask and the photosensitive composition layer into contact with each other. An exposure amount was 100 mJ/cm² in terms of i-rays (wavelength: 365 nm). In addition, in the pattern exposure, the surface of the photosensitive composition layer was irradiated with ultraviolet rays from a perpendicular) (90°) direction.

### <Developing Step (Step P3)>

The pattern-exposed dry film DF1 was immersed for 60 seconds in a developer consisting of a 1% by mass sodium carbonate aqueous solution (liquid temperature: 25° C.) (dip development). The developed laminate was immersed and washed in pure water having a liquid temperature of 25° C. for 60 seconds to remove a non-exposed portion.

### <Peeling Step (Step P4-a)>

A tape was attached to an end part of the developed photosensitive composition layer, and the attached tape was pulled to peel off the developed photosensitive composition layer from the temporary support. More specifically, the peeling was carried out under conditions of a peeling angle of 180° and a peeling rate of 1 m/min while maintaining a state in which the tape was attached to the end part of the developed photosensitive composition layer.

By the above-described method, a resin membrane filter of Example 1, having a plurality of through-holes which penetrated both main surfaces and were arranged in a 60° staggered pattern, was manufactured.

### Example 2

A resin membrane filter was manufactured according to the method described in Example 1, except that, in the exposing step (step P2), ultraviolet rays were radiated from a direction forming an angle of 60° with respect to the surface of the photosensitive composition layer.

### Example 3

As an exposure mask, a photo mask 2 in which a plurality of light shielding units were arranged in the same arrangement pattern as the photo mask 1 and circular light shielding units having a diameter of 3 μm and circular light shielding units having a diameter of 4 μm were randomly formed at the position of each light shielding unit at a number ratio of 98:2 was prepared. A resin membrane filter was manufactured according to the method described in Example 1, except that, in the exposing step (step P2), the pattern exposure was performed using the photo mask 2.

### Example 4

A resin membrane filter was manufactured according to the method described in Example 1, except that, in the developing step (step P3), the pattern-exposed dry film DF1 was immersed for 30 seconds in a developer consisting of a 1% by mass sodium carbonate aqueous solution (liquid temperature: 25° C.).

### Examples 5 to 8

As an exposure mask, a photo mask 3 in which circular light shielding units having a diameter of 12 μm were arranged in a staggered pattern with a pitch of 20 μm and an angle of 60°, a photo mask 4 in which circular light shielding units having a diameter of 6 μm were arranged in a staggered pattern with a pitch of 20 μm and an angle of 60°, a photo mask 5 in which circular light shielding units having a diameter of 3 μm were arranged in a staggered pattern with a pitch of 50 μm and an angle of 60°, and a photo mask 6 in which square light shielding units with a side of 3 μm were arranged in a staggered pattern with a pitch of 20 μm and an angle of 60° were each prepared.

Each resin membrane filter of Examples 5 to 8 was manufactured according to the method described in Example 1, except that, the pattern exposure was performed using each of the photo masks 3 to 6 instead of the photo mask 1.

### Example 9

A dry film DF51 was produced according to the method described in the step P1-a of Example 1, except that the composition N1 was applied onto the surface of the temporary support to form a coating film, in which the coating amount of the composition N1 was adjusted so that the film thickness of the photosensitive composition layer obtained by drying the formed coating film was 9 μm.

A resin membrane filter was manufactured according to the method described in Example 1, except that the produced dry film DF51 was used instead of the dry film D1.

### Example 10

A pattern-exposed dry film DF1 was produced according to the methods described in the step P1-a and the step P2 of Example 1.

### <Peeling Step (Step P4-a)>

A tape was attached to an end part of the pattern-exposed photosensitive composition layer, and the attached tape was pulled to peel off the pattern-exposed photosensitive composition layer from the temporary support. More specifically, the peeling was carried out under conditions of a peeling angle of 180° and a peeling rate of 1 m/min while maintaining a state in which the tape was attached to the end part of the pattern-exposed photosensitive composition layer.

### <Developing Step (Step P3)>

The pattern-exposed photosensitive composition layer obtained by the peeling was immersed for 60 seconds in a developer consisting of a 1% by mass sodium carbonate aqueous solution (liquid temperature: 25° C.) (dip development). Next, the developed photosensitive composition layer was immersed and washed in pure water having a liquid temperature of 25° C. for 60 seconds to remove a non-exposed portion, thereby manufacturing a resin membrane filter.

### Example 11

### [Preparation of Coating Liquid for Forming Water-Soluble Resin Layer]

Each of the following components was mixed to prepare a coating liquid for forming a water-soluble resin layer.
Polyvinyl alcohol (KURARAY POVAL (registered trademark) PVA-205, manufactured by KURARAY CO., LTD.): 227 parts by mass
Polyvinylpyrrolidone (K-30, manufactured by NIPPON SHOKUBAI CO., LTD.): 105 parts by mass
Fluorine-based surfactant (MEGAFACE (registered trademark) F-444, manufactured by DIC Corporation): 0.1 parts by mass
Ion exchange water: 401 parts by mass
Methanol: 267 parts by mass

### [Manufacturing of Resin Membrane Filter]

### <Formation of Photosensitive Composition Layer (Step P1-b)>

The coating liquid for forming a water-soluble resin layer was applied onto a surface of a temporary support consisting of a polyethylene terephthalate (PET) film (LUMIRROR (registered trademark) #50-T60, manufactured by Toray Industries, Inc.) having a thickness of 50 μm, and the formed coating film was dried to form a water-soluble resin layer. Next, the composition N1 was applied onto the surface of the formed water-soluble resin layer, and the formed coating film was dried. As a result, a laminate including the temporary support, a water-soluble resin layer having a film thickness of 1 μm, and a photosensitive composition layer having a film thickness of 15 μm was produced.

Furthermore, a polypropylene (PP) film (TORAYFAN (registered trademark) #25A-KW37, manufactured by Toray Industries, Inc.) having a thickness of 25 μm was superimposed on the laminate as a cover film so as to be in contact with the photosensitive composition layer, thereby producing a dry film DF52 having a layer configuration consisting of temporary support/water-soluble resin layer/photosensitive composition layer/cover film.

### <Exposing Step (Step P2) and Developing Step (Step P3-a)>

Pattern exposure was performed according to the method described in the step P2 of Example 1, except that the produced dry film DF52 was used instead of the dry film DF1.

Next, the pattern-exposed dry film DF52 was developed according to the method described in the step P3 of Example 1.

### <Peeling Step (Step P4-b)>

The dry film DF52 including the developed photosensitive composition layer, the water-soluble resin layer, and the temporary support was immersed in hot water having a liquid temperature of 80° C. Eventually, the water-soluble resin layer was dissolved in the hot water, and the temporary support and the developed photosensitive composition layer were separated from each other. Hot water having a liquid temperature of 80° C. was poured into the developed photosensitive composition layer obtained by recovery to remove residues, followed by drying to manufacture a resin membrane filter.

### Example 12

### [Manufacturing of Resin Membrane Filter]

### <Formation of Photosensitive Composition Layer (Step P1-c)>

A dry film DF53 having a layer configuration consisting of water-soluble temporary support/photosensitive composition layer/cover film was produced according to the method described in the step P1-a of Example 1, except that a water-soluble film (Solublon EF, manufactured by Aicello Chemical Co., Ltd., polyvinyl alcohol (PVA) made) having a thickness of 50 μm was used as the temporary support instead of the PET film.

<Exposing Step (step P2) and Developing Step (Step P3-a)>

Pattern exposure was performed according to the method described in the step P2 of Example 1, except that the produced dry film DF53 was used instead of the dry film DF1.

Next, the pattern-exposed dry film DF53 was developed according to the method described in the step P3 of Example 1.

### <Peeling Step (Step P4-c)>

The dry film DF53 including the developed photosensitive composition layer and the water-soluble temporary support was immersed in hot water having a liquid temperature of 80° C. Eventually, the water-soluble temporary support was dissolved in the hot water, and a single membrane of the developed photosensitive composition layer was obtained. Hot water having a liquid temperature of 80° C. was poured into the developed photosensitive composition layer obtained by recovery to remove residues, followed by drying to manufacture a resin membrane filter.

### Comparative Example 1

As an exposure mask, a photo mask C1 in which a plurality of light shielding units were arranged in the same arrangement pattern as the photo mask 1 and circular light shielding units having a diameter of 3 μm and circular light shielding units having a diameter of 5 μm were randomly formed at the position of each light shielding unit at a number ratio of 95:5 was prepared. A resin membrane filter was manufactured according to the method described in Example 1, except that, in the exposing step (step P2), the pattern exposure was performed using the photo mask C1.

### Comparative Example 2

A PET film (LUMIRROR (registered trademark) #16-T70, manufactured by Toray Industries, Inc.) having a thickness of 15 μm was accommodated in an irradiation chamber located downstream of a beam line connected to an azimuthally varying field (AVF) cyclotron, and a pressure inside the irradiation chamber was reduced to 1.0×10⁻⁴ Pa. Next, the PET film was irradiated with a xenon ion beam (energy: 350 MeV). The irradiation with a xenon ion beam was carried out at an irradiation density of 3×10⁵ pieces/cm² along a direction perpendicular to the main surface of the PET film. The irradiated PET film was taken out from the irradiation chamber and then subjected to chemical etching to form through-holes (average hole diameter: 3.8 μm) corresponding to ion tracks of xenon ions in the PET film, thereby obtaining a resin membrane filter. The chemical etching was carried out by immersing the PET film in a sodium hydroxide aqueous solution (concentration: 1.0 M, temperature: 60° C.) for 30 minutes.

### Comparative Example 3

While moving a PET film (LUMIRROR #16-T70, manufactured by Toray Industries, Inc.) having a thickness of 15 μm from one main surface toward the other main surface at a moving speed of 8000 pm/s, the PET film was irradiated with a titanium-sapphire femtosecond pulse laser with an irradiation wavelength of 780 nm, a pulse width of 140 femtoseconds, and a repetition rate of 1 kHz under conditions of an irradiation output of 50 mW, an objective lens magnification of 10 times, and an irradiation spot diameter of approximately 5 μm. Thereafter, the irradiated PET film was subjected to ultrasonic washing in pure water to obtain a resin membrane filter having micro through-holes.

### Comparative Example 4

As an exposure mask, a metal mask in which circular holes having a diameter of 3.5 μm were arranged in a staggered pattern with an angle of 60° was prepared. The prepared metal mask was disposed on a surface of a 15 μm-thick PET film (LUMIRROR #16-T70, manufactured by Toray Industries, Inc.) in contact with each other, and reactive ion etching (RIE) was carried out through the metal mask to form through-holes in the PET film, thereby obtaining a resin membrane filter.

### Examples 13 to 41

Dry films DF2 to DF30 each having a layer configuration of temporary support/photosensitive composition layer/cover film were produced according to the method described in the step P1-a of Example 1, except that the compositions N2 to N30 prepared by the above-described method each were used instead of the composition N1.

Next, resin membrane filters of Examples 13 to 41, each having a plurality of through-holes which penetrated both main surfaces and were arranged in a 60° staggered pattern, were manufactured according to the methods described in the step P2, the step P3, and the step P4-a of Example 1, except that the produced dry films DF2 to DF30 each were used instead of the dry film DF1.

### Example 42

A dry film DF31 having a layer configuration consisting of temporary support/photosensitive composition layer/cover film was produced according to the method described in the step P1-a of Example 1, except that, in the production of the dry film DF1, the coating amount was adjusted so that the film thickness of the photosensitive composition layer was 20 μm.

Next, a resin membrane filter of Example 42, having a plurality of through-holes which penetrated both main surfaces and were arranged in a 60° staggered pattern, was manufactured according to the methods described in the step P2, the step P3, and the step P4-a of Example 1, except that the produced dry film DF31 was used instead of the dry film DF1.

### Example 101

### <Formation of Photosensitive Composition Layer (Step P1-a)>

A dry film DF101 having a layer configuration of temporary support/positive tone photosensitive composition layer/cover film was produced according to the method described in the step P1-a of Example 1, except that the composition P1 prepared by the above-described method was used instead of the composition N1.

### <Exposing Step (Step P2)>

As an exposure mask, a photo mask 101 in which circular hole portions having a diameter of 3 μm were arranged in a staggered pattern with an angle of 60° was prepared. A pitch (distance between centers of two adjacent hole portions) of the hole portions in the photo mask 101 was 20 μm. That is, in the photo mask 101, a lattice unit consisting of an equilateral triangle with a side of 20 μm and an angle of 60° was formed by three adjacent hole portions, and the formed lattice units constituted a staggered pattern.

The cover film was peeled off from the dry film DF101. Next, using an ultra-high pressure mercury lamp proximity exposure machine, pattern exposure was performed by irradiating the positive tone photosensitive composition layer with ultraviolet rays through the photo mask 101. At this time, contact exposure was performed with an exposure gap of 0 μm by bringing the photo mask and the positive tone photosensitive composition layer into contact with each other. An exposure amount was 100 mJ/cm² in terms of i-rays (wavelength: 365 nm). In addition, in the pattern exposure, the surface of the positive tone photosensitive composition layer was irradiated with ultraviolet rays from a perpendicular (90°) direction.

### <Developing Step (Step P3) and Peeling Step (Step P4-a)>

A resin membrane filter of Example 101, having a plurality of through-holes which penetrated both main surfaces and were arranged in a 60° staggered pattern, was manufactured according to the methods described in the step P3 and the step P4-a of Example 1, except that the dry film DF101 exposed in a patterned manner as the above-described method was used instead of the dry film DF1.

### Examples 102 to 104

Resin membrane filters were manufactured according to the method described in Example 101, except that the compositions P2 to P4 prepared by the above-described method were used instead of the composition P1.

### [Measurement and Evaluation]

### [Measurement of Shape of Through-Hole]

The shape and the like of the through-hole included in the resin membrane filter manufactured by each of Examples and Comparative Examples were measured by the following method.

The manufactured resin membrane filter was embedded in an embedding resin (Epok812, manufactured by Okenshoji Co., Ltd.). The resin membrane filter embedded in the embedding resin was polished from one surface (first main surface) side by chemical mechanical polishing (CMP) so that the polished surface was parallel to the first main surface. The polishing by CMP was carried out until the position A at a distance (depth) of 10% of the thickness of the resin membrane filter was reached.

In a cross section of the resin membrane filter at the position A, which was exposed by the polishing treatment, ten regions each having an area of 1 square millimeter were randomly selected, and each region was observed with SEM (“JSM-7200 type FE-SEM” manufactured by JEOL Ltd.). Among through-holes observed in each of the obtained observation images, 100 through-holes were randomly selected, and areas of opening portions of a total of 1000 selected through-holes were measured.

An average area Sva of the opening portions of the through-holes at the position A was calculated from the measured area of the opening portion of each through-hole, and based on the calculated average area Sva, a number ratio Ra of through-holes larger than 1.25 times the average area Sva was calculated.

In the same manner, the polishing treatment by CMP was carried out until the position B at a distance (depth) of 90% of the thickness of the resin membrane filter from the first main surface side was reached. In the same manner as the measurement at the position A, ten regions in the cross section of the resin membrane filter at the position B, which was exposed by the polishing treatment, were observed with the SEM, 100 through-holes observed in each of the obtained observation images were measured, and an average area Svb of the opening portions of the through-holes at the position B and a number ratio Rb of through-holes larger than 1.25 times the average area Svb were calculated.

Furthermore, a ratio “Svb/Sva” of the average area of the opening portion was calculated from the obtained average areas Sva and Svb of the opening portions of the through-holes at the positions A and B.

In addition, in the observed image of the cross section of the resin membrane filter at the position A, which was observed by the above-described method, the number of through-holes present in an observation area of 1 square millimeter was measured, and a number density (unit: holes/cm 2) of through-holes per area of the resin membrane filter was determined.

In addition, in the observed image of the cross section of the resin membrane filter at the position A, which was observed by the above-described method, the shape of the opening portion of each through-hole selected was measured. Based on the obtained measurement results, an average hole diameter of the opening portions of the through-hole and a standard deviation of a hole diameter distribution were calculated, and a number ratio Rr of through-holes in which a hole diameter was 0.9 to 1.1 times the average hole diameter of the total 1000 through-holes selected was determined.

In addition, a sample was produced by embedding the manufactured resin membrane filter in the embedding resin according to the above-described method. The produced sample was polished by CMP so that the polished surface was parallel to the first main surface, in which the polishing treatment by CMP was carried out until a position at a distance (depth) of 5% of the thickness of the resin membrane filter from the first main surface side was reached. A cross section of the resin membrane filter at the position A, which was exposed by the polishing treatment, was observed with the SEM to obtain an observation image.

Similarly to the above, the sample was polished by CMP from the first main surface side, and a cross section parallel to the first main surface was observed with SEM at each position which was at a distance of 10% (position A), 20%, 30%, 40%, 50%, 60%, 70%, 80%, 90% (position B), and 95% of the thickness of the resin membrane filter from the first main surface side.

Data of the observation image of each cross section obtained by the above-described CMP polishing treatment and image data of observation images obtained by observing the first main surface and the second main surface of the resin membrane filter, obtained in advance using SEM, were superimposed three-dimensionally using a computer to create a three-dimensional image of the resin membrane filter. From the three-dimensional image, an angle (tilt angle of the through-hole; unit: °) between the extending direction of the through-hole and the normal direction to the first main surface (and the second main surface) of the resin membrane filter was calculated.

1000 through-holes were randomly selected from the three-dimensional image obtained as above. An arithmetic average value of tilt angles of the selected through-holes was calculated, and a number ratio Rt of through-holes in which the tilt angle of the through-holes among the 1000 through-holes selected was within 5° was determined.

In addition, based on the three-dimensional image obtained as above, a curvature radius of an outline of the resin membrane filter at both end parts of the first main surface and the second main surface of the through-hole was calculated, and it was confirmed whether a gently curved portion with a curvature radius of 1 μm or more existed at at least one end part of the through-hole.

### [Measurement of Resin Membrane Filter]

The thickness of the resin membrane filter manufactured by each of Examples and Comparative Examples was measured using SEM by the above-described method.

In addition, using a contact angle meter (automatic contact angle meter “DMo-602”, manufactured by Kyowa Interface Science Co., Ltd.), a static contact angle (°) of the surface (first main surface and second main surface) of the resin membrane filter with water was measured by a liquid droplet method.

### [Evaluation of Separation Accuracy]

The resin membrane filter manufactured by each of Examples and Comparative Examples was cut to produce a circular sample having a diameter of 47 mm. A dispersion liquid in which silica particles having a particle diameter of 1 to 20 μm were dispersed was allowed to pass through a surface of the obtained sample. A particle size distribution of silica particles contained in each of the dispersion liquid before passing and the purified liquid after passing was measured using a laser diffraction particle distribution measuring device “SALD-2300” manufactured by Shimadzu Corporation. In addition, among the silica particles contained in each of the dispersion liquid before passing and the purified liquid after passing, a content of silica particles having a size equal to or larger than the average hole diameter of the through-holes in each sample was calculated, and a proportion of decrease in content of the silica particles having the size was derived as a capture rate (unit: number %) of the silica particles by purification using the sample.

In order to obtain the number of particles from the particle distribution, standard particles of which the size and number were known were added to the liquid to be measured, and the number thereof could be obtained from comparison with the number thereof.

From the obtained capture rate, separation accuracy of each sample was evaluated based on the following evaluation standard. In a case where the evaluation was 3 or more, it was considered that the level had no problem in practical use. The evaluation results of the separation accuracy are shown in Tables 3 to 5 later.

### (Evaluation Standard of Separation Accuracy)

5: capture rate was 95% or more.
4: capture rate was 90% or more and less than 95%.
   3: capture rate was 85% or more and less than 90%.
   2: capture rate was 80% or more and less than 85%.
   1: capture rate was less than 80%.

### [Evaluation of Toughness of Resin Membrane Filter]

The resin membrane filter manufactured by each of Examples and Comparative Examples was cut to produce a circular sample having a diameter of 47 mm Pure water was allowed to pass through the sample at a pressure of 150 mmHg for 10 minutes. After performing the pass treatment, the surface of the sample was visually observed and observed with an optical microscope to confirm the presence or absence of tearing of the sample. In the observation with an optical microscope, a region having an area of 1 mm² on the surface of the sample was observed. From the observation results, toughness of the sample was evaluated based on the following evaluation standard. In a case where the evaluation was 4 or more, it was considered that the level had no problem in practical use. The evaluation results of the toughness are shown in Tables 3 to 5 later.

### (Evaluation Standard of Toughness)

5: no tearing was observed in both the visual observation and the observation with an optical microscope.
4: no tearing was observed in the visual observation, but several tearing of the through-holes were observed in the case of using an optical microscope.
3: no tearing was observed in the visual observation, but many tearing of the through-holes were observed in the case of using an optical microscope.
2: slight tearing was observed in the visual observation.
1: many tearing were observed in the visual observation.

Regarding each of Examples and Comparative Examples, Tables 3 to 5 show the dry film used to manufacture the resin membrane filter, the conditions of the exposing step, the developing step, and the peeling step, each characteristic of the manufactured resin membrane filter, and each evaluation result.

In the tables, the column of “Dry film” indicates the number of the dry film used.

The column of “Photo mask” in “Exposing step” indicates the shape and arrangement of the light shielding units or the opening portions of the photo mask used.

The column of “Exposure angle”, the column of “Exposure gap [pin]”, and the column of “Exposure amount [mJ/cm²]” in “Exposing step” indicate each condition of the exposing step.

A case where “Before peeling step” is described in the column of “Performing order” in “Developing step” indicates that the developing step was performed before the peeling step, and a case where “After peeling step” is described indicates that the developing step was performed after the peeling step.

In the tables, the column of “Physical properties of resin membrane filter” indicates each physical property value measured by the above-described method for the resin membrane filter produced in each of Examples and Comparative Examples.

The column of “Standard deviation/average hole diameter” indicates the ratio (unit: %) of the standard deviation of the hole diameter distribution to the average hole diameter of the opening portions of the through-hole.

A case where “Y” is described in the column of “Curved portion of end part of through-hole” indicates that a curved portion having a curvature radius of 1 μm or more was formed at at least one end part of the through-hole, and a case where “N” is described in the column of “Curved portion of end part of through-hole” indicates that a curved portion having a curvature radius of 1 μm or more was not formed at both end parts of the through-hole.

TABLE 3
(1)

| | | Example 1 | Example 2 | Example 3 | Example 4 | Example 5 | Example 6 | Example 7 |
|---|---|---|---|---|---|---|---|---|
| Dry film | | DF1 | DF1 | DF1 | DF1 | DF1 | DF1 | DF1 |
| Exposing | Photo mask | Circular | Circular | Circular | Circular | Circular | Circular | Circular |
| step | | staggered | staggered | staggered | staggered | staggered | staggered | staggered |
| | | arrangement | arrangement | arrangement | arrangement | arrangement | arrangement | arrangement |
| | | (diameter: 3 μm) | (diameter: 3 μm) | (diameter: 3 μm) | (diameter: mixed) | (diameter: 12 μm) | (diameter: 6 μm) | (diameter: 3 μm) |
| | | with pitch of 20μm | with pitch of 20μm | with pitch of 20μm | with pitch of 20μm | with pitch of 20μm | with pitch of 20μm | with pitch of 20μm |
| | | and angle of 60° | and angle of 60° | and angle of 60° | and angle of 60° | and angle of 60° | and angle of 60° | and angle of 60° |
| | Exposure angle | Perpendicular | 60° | Perpendicular | Perpendicular | Perpendicular | Perpendicular | Perpendicular |
| | | (90°) | | (90°) | (90°) | (90°) | (90°) | (90°) |
| | Exposure gap [μm] | 0 | 0 | 0 | 0 | 0 | 0 | 0 |
| | Exposure amount | 100 | 100 | 100 | 100 | 100 | 100 | 100 |
| | [mJ/cm²] | | | | | | | |
| Developing | Development | 25° C., | 25° C., | 25° C., | 25° C., | 25° C., | 25° C., | 25° C., |
| step | condition | 60 seconds | 60 seconds | 60 seconds | 60 seconds | 60 seconds | 60 seconds | 60 seconds |
| | Order of | Before | Before | Before | Before | Before | Before | Before |
| | implementation | peeling step | peeling step | peeling step | peeling step | peeling step | peeling step | peeling step |
| Peeling step | | Physically | Physically | Physically | Physically | Physically | Physically | Physically |
| | | peeling | peeling | peeling | peeling | peeling | peeling | peeling |
| Physical | Sva[μm²] | 7.0 | 7.0 | 11.0 | 7.0 | 113.0 | 28.3 | 7.0 |
| properties | Svb[μm²] | 7.0 | 7.0 | 11.0 | 7.0 | 113.0 | 28.3 | 7.0 |
| of resin | Sva/Svb | 1.0 | 1.0 | 1.0 | 1.0 | 1.0 | 1.0 | 1.0 |
| membrane | Number ratio Ra | 0.5% | 0.5% | 2.0% | 0.5% | 0.5% | 0.5% | 0.5% |
| filter | Number ratio Rb | 0.5% | 0.5% | 2.0% | 0.5% | 0.5% | 0.5% | 0.5% |
| | Tilt angle of | 0 | 30 | 0 | 0 | 0 | 0 | 0 |
| | through-hole [°] | | | | | | | |
| | Number ratio Rt | 99.5% | 0.5% | 99.5% | 99.5% | 99.5% | 99.5% | 99.5% |
| | Average hole | 3 | 3 | 3.8 | 3 | 12 | 6 | 3 |
| | diameter [μm] | | | | | | | |
| | Number ratio Rr | 99.5% | 99.5% | 95.0% | 99.5% | 99.5% | 99.5% | 99.5% |
| | Standard deviation of hole | 0.08 | 0.08 | 0.12 | 0.08 | 0.2 | 0.15 | 0.08 |
| | diameter distribution [μm] | | | | | | | |
| | Standard deviation/ | 2.7% | 2.7% | 3.2% | 2.7% | 1.7% | 2.5% | 2.7% |
| | average hole diameter | | | | | | | |
| | Density of through- | 3 × 10⁵ | 3 × 10⁵ | 3 × 10⁵ | 3 × 10⁵ | 3 × 10⁵ | 3 × 10⁵ | 5 × 10⁴ |
| | holes [holes/cm²] | | | | | | | |
| | Curved portion of end | Y | Y | Y | N | Y | Y | Y |
| | part of through-hole | | | | | | | |
| | Thickness of resin | 15 | 15 | 15 | 15 | 15 | 15 | 15 |
| | membrane filter [μm] | | | | | | | |
| | Contact angle of | 50 | 50 | 50 | 50 | 50 | 50 | 50 |
| | main surface [°] | | | | | | | |
| Evaluation | Separation accuracy | 5 | 5 | 4 | 5 | 4 | 5 | 5 |
| result | Toughness | 5 | 4 | 5 | 4 | 4 | 4 | 5 |

TABLE 3
(2)

| | | | | | | | Comparative | Comparative | Comparative | Comparative |
|---|---|---|---|---|---|---|---|---|---|---|
| | | Example 8 | Example 9 | Example 10 | Example 11 | Example 12 | Example 1 | Example 2 | Example 3 | Example 4 |
| Dry film | | DF1 | DF51 | DF1 | DF52 | DF53 | DF1 | PET film | PET film | PET film |
| Exposing | Photo mask | Square | Circular | Circular | Circular | Circular | Circular | Ion beam | Laser | RIE |
| step | | staggered | staggered | staggered | staggered | staggered | staggered | irradiation | processing | |
| | | arrangement | arrangement | arrangement | arrangement | arrangement | arrangement | | | |
| | | (one side: 3 | (diameter: 3 | (diameter: 3 | (diameter: 3 | (diameter: 3 | (diameter: | | | |
| | | μm) with pitchμm) | μm) with pitch | μm) with pitch | μm) with pitch | μm) with pitch | mixed) with | | | |
| | | of 20 μm and | of 20 μm and | of 20 μm and | of 20 μm and | of 20 μm and | pitch of 20 μm | | | |
| | | angle of 60° | angle of 60° | angle of 60° | angle of 60° | angle of 60° | and angle of | | | |
| | | | | | | | 60° | | | |
| | Exposure angle | Perpendicular | Perpendicular | Perpendicular | Perpendicular | Perpendicular | Perpendicular | | | |
| | | (90°) | (90°) | (90°) | (90°) | (90°) | (90°) | | | |
| | Exposure gap | 0 | 0 | 0 | 0 | 0 | 0 | | | |
| | [μm] | | | | | | | | | |
| | Exposure amount | 100 | 100 | 100 | 100 | 100 | 100 | | | |
| | [mJ/cm²] | | | | | | | | | |
| Developing | Development | 25° C., 60 | 25° C., 60 | 25° C., 60 | 25° C., 60 | 25° C., 60 | 25° C., 60 | 60° C., 30 | | |
| step | condition | seconds | seconds | seconds | seconds | seconds | seconds | minutes | | |
| | Order of | Before | Before | Before | Before | Before | Before | — | | |
| | implementation | peeling step | peeling step | peeling step | peeling step | peeling step | peeling step | | | |
| Peeling step | | Physically | Physically | Physically | Dissolving | Dissolving | Physically | — | | |
| | | peeling | peeling | peeling | water-soluble | water-soluble | peeling | | | |
| | | | | | resin layer | resin layer | | | | |
| Physical | Sva[μm²] | 9.0 | 7.0 | 7.0 | 7.0 | 7.0 | 13.6 | 9.5 | 9.0 | 10.0 |
| properties | Svb[μm²] | 9.0 | 7.0 | 7.0 | 7.0 | 7.0 | 12.6 | 7.5 | 9.0 | 8.0 |
| of resin | Sva/Svb | 1.0 | 1.0 | 1.0 | 1.0 | 1.0 | 1.1 | 1.3 | 1.0 | 1.3 |
| membrane | Number ratio Ra | 0.5% | 0.5% | 0.5% | 0.5% | 0.5% | 5.0% | 10.0% | 15.0% | 8.0% |
| filter | Number ratio Rb | 0.5% | 0.5% | 0.5% | 0.5% | 0.5% | 5.0% | 10.0% | 15.0% | 8.0% |
| | Tilt angle of | 0 | 0 | 0 | 0 | 0 | 0 | 0 | 0 | 0 |
| | through-hole [°] | | | | | | | | | |
| | Number ratio Rt | 99.5% | 99.5% | 99.5% | 99.5% | 99.5% | 99.5% | 80.0% | 95.0% | 99.5% |
| | Average hole | 3 | 3 | 3 | 3 | 3 | 3.8 | 3.5 | 3.5 | 3.5 |
| | diameter [μm] | | | | | | | | | |
| | Number ratio Rr | 99.5% | 99.5% | 99.5% | 99.5% | 99.5% | 85.0% | 75.0% | 80.0% | 80.0% |
| | Standard | 0.08 | 0.08 | 0.08 | 0.08 | 0.08 | 0.5 | 0.5 | 0.5 | 0.5 |
| | deviation of hole | | | | | | | | | |
| | diameter | | | | | | | | | |
| | distribution [μm] | | | | | | | | | |
| | Standard | 2.7% | 2.7% | 2.7% | 2.7% | 2.7% | 13.2% | 14.3% | 14.3% | 14.3% |
| | deviation/average | | | | | | | | | |
| | hole diameter | | | | | | | | | |
| | Density of | 3 × 10⁵ | 3 × 10⁵ | 3 × 10⁵ | 3 × 10⁵ | 3 × 10⁵ | 3 × 10⁵ | 3 × 10⁵ | 3 × 10⁵ | 3 × 10⁵ |
| | through-holes | | | | | | | | | |
| | [holes/cm²] | | | | | | | | | |
| | Curved portion of | Y | Y | Y | Y | Y | Y | N | N | N |
| | end part of | | | | | | | | | |
| | through-hole | | | | | | | | | |
| | Thickness of resin | 15 | 9 | 15 | 15 | 15 | 15 | 15 | 15 | 15 |
| | membrane filter | | | | | | | | | |
| | [μm] | | | | | | | | | |
| | Contact angle of | 50 | 50 | 50 | 50 | 50 | 50 | 50 | 50 | 50 |
| | main surface [°] | | | | | | | | | |
| Evaluation | Separation | 4 | 5 | 5 | 5 | 5 | 2 | 1 | 1 | 1 |
| result | accuracy | | | | | | | | | |
| | Toughness | 4 | 4 | 5 | 5 | 5 | 3 | 3 | 3 | 3 |

TABLE 4
(1)

| | | Example 13 | Example 14 | Example 15 | Example 16 | Example 17 | Example 18 |
|---|---|---|---|---|---|---|---|
| Dry film | | DF2 | DF3 | DF4 | DF5 | DF6 | DF7 |
| Exposing | Photo mask | Circular | Circular | Circular | Circular | Circular | Circular |
| step | | staggered | staggered | staggered | staggered | staggered | staggered |
| | | arrangement | arrangement | arrangement | arrangement | arrangement | arrangement |
| | | (diameter: 3 | (diameter: 3 | (diameter: 3 | (diameter: 3 | (diameter: 3 | (diameter: 3 |
| | | μm) with pitch | μm) with pitch | μm) with pitch | μm) with pitch | μm) with pitch | μm) with pitch |
| | | of 20 μm and | of 20 μm and | of 20 μm and | of 20 μm and | of 20 μm and | of 20 μm and |
| | | angle of 60° | angle of 60° | angle of 60° | angle of 60° | angle of 60° | angle of 60° |
| | Exposure angle | Perpendicular | Perpendicular | Perpendicular | Perpendicular | Perpendicular | Perpendicular |
| | | (90°) | (90°) | (90°) | (90°) | (90°) | (90°) |
| | Exposure gap [μm] | 0 | 0 | 0 | 0 | 0 | 0 |
| | Exposure amount | 100 | 100 | 100 | 100 | 100 | 100 |
| | [mJ/cm²] | | | | | | |
| Developing | Development | 25° C., | 25° C., | 25° C., | 25° C., | 25° C., | 25° C., |
| step | condition | 60 seconds | 60 seconds | 60 seconds | 60 seconds | 60 seconds | 60 seconds |
| | Order of | Before | Before | Before | Before | Before | Before |
| | implementation | peeling step | peeling step | peeling step | peeling step | peeling step | peeling step |
| Peeling step | | Physically peeling | Physically | Physically | Physically | Physically | Physically |
| | | | peeling | peeling | peeling | peeling | peeling |
| Physical | Sva[μm²] | 7.0 | 7.0 | 7.0 | 7.0 | 7.0 | 7.0 |
| properties | Svb[μm²] | 7.0 | 7.0 | 7.0 | 7.0 | 7.0 | 7.0 |
| of resin | Sva/Svb | 1.0 | 1.0 | 1.0 | 1.0 | 1.0 | 1.0 |
| membrane | Number ratio Ra | 0.5% | 0.5% | 0.5% | 0.5% | 0.5% | 0.5% |
| filter | Number ratio Rb | 0.5% | 0.5% | 0.5% | 0.5% | 0.5% | 0.5% |
| | Tilt angle of | 0 | 0 | 0 | 0 | 0 | 0 |
| | through-hole [°] | | | | | | |
| | Number ratio Rt | 99.5% | 99.5% | 99.5% | 99.5% | 99.5% | 99.5% |
| | Average hole | 3 | 3 | 3 | 3 | 3 | 3 |
| | diameter [μm] | | | | | | |
| | Number ratio Rr | 99.5% | 99.5% | 99.5% | 99.5% | 99.5% | 99.5% |
| | Standard deviation | 0.08 | 0.08 | 0.08 | 0.08 | 0.08 | 0.08 |
| | of hole diameter | | | | | | |
| | distribution [μm] | | | | | | |
| | Standard | 2.7% | 2.7% | 2.7% | 2.7% | 2.7% | 2.7% |
| | deviation/average | | | | | | |
| | hole diameter | | | | | | |
| | Density of | 3 × 10⁵ | 3 × 10⁵ | 3 × 10⁵ | 3 × 10⁵ | 3 × 10⁵ | 3 × 10⁵ |
| | through-holes | | | | | | |
| | [holes/cm²] | | | | | | |
| | Curved portion of | Y | Y | | Y | Y | Y |
| | end part of | | | | | | |
| | through-hole | | | | | | |
| | Thickness of resin | 15 | 15 | 15 | 15 | 15 | 15 |
| | membrane filter | | | | | | |
| | [μm] | | | | | | |
| | Contact angle of | 50 | 50 | 50 | 50 | 50 | 50 |
| | main surface [°] | | | | | | |
| Evaluation | Separation accuracy | 5 | 5 | 5 | 5 | 5 | 5 |
| result | Toughness | 5 | 4 | 4 | 5 | 5 | 5 |

TABLE 4
(2)

| | | Example 19 | Example 20 | Example 21 | Example 22 | Example 23 | Example 24 |
|---|---|---|---|---|---|---|---|
| Dry film | | DF8 | DF9 | DF10 | DF11 | DF12 | DF13 |
| Exposing | Photo mask | Circular | Circular | Circular | Circular | Circular | Circular |
| step | | staggered | staggered | staggered | staggered | staggered | staggered |
| | | arrangement | arrangement | arrangement | arrangement | arrangement | arrangement |
| | | (diameter: 3 | (diameter: 3 | (diameter: 3 | (diameter: 3 | (diameter: 3 | (diameter: 3 |
| | | μm) with pitch | μm) with pitch | μm) with pitch | μm) with pitch | μm) with pitch | μm) with pitch |
| | | of 20 μm and | of 20 μm and | of 20 μm and | of 20 μm and | of 20 μm and | of 20 μm and |
| | | angle of 60° | angle of 60° | angle of 60° | angle of 60° | angle of 60° | angle of 60° |
| | Exposure angle | Perpendicular | Perpendicular | Perpendicular | Perpendicular | Perpendicular | Perpendicular |
| | | (90°) | (90°) | (90°) | (90°) | (90°) | (90°) |
| | Exposure gap [μm] | 0 | 0 | 0 | 0 | 0 | 0 |
| | Exposure amount | 100 | 100 | 100 | 100 | 100 | 100 |
| | [mJ/cm²] | | | | | | |
| Developing | Development | 25° C., | 25° C., | 25° C., | 25° C., | 25° C., | 25° C., |
| step | condition | 60 seconds | 60 seconds | 60 seconds | 60 seconds | 60 seconds | 60 seconds |
| | Order of | Before | Before | Before | Before | Before | Before |
| | implementation | peeling step | peeling step | peeling step | peeling step | peeling step | peeling step |
| Peeling step | | Physically | Physically | Physically | Physically | Physically | Physically |
| | | peeling | peeling | peeling | peeling | peeling | peeling |
| Physical | Sva[μm²] | 7.0 | 7.0 | 7.0 | 7.0 | 7.0 | 7.0 |
| properties of | Svb[μm²] | 7.0 | 7.0 | 7.0 | 7.0 | 7.0 | 7.0 |
| resin | Sva/Svb | 1.0 | 1.0 | 1.0 | 1.0 | 1.0 | 1.0 |
| membrane | Number ratio Ra | 0.5% | 0.5% | 0.5% | 0.5% | 0.5% | 0.5% |
| filter | Number ratio Rb | 0.5% | 0.5% | 0.5% | 0.5% | 0.5% | 0.5% |
| | Tilt angle of | 0 | 0 | 0 | 0 | 0 | 0 |
| | through-hole [°] | | | | | | |
| | Number ratio Rt | 99.5% | 99.5% | 99.5% | 99.5% | 99.5% | 99.5% |
| | Average hole | 3 | 3 | 3 | 3 | 3 | 3 |
| | diameter [μm] | | | | | | |
| | Number ratio Rr | 99.5% | 99.5% | 99.5% | 99.5% | 99.5% | 99.5% |
| | Standard deviation | 0.08 | 0.08 | 0.08 | 0.08 | 0.08 | 0.08 |
| | of hole diameter | | | | | | |
| | distribution [μm] | | | | | | |
| | Standard | 2.7% | 2.7% | 2.7% | 2.7% | 2.7% | 2.7% |
| | deviation/average | | | | | | |
| | hole diameter | | | | | | |
| | Density of | 3 × 10⁵ | 3 × 10⁵ | 3 × 10⁵ | 3 × 10⁵ | 3 × 10⁵ | 3 × 10⁵ |
| | through-holes | | | | | | |
| | [holes/cm²] | | | | | | |
| | Curved portion of | Y | Y | Y | Y | Y | Y |
| | end part of | | | | | | |
| | through-hole | | | | | | |
| | Thickness of resin | 15 | 15 | 15 | 15 | 15 | 15 |
| | membrane filter | | | | | | |
| | [μm] | | | | | | |
| | Contact angle of | 30 | 30 | 50 | 30 | 50 | 50 |
| | main surface [°] | | | | | | |
| Evaluation | Separation accuracy | 5 | 5 | 5 | 5 | 5 | 5 |
| result | Toughness | 5 | 5 | 4 | 5 | 5 | 5 |

TABLE 4
(3)

| | | Example 25 | Example 26 | Example 27 | Example 28 | Example 29 | Example 30 |
|---|---|---|---|---|---|---|---|
| Dry film | | DF14 | DF15 | DF16 | DF17 | DF18 | DF19 |
| Exposing | Photo mask | Circular | Circular | Circular | Circular | Circular | Circular |
| step | | staggered | staggered | staggered | staggered | staggered | staggered |
| | | arrangement | arrangement | arrangement | arrangement | arrangement | arrangement |
| | | (diameter: 3 | (diameter: 3 | (diameter: 3 | (diameter: 3 | (diameter: 3 | (diameter: 3 |
| | | μm) with pitch | μm) with pitch | μm) with pitch | μm) with pitch | μm) with pitch | μm) with pitch |
| | | of 20 μm and | of 20 μm and | of 20 μm and | of 20 μm and | of 20 μm and | of 20 μm and |
| | | angle of 60° | angle of 60° | angle of 60° | angle of 60° | angle of 60° | angle of 60° |
| | Exposure angle | Perpendicular | Perpendicular | Perpendicular | Perpendicular | Perpendicular | Perpendicular |
| | | (90°) | (90°) | (90°) | (90°) | (90°) | (90°) |
| | Exposure gap [μm] | 0 | 0 | 0 | 0 | 0 | 0 |
| | Exposure amount | 100 | 100 | 100 | 100 | 100 | 100 |
| | [mJ/cm²] | | | | | | |
| Developing | Development | 25° C., | 25° C., | 25° C., | 25° C., | 25° C., | 25° C., |
| step | condition | 60 seconds | 60 seconds | 60 seconds | 60 seconds | 60 seconds | 60 seconds |
| | Order of | Before | Before | Before | Before | Before | Before |
| | implementation | peeling step | peeling step | peeling step | peeling step | peeling step | peeling step |
| Peeling step | | Physically | Physically | Physically | Physically | Physically | Physically |
| | | peeling | peeling | peeling | peeling | peeling | peeling |
| Physical | Sva[μm²] | 7.0 | 7.0 | 7.0 | 7.0 | 7.0 | 7.0 |
| properties | Svb[μm²] | 7.0 | 7.0 | 7.0 | 7.0 | 7.0 | 7.0 |
| of resin | Sva/Svb | 1.0 | 1.0 | 1.0 | 1.0 | 1.0 | 1.0 |
| membrane | Number ratio Ra | 0.5% | 0.5% | 0.5% | 0.5% | 0.5% | 0.5% |
| filter | Number ratio Rb | 0.5% | 0.5% | 0.5% | 0.5% | 0.5% | 0.5% |
| | Tilt angle of | 0 | 0 | 0 | 0 | 0 | 0 |
| | through-hole [°] | | | | | | |
| | Number ratio Rt | 99.5% | 99.5% | 99.5% | 99.5% | 99.5% | 99.5% |
| | Average hole | 3 | 3 | 3 | 3 | 3 | 3 |
| | diameter [μm] | | | | | | |
| | Number ratio Rr | 99.5% | 99.5% | 99.5% | 99.5% | 99.5% | 99.5% |
| | Standard deviation | 0.08 | 0.08 | 0.08 | 0.08 | 0.08 | 0.08 |
| | of hole diameter | | | | | | |
| | distribution [μm] | | | | | | |
| | Standard | 2.7% | 2.7% | 2.7% | 2.7% | 2.7% | 2.7% |
| | deviation/average | | | | | | |
| | hole diameter | | | | | | |
| | Density of | 3 × 10⁵ | 3 × 10⁵ | 3 × 10⁵ | 3 × 10⁵ | 3 × 10⁵ | 3 × 10⁵ |
| | through-holes | | | | | | |
| | [holes/cm²] | | | | | | |
| | Curved portion of | Y | Y | Y | Y | Y | Y |
| | end part of | | | | | | |
| | through-hole | | | | | | |
| | Thickness of resin | 15 | 15 | 15 | 15 | 15 | 15 |
| | membrane filter | | | | | | |
| | [μm] | | | | | | |
| | Contact angle of | 90 | 50 | 50 | 50 | 50 | 50 |
| | main surface [°] | | | | | | |
| Evaluation | Separation accuracy | 5 | 5 | 5 | 5 | 5 | 5 |
| result | Toughness | 4 | 4 | 5 | 4 | 5 | 4 |

TABLE 4
(4)

| | | Example 31 | Example 32 | Example 33 | Example 34 | Example 35 | Example 36 |
|---|---|---|---|---|---|---|---|
| Dry film | | DF20 | DF21 | DF22 | DF23 | DF24 | DF25 |
| Exposing | Photo mask | Circular | Circular | Circular | Circular | Circular | Circular |
| step | | staggered | staggered | staggered | staggered | staggered | staggered |
| | | arrangement | arrangement | arrangement | arrangement | arrangement | arrangement |
| | | (diameter: 3 | (diameter: 3 | (diameter: 3 | (diameter: 3 | (diameter: 3 | (diameter: 3 |
| | | μm) with pitch | μm) with pitch | μm) with pitch | μm) with pitch | μm) with pitch | μm) with pitch |
| | | of 20 μm and | of 20 μm and | of 20 μm and | of 20 μm and | of 20 μm and | of 20 μm and |
| | | angle of 60° | angle of 60° | angle of 60° | angle of 60° | angle of 60° | angle of 60° |
| | Exposure angle | Perpendicular | Perpendicular | Perpendicular | Perpendicular | Perpendicular | Perpendicular |
| | | (90°) | (90°) | (90°) | (90°) | (90°) | (90°) |
| | Exposure gap [μm] | 0 | 0 | 0 | 0 | 0 | 0 |
| | Exposure amount | 100 | 100 | 100 | 100 | 100 | 100 |
| | [mJ/cm²] | | | | | | |
| Developing | Development | 25° C., | 25° C., | 25° C., | 25° C., | 25° C., | 25° C., |
| step | condition | 60 seconds | 60 seconds | 60 seconds | 60 seconds | 60 seconds | 60 seconds |
| | Order of | Before | Before | Before | Before | Before | Before |
| | implementation | peeling step | peeling step | peeling step | peeling step | peeling step | peeling step |
| Peeling step | | Physically | Physically | Physically | Physically | Physically | Physically |
| | | peeling | peeling | peeling | peeling | peeling | peeling |
| Physical | Sva[μm²] | 7.0 | 7.0 | 7.0 | 7.0 | 7.0 | 7.0 |
| properties | Svb[μm²] | 7.0 | 7.0 | 7.0 | 7.0 | 7.0 | 7.0 |
| of resin | Sva/Svb | 1.0 | 1.0 | 1.0 | 1.0 | 1.0 | 1.0 |
| membrane | Number ratio Ra | 2.0% | 0.5% | 0.5% | 0.5% | 0.5% | 2.0% |
| filter | Number ratio Rb | 2.0% | 0.5% | 0.5% | 0.5% | 0.5% | 2.0% |
| | Tilt angle of | 0 | 0 | 0 | 0 | 0 | 0 |
| | through-hole [°] | | | | | | |
| | Number ratio Rt | 99.5% | 99.5% | 99.5% | 99.5% | 99.5% | 99.5% |
| | Average hole | 3 | 3 | 3 | 3 | 3 | 3 |
| | diameter [μm] | | | | | | |
| | Number ratio Rr | 95.0% | 99.5% | 99.5% | 99.5% | 99.5% | +12% |
| | Standard deviation | 0.12 | 0.08 | 0.08 | 0.08 | 0.08 | 0.12 |
| | of hole diameter | | | | | | |
| | distribution [μm] | | | | | | |
| | Standard | 4.0% | 2.7% | 2.7% | 2.7% | 2.7% | 4.0% |
| | deviation/average | | | | | | |
| | hole diameter | | | | | | |
| | Density of | 3 × 10⁵ | 3 × 10⁵ | 3 × 10⁵ | 3 × 10⁵ | 3 × 10⁵ | 3 × 10⁵ |
| | through-holes | | | | | | |
| | [holes/cm²] | | | | | | |
| | Curved portion of | Y | Y | Y | Y | Y | Y |
| | end part of | | | | | | |
| | through-hole | | | | | | |
| | Thickness of resin | 15 | 15 | 15 | 15 | 15 | 15 |
| | membrane filter | | | | | | |
| | [μm] | | | | | | |
| | Contact angle of | 50 | 50 | 50 | 50 | 50 | 50 |
| | main surface [°] | | | | | | |
| Evaluation | Separation accuracy | 4 | 5 | 5 | 5 | 5 | 4 |
| result | Toughness | 5 | 5 | 5 | 5 | 5 | 5 |

TABLE 4
(5)

| | | Example 37 | Example 38 | Example 39 | Example 40 | Example 41 | Example 42 |
|---|---|---|---|---|---|---|---|
| Dry film | | DF26 | DF27 | DF28 | DF29 | DF30 | DF30 |
| Exposing | Photo mask | Circular | Circular | Circular | Circular | Circular | Circular |
| step | | staggered | staggered | staggered | staggered | staggered | staggered |
| | | arrangement | arrangement | arrangement | arrangement | arrangement | arrangement |
| | | (diameter: 3 μm) | (diameter: 3 μm) | (diameter: 3 μm) | (diameter: 3 μm) | (diameter: 3 μm) | (diameter: 3 μm) |
| | | with pitch of 20 μm | with pitch of 20 μm | with pitch of 20 μm | with pitch of 20 μm | with pitch of 20 μm | with pitch of 20 μm |
| | | and angle of 60° | and angle of 60° | and angle of 60° | and angle of 60° | and angle of 60° | and angle of 60° |
| | Exposure angle | Perpendicular (90°) | Perpendicular (90°) | Perpendicular (90°) | Perpendicular (90°) | Perpendicular (90°) | Perpendicular (90°) |
| | Exposure gap [μm] | 0 | 0 | 0 | 0 | 0 | 0 |
| | Exposure amount | 100 | 100 | 100 | 100 | 100 | 100 |
| | [mJ/cm²] | | | | | | |
| Developing | Development | 25° C., | 25° C., | 25° C., | 25° C., | 25° C., | 25° C., |
| step | condition | 60 seconds | 60 seconds | 60 seconds | 60 seconds | 60 seconds | 60 seconds |
| | Order of | Before | Before | Before | Before | Before | Before |
| | implementation | peeling step | peeling step | peeling step | peeling step | peeling step | peeling step |
| Peeling step | | Physically | Physically | Physically | Physically | Physically | Physically |
| | | peeling | peeling | peeling | peeling | peeling | peeling |
| Physical | Sva[μm²] | 7.0 | 7.0 | 7.0 | 7.0 | 7.0 | 7.0 |
| properties | Svb[μm²] | 7.0 | 7.0 | 7.0 | 7.0 | 7.0 | 7.0 |
| of resin | Sva/Svb | 1.0 | 1.0 | 1.0 | 1.0 | 1.0 | 1.0 |
| membrane | Number ratio Ra | 0.5% | 0.5% | 0.5% | 0.5% | 0.5% | 0.5% |
| filter | Number ratio Rb | 0.5% | 0.5% | 0.5% | 0.5% | 0.5% | 0.5% |
| | Tilt angle of | 0 | 0 | 0 | 0 | 0 | 0 |
| | through-hole [°] | | | | | | |
| | Number ratio Rt | 99.5% | 99.5% | 99.5% | 99.5% | 99.5% | 99.5% |
| | Average hole | 3 | 3 | 3 | 3 | 3 | 3 |
| | diameter [μm] | | | | | | |
| | Number ratio Rr | 99.5% | 99.5% | 99.5% | 99.5% | 99.5% | 99.5% |
| | Standard deviation | 0.08 | 0.08 | 0.08 | 0.08 | 0.08 | 0.08 |
| | of hole diameter | | | | | | |
| | distribution [μm] | | | | | | |
| | Standard | 2.7% | 2.7% | 2.7% | 2.7% | 2.7% | 2.7% |
| | deviation/average | | | | | | |
| | hole diameter | | | | | | |
| | Density of | 3 × 10⁵ | 3 × 10⁵ | 3 × 10⁵ | 3 × 10⁵ | 3 × 10⁵ | 3 × 10⁵ |
| | through-holes | | | | | | |
| | [holes/cm²] | | | | | | |
| | Curved portion of | Y | Y | Y | Y | Y | Y |
| | end part of | | | | | | |
| | through-hole | | | | | | |
| | Thickness of resin | 15 | 15 | 15 | 15 | 15 | 20 |
| | membrane filter | | | | | | |
| | [μm] | | | | | | |
| | Contact angle of | 50 | 50 | 50 | 50 | 50 | 50 |
| | main surface [°] | | | | | | |
| Evaluation | Separation accuracy | 5 | 5 | 5 | 5 | 5 | 5 |
| result | Toughness | 5 | 5 | 5 | 5 | 5 | 5 |

TABLE 5

| | | Example 101 | Example 102 | Example 103 | Example 104 |
|---|---|---|---|---|---|
| Dry film | | DF101 | DF102 | DF103 | DF104 |
| Exposing step | Photo mask | Circular staggered | Circular staggered | Circular staggered | Circular staggered |
| | | arrangement (diameter: | arrangement (diameter: | arrangement (diameter: | arrangement (diameter: |
| | | 3 μm) with pitch of 20 | 3 μm) with pitch of 20 | 3 μm) with pitch of 20 | 3 μm) with pitch of 20 |
| | | μm and angle of 60° | μm and angle of 60° | μm and angle of 60° | μm and angle of 60° |
| | Exposure angle | Perpendicular (90°) | Perpendicular (90°) | Perpendicular (90°) | Perpendicular (90°) |
| | Exposure gap [μm] | 0 | 0 | 0 | 0 |
| | Exposure amount | 100 | 100 | 100 | 100 |
| | [mJ/cm²] | | | | |
| Developing step | | 25° C., 60 seconds | 25° C., 60 seconds | 25° C., 60 seconds | 25° C., 60 seconds |
| Peeling step | | Physically peeling | Physically peeling | Physically peeling | Physically peeling |
| Physical | Sva[μm²] | 7.0 | 7.0 | 7.0 | 7.0 |
| properties of | Svb[μm²] | 7.0 | 7.0 | 7.0 | 7.0 |
| resin | Sva/Svb | 1.0 | 1.0 | 1.0 | 1.0 |
| membrane | Number ratio Ra | 0.5% | 0.5% | 0.5% | 0.5% |
| filter | Number ratio Rb | 0.5% | 0.5% | 0.5% | 0.5% |
| | Tilt angle of | 0 | 0 | 0 | 0 |
| | through-hole [°] | | | | |
| | Number ratio Rt | 99.5% | 99.5% | 99.5% | 99.5% |
| | Average hole diameter | 3 | 3 | 3 | 3 |
| | [μm] | | | | |
| | Number ratio Rr | 99.5% | 99.5% | 99.5% | 99.5% |
| | Standard deviation of | 0.08 | 0.08 | 0.08 | 0.08 |
| | hole diameter | | | | |
| | distribution [μm] | | | | |
| | Standard | 2.7% | 2.7% | 2.7% | 2.7% |
| | deviation/average hole | | | | |
| | diameter | | | | |
| | Density of | 3 × 10⁵ | 3 × 10⁵ | 3 × 10⁵ | 3 × 10⁵ |
| | through-holes | | | | |
| | [holes/cm²] | | | | |
| | Curved portion of end | Y | Y | Y | Y |
| | part of through-hole | | | | |
| | Thickness of resin | 15 | 15 | 15 | 15 |
| | membrane filter [μm] | | | | |
| | Contact angle of main | 50 | 50 | 50 | 50 |
| | surface [°] | | | | |
| Evaluation | Separation accuracy | 5 | 5 | 5 | 5 |
| result | Toughness | 5 | 5 | 5 | 5 |

From the results of each of Examples and Comparative Examples, it was found that the resin membrane filter according to the embodiment of the present invention, having a plurality of through-holes in which the area of the opening portion satisfies a predetermined requirement, had high separation accuracy and excellent toughness.

### EXPLANATION OF REFERENCES

10, 30: resin membrane filter
11, 31: first main surface
12, 32: second main surface
13, 33: cross section
20, 40: through-hole
21, 22: opening portion
23, 43: curved portion
A, B: position

What is claimed is:

1. A resin membrane filter comprising:
a first main surface;
a second main surface; and
a plurality of through-holes penetrating from the first main surface to the second main surface,
in the through-hole, in a case where an average area of an opening portion at a position A which is located at a distance of 10% of a thickness of the resin membrane filter from the first main surface is denoted as Sva and an average area of an opening portion at a position B which is located at a distance of 90% of the thickness of the resin membrane filter from the first main surface is denoted as Svb, a relationship of an expression (1) is satisfied,
0.8≤Sva/Svb≤1.25 the expression (1)
in the plurality of through-holes, a number ratio Ra of through-holes in which an area of the opening portion at the position A is more than 1.25 times Sva is 3.0% or less, and
in the plurality of through-holes, a number ratio Rb of through-holes in which an area of the opening portion at the position B is more than 1.25 times Svb is 3.0% or less.

2. The resin membrane filter according to claim 1,
wherein, in the plurality of through-holes, a number ratio Rt of through-holes in which an angle between an extending direction of the through-holes and a thickness direction of the resin membrane filter is within 5° is 99.0% or more.

3. The resin membrane filter according to claim 1,
wherein, in the plurality of through-holes, a number ratio Rr of through-holes in which a hole diameter is 0.9 to 1.1 times an average hole diameter of the through-holes is 99% or more.

4. The resin membrane filter according to claim 1,
wherein a ratio of a standard deviation of hole diameters of the through-holes to an average hole diameter of the through-holes is 3.0% or less.

5. The resin membrane filter according to claim 1,
wherein a curved portion in which a hole diameter of the through-hole increases as the curved portion approaches an opening end of the through-hole is formed in at least one end part of the through-hole, and
a curvature radius of the curved portion in a cut plane including an extending direction of the through-hole and a thickness direction of the resin membrane filter is 1 μm or more.

6. The resin membrane filter according to claim 1,
wherein an average hole diameter of the through-holes is 10 μm or less.

7. The resin membrane filter according to claim 1,
wherein an average hole diameter of the through-holes is 5 μm or less.

8. The resin membrane filter according to claim 1,
wherein a shape of the opening portion of the through-hole observed from a normal direction of the resin membrane filter is circular.

9. The resin membrane filter according to claim 1,
wherein the thickness of the resin membrane filter is 10 μm or more.

10. The resin membrane filter according to claim 1,
wherein a contact angle of at least one of the first main surface or the second main surface with water is 10° to 70°.

11. The resin membrane filter according to claim 1,
wherein the resin membrane filter consists of a resin membrane formed of a photosensitive composition layer.

12. A resin membrane filter comprising:
a first main surface;
a second main surface; and
a plurality of through-holes penetrating from the first main surface to the second main surface,
in the through-hole, in a case where an average area of an opening portion at a position A which is located at a distance of 10% of a thickness of the resin membrane filter from the first main surface is denoted as Sva and an average area of an opening portion at a position B which is located at a distance of 90% of the thickness of the resin membrane filter from the first main surface is denoted as Svb, a relationship of an expression (1) is satisfied,
0.8≤Sva/Svb≤1.25 the expression (1)
in the plurality of through-holes, a number ratio Ra of through-holes in which an area of the opening portion at the position A is more than 1.25 times Sva is 3.0% or less,
in the plurality of through-holes, a number ratio Rb of through-holes in which an area of the opening portion at the position B is more than 1.25 times Svb is 3.0% or less,
in the plurality of through-holes, a number ratio Rt of through-holes in which an angle between an extending direction of the through-holes and a thickness direction of the resin membrane filter is within 5° is 99.0% or more,
in the plurality of through-holes, a number ratio Rr of through-holes in which a hole diameter is 0.9 to 1.1 times an average hole diameter of the through-holes is 99% or more,
a ratio of a standard deviation of hole diameters of the through-holes to an average hole diameter of the through-holes is 3.0% or less,
a curved portion in which a hole diameter of the through-hole increases as the curved portion approaches an opening end of the through-hole is formed in at least one end part of the through-hole,
a curvature radius of the curved portion in a cut plane including an extending direction of the through-hole and a thickness direction of the resin membrane filter is 1 μm or more, an average hole diameter of the through-holes is 5 μm or less,
a shape of the opening portion of the through-hole observed from a normal direction of the resin membrane filter is circular,
the thickness of the resin membrane filter is 10 μm or more, and
a contact angle of at least one of the first main surface or the second main surface with water is 10° to 70°.

13. The resin membrane filter according to claim 1,
wherein the resin membrane filter is a cured membrane of a negative tone photosensitive composition layer.

14. The resin membrane filter according to claim 1,
wherein the resin membrane filter is formed from a positive tone photosensitive composition layer.

15. The resin membrane filter according to claim 1,
wherein the resin membrane filter is used for cell separation.

16. A manufacturing method of the resin membrane filter according to claim 1, comprising, in the following order:
a step P1 of preparing a photosensitive composition layer;
a step P2 of exposing the photosensitive composition layer in a patterned manner; and
a step P3 of developing the pattern-exposed photosensitive composition layer with a developer to form through-holes in the pattern-exposed photosensitive composition layer.

17. The manufacturing method of the resin membrane filter according to claim 16,
wherein the photosensitive composition layer is a layer formed of a negative tone photosensitive resin composition.

18. The manufacturing method of the resin membrane filter according to claim 16,
wherein an exposure light of the step P2 includes i-rays.

19. The manufacturing method of the resin membrane filter according to claim 16,
wherein the step P2 is a step of performing the exposure through a photo mask.

20. The manufacturing method of the resin membrane filter according to claim 16,
wherein the manufacturing method includes, in the following order,
a step P1-a of preparing a laminate including a temporary support and a photosensitive composition layer, and
the step P2 of exposing the photosensitive composition layer in a patterned manner, and
after the step P2, the step P3 of developing the pattern-exposed photosensitive composition layer with a developer to form through-holes in the pattern-exposed photosensitive composition layer and a step P4-a of physically peeling off the temporary support and the pattern-exposed photosensitive composition layer are performed.

21. The manufacturing method of the resin membrane filter according to claim 20,
wherein the step P4-a is performed after performing the step P3.

22. The manufacturing method of the resin membrane filter according to claim 20,
wherein the step P3 is performed after performing the step P4-a.

23. The manufacturing method of the resin membrane filter according to claim 16,
wherein the manufacturing method includes, in the following order,
a step P1-b of preparing a laminate including a temporary support, a water-soluble resin layer, and a photosensitive composition layer in this order, and
the step P2 of exposing the photosensitive composition layer in a patterned manner, and
after the step P2, a step P3-a of developing the pattern-exposed photosensitive composition layer with a developer to form through-holes in the pattern-exposed photosensitive composition layer and a step P4-b of peeling off the pattern-exposed photosensitive composition layer from the temporary support by dissolving the water-soluble resin layer are performed.

24. The manufacturing method of the resin membrane filter according to claim 16,
wherein the manufacturing method includes, in the following order,
a step P1-c of preparing a laminate including a water-soluble temporary support and a photosensitive composition layer in this order, and
the step P2 of exposing the photosensitive composition layer in a patterned manner, and
after the step P2, a step P3-a of developing the pattern-exposed photosensitive composition layer with a developer to form through-holes in the pattern-exposed photosensitive composition layer and a step P4-c of obtaining the pattern-exposed photosensitive composition layer by dissolving the water-soluble temporary support are performed.
